(19) United States
(12) Patent Application Publication
(10) Pub. No.: US 2026/0158964 A1
(43) Pub. Date: Jun. 11, 2026

(54) Method and system for testing vehicle battery system

(71) Applicant: Snap-on Incorporated, Kenosha, WI (US)

(72) Inventors: Damien J. Coleman, Cork (IE); Jacob G. Foreman, Hollister, CA (US); Patrick S. Merg, Hollister, CA (US)

(21) Appl. No.: 18/972,389

(22) Filed: Dec. 6, 2024

(51) Int. Cl. B60L 58/16; B60L 3/00; B60L 58/12; G01R 31/3842; G01R 31/392; H01M 10/48

(52) U.S. Cl. CPC B60L 58/16; B60L 3/0046; B60L 58/12; G01R 31/3842; G01R 31/392; H01M 10/486; B60L 2260/22

(57) ABSTRACT

A method to test a battery pack in a vehicle comprises determining the vehicle is driven in electric vehicle and regenerative braking modes with respective output rates continuously for threshold amounts of time. The method includes determining first and second sets of battery voltage values for multiple battery pack components in the battery pack as the vehicle is driven in the electric vehicle mode and the regenerative braking mode, respectively. Each first and second set of battery voltage values includes a value for each battery pack component in the multiple battery pack components. The method includes outputting an indicator regarding a state of the battery pack based on differences in pairs of battery voltage values among the first or second sets of battery voltage values. Each pair of battery voltage values includes a maximum and minimum battery voltage value from each first or second sets of battery voltage values.

### BACKGROUND

Some vehicles, such as electric vehicles (and hybrid vehicles including an internal combustion engine) include one or more electrical motors and a battery pack assembly (or more simply, “battery pack”) to chemically store energy for driving the electrical motor(s). The battery pack can include multiple battery pack components, such as multiple battery cells. A poorly performing battery pack component can indicate that other battery pack components within the battery pack may begin perform poorly in the near future. Replacement of a battery pack can cost thousands of dollars. Therefore, a person considering whether to buy a used vehicle with a battery pack may want to know what condition the battery pack is in before purchasing the vehicle.

### SUMMARY

In a first embodiment, a method is provided. The method includes determining a vehicle is being driven in an electric vehicle mode with a first output rate continuously for at least a first threshold amount of time. The method also includes determining multiple first sets of battery voltage values for multiple battery pack components in the vehicle as the vehicle is driven in the electric vehicle mode with the first output rate continuously for at least the first threshold amount of time. Each first set of battery voltage values includes or is representative of a pair of battery voltage values. The method further includes determining the vehicle is being driven in a regenerative braking mode with a second output rate continuously for at least a second threshold amount of time. Additionally, the method includes determining multiple second sets of battery voltage values for the multiple battery pack components in the vehicle as the vehicle is driven in the regenerative braking mode. Each second set of battery voltage values includes or is representative of a pair of battery voltage values. Even more, the method includes outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Additionally, each pair of battery voltage values among the second set of battery voltage values includes or is representative of minimum and maximum battery voltage values from each second set of battery voltage values.

In a second embodiment, a computing system is provided. The computing system comprises a processor and a non-transitory computer-readable memory storing executable instructions. Execution of the executable instructions by the processor causes the computing system to perform functions. The functions include determining a vehicle is being driven in an electric vehicle mode with a first output rate continuously for at least a first threshold amount of time. The functions also include determining multiple first sets of battery voltage values for multiple battery pack components in the vehicle as the vehicle is driven in the electric vehicle mode with the first output rate continuously for at least the first threshold amount of time. Each first set of battery voltage values includes or is representative of a pair of battery voltage values. The functions further include determining the vehicle is being driven in a regenerative braking mode with a second output rate continuously for at least a second threshold amount of time. Additionally, the functions include determining multiple second sets of battery voltage values for the multiple battery pack components in the vehicle as the vehicle is driven in the regenerative braking mode. Each second set of battery voltage values includes or is representative of a pair of battery voltage values. Even more, the functions include outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Additionally, each pair of battery voltage values among the second set of battery voltage values includes or is representative of minimum and maximum battery voltage values from each second set of battery voltage values.

In a third embodiment, a non-transitory computer-readable memory is provided. The non-transitory computer-readable memory has stored therein instructions executable by a processor to cause a computing system to perform functions. The functions include determining a vehicle is being driven in an electric vehicle mode with a first output rate continuously for at least a first threshold amount of time. The functions also include determining multiple first sets of battery voltage values for multiple battery pack components in the vehicle as the vehicle is driven in the electric vehicle mode with the first output rate continuously for at least the first threshold amount of time. Each first set of battery voltage values includes or is representative of a pair of battery voltage values. The functions further include determining the vehicle is being driven in a regenerative braking mode with a second output rate continuously for at least a second threshold amount of time. Additionally, the functions further include determining multiple second sets of battery voltage values for the multiple battery pack components in the vehicle as the vehicle is driven in the regenerative braking mode. Each second set of battery voltage values includes or is representative of a pair of battery voltage values. Even more, the functions include outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Additionally, each pair of battery voltage values among the second set of battery voltage values includes or is representative of minimum and maximum battery voltage values from each second set of battery voltage values.

In a fourth embodiment, a computing system having a processing means and a data storage means is provided. The computing system includes means for determining a vehicle is being driven in an electric vehicle mode with a first output rate continuously for at least a first threshold amount of time. The computing system also includes means for determining multiple first sets of battery voltage values for multiple battery pack components in the vehicle as the vehicle is driven in the electric vehicle mode with the first output rate continuously for at least the first threshold amount of time. Each first set of battery voltage values includes or is representative of a pair of battery voltage values. The computing system also includes means for determining the vehicle is being driven in a regenerative braking mode with a second output rate continuously for at least a second threshold amount of time. Additionally, the computing system also includes means for determining multiple second sets of battery voltage values for the multiple battery pack components in the vehicle as the vehicle is driven in the regenerative braking mode. Each second set of battery voltage values includes or is representative of a pair of battery voltage values. Even more, the computing system includes means for outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Additionally, each pair of battery voltage values among the second set of battery voltage values includes or is representative of minimum and maximum battery voltage values from each second set of battery voltage values.

Other embodiments will become apparent to those of ordinary skill in the art by reading the following detailed description, with reference where appropriate to the accompanying drawings.

### BRIEF DESCRIPTION OF THE DRAWINGS

Example embodiments are described herein with reference to the drawings.

FIG. 1 shows block diagrams of systems, in accordance with the example embodiments.

FIG. 2 shows connection arrangements, in accordance with the example embodiments.

FIG. 3 and FIG. 4 show vehicles, in accordance with the example embodiments.

FIG. 5 is a block diagram of a vehicle service tool, in accordance with the example embodiments.

FIG. 6 shows modules, in accordance with the example embodiments.

FIG. 7 is a block diagram of a server, in accordance with the example embodiments.

FIG. 8 shows a vehicle service tool, in accordance with the example embodiments.

FIG. 9 and FIG. 10 show a flow chart, in accordance with the example embodiments.

FIG. 11, FIG. 12, FIG. 13, FIG. 14, FIG. 15, FIG. 16, FIG. 17, FIG. 18, FIG. 19, FIG. 20, FIG. 21, FIG. 22, and FIG. 23 show a function set, in accordance with the example embodiments.

FIG. 24, FIG. 25, FIG. 26, FIG. 27, FIG. 28, FIG. 29, FIG. 30, FIG. 31, FIG. 32, FIG. 33, FIG. 34, FIG. 35, FIG. 36, FIG. 37, and FIG. 38 show a graphical user interface (GUI), in accordance with the example embodiments.

FIG. 39 and FIG. 40 show vehicle message flows in accordance with the example embodiments.

FIG. 41 and FIG. 42 show vehicle message flows in accordance with the example embodiments.

FIG. 43 is a block diagram illustrating a computing system that is arranged in accordance with the example embodiments.

FIG. 44 is a schematic illustrating a conceptual partial view of a computer program product for executing a computer process on a computing system, in accordance with the example embodiments.

All the figures are schematic and not necessarily to scale. Like reference numbers are used in the drawings to identify like elements unless the context or description describes otherwise.

### DETAILED DESCRIPTION

### I. Introduction

This description describes several example embodiments, at least some of which pertain to improved methods and systems for servicing a vehicle (e.g., an electric vehicle or a hybrid vehicle) and/or use of a computing system (e.g., a vehicle service tool (i.e., a VST) and/or a server) to service a vehicle. Servicing the vehicle can include testing (e.g., diagnosing) a component or system of the vehicle. Servicing the vehicle can include replacing a malfunctioning vehicle component with a replacement component and the programming, calibrating or performing a reset procedure to the replacement component via the VST. Testing the component or system can include testing a battery pack or battery system within an electric or hybrid vehicle. A result of such testing can indicate whether the battery pack or battery system needs to be replaced now or in the near future. A person considering whether to purchase an electric or hybrid vehicle may wish to have such testing performed so that the person can make a more informed purchasing decision. Alternatively, a person considering whether to drive the vehicle on a long distance trip may wish to have such testing performed so that the person can make a better decision as to whether the vehicle is suitable for the long trip.

As described below, a VST and a vehicle can operatively connect to one another using a wired or wireless connection. The vehicle can transmit a vehicle data message (VDM) according to a VDM protocol. Some vehicles uses multiple different VDM protocols to transmit VDMs. A wired connection between the VST and the vehicle can include a connection to one or more vehicle networks. In some embodiments, multiple vehicle networks in the vehicle carry VDMs according to different VDM protocols. The VST can operatively connect to the multiple vehicle networks at the same or different times. The VST can perform testing of the battery pack, the battery system, and/or other components and systems within a vehicle.

A vehicle can transmit a VDM between two or more electronic control units (ECUs) while the vehicle operates in a normal mode (e.g., a mode in which a VST is not connected to the vehicle or a mode in which a VST is connected to the vehicle, but is not transmitting VDMs to the vehicle). On the other hand, when a VST is connected to the vehicle and operating in a diagnostic mode, the vehicle can continue transmitting a VDM between two or more ECUs, as well as transmit a VDM directed to the connected VST. In some cases, the vehicle transmits the VDM directed to the VST in response to receiving a VDM from the VST.

In accordance with at least some embodiments, the VST can transmit (to a vehicle) a VDM to request a parameter identifier (PID) parameter value. As an example, a PID parameter value can indicate an electrical signal received at an ECU from a sensor connected to the ECU. As another example, a PID parameter value can indicate a value calculated by an ECU, such as a battery state-of-charge value calculated by an ECU for a battery system. As yet another example, a PID parameter value can indicate a current flowing within an electrical circuit or a voltage across multiple nodes in an electrical circuit. As still yet another example, a PID parameter value can indicate a temperature, such as a battery temperature.

The VDM to request the PID parameter value can include a PID. The ECU is programmed to receive the PID via the request, read a parameter value corresponding to the PID and transmit a response including the PID parameter value. As an example, a PID is defined using a hexadecimal number. As another example, a PID parameter value is represented using one or more data bits or one or more data bytes. The ECU may convert an input value determined by the ECU using a particular formula to determine the PID parameter value. For example, a formula to convert a byte representing a percentage from 0 to 100 percent can be the (hexadecimal PID parameter value)×(100/255).

In accordance with at least some embodiments, the VST can transmit (to a vehicle) a VDM to request a diagnostic trouble code (DTC) status from an ECU. The ECU can respond by transmitting (to the VST) a VDM indicative of whether a DTC is set active (i.e., current) or was previously set active (i.e., historical).

In accordance with at least some embodiments, the VST can transmit (to a vehicle) a VDM to request an ECU to perform a functional test or reset procedure. The ECU can respond by performing the requested functional test or reset procedure. During performance of the functional test the VST can gain control over one or more inputs or outputs of the ECU. The VST can transmit (to the vehicle) another VDM to request the ECU to stop or modify performance of the functional test or reset procedure.

In this description, a user-selectable control is sometimes abbreviated as USC. A USC can be output on a display screen (or more simply, a display). In embodiments in which the display is configured as a touch screen display, the USC output on the display can be selectable to trigger a processor to perform a function corresponding to the USC. The processor can be configured to detect that a particular USC corresponds to a location of the touch screen display is contacted by a user. A USC can be described by using a prefix followed by USC or user-selectable control. Any such described USC can be referred to more briefly as a “USC” or a user-selectable control.

Under some circumstances, however, the USC output on the display may not be selectable. For example, the USC may be output on the display to notify a user that the device including the display has the capability to perform the function, but the USC is not currently enabled to trigger performance of the function. In other words, the USC may be disabled until the user enables the USC (e.g., by paying a subscription fee, obtaining a certification credential to perform the feature, or acknowledging a safety warning).

In at least some embodiments, a USC includes a hardware key or button remote from a display. Selection of such a USC can occur by selecting (e.g., pushing the hardware key or button). Selection of such a USC can cause a change in resistance of a resistor network and a corresponding change in a voltage detected by the processor or an analog-to-digital converter. A USC including a hardware key or button can be reconfigurable. For example, selection of the USC while a first GUI is displayed triggers performance of a first set of functions and selection of the USC while a second GUI is displayed triggers performance of a second set of functions. A USC can include a graphical icon and/or text. The graphical icon and/or text can be a representative description of a set of functions (i.e., one or more functions) that is performed in response to a selection of the USC including the graphical icon and/or text.

In this description, at least some of the embodiments pertain to a GUI that includes one or more containers. A container is an area of a GUI for displaying other component(s) of the GUI. Accordingly, a container can cover at least a portion of an area of the display on which the GUI is displayed. In many instances, multiple components within a container are related to one another. For example, a container can include a PID, a PID parameter value, and a PID flag that indicates whether a PID parameter value corresponding to the PID has breached a threshold corresponding to the PID. Other containers can includes aspects corresponding to a component test, a functional test, or a reset procedure. In at least some embodiments, a container is marked using visible borders, such as line segments. In at least some of those embodiments, two containers share a common border. In at least some embodiments, a container distinguishes itself from other containers or other portions of the GUI using shading (e.g., a first color distinctly different from an adjacent second color). A container may include one or more containers. A container within another container can be referred to as a sub-container. On one hand, a container may contact one or more other containers. On the other hand, a container may not contact another container.

A container or some other portion of a GUI can include a user-selectable control (USC). The user-selectable control corresponds to one or more functions that can be initiated and/or performed in response to a selection of the USC. A USC can be embodied in a VST as a hardware USC, such as a hardware key or button. The hardware USC can be reconfigured. A GUI can show an indication of the function(s) corresponding to the hardware USC.

### II. Example Systems, Vehicles, and Connectivity

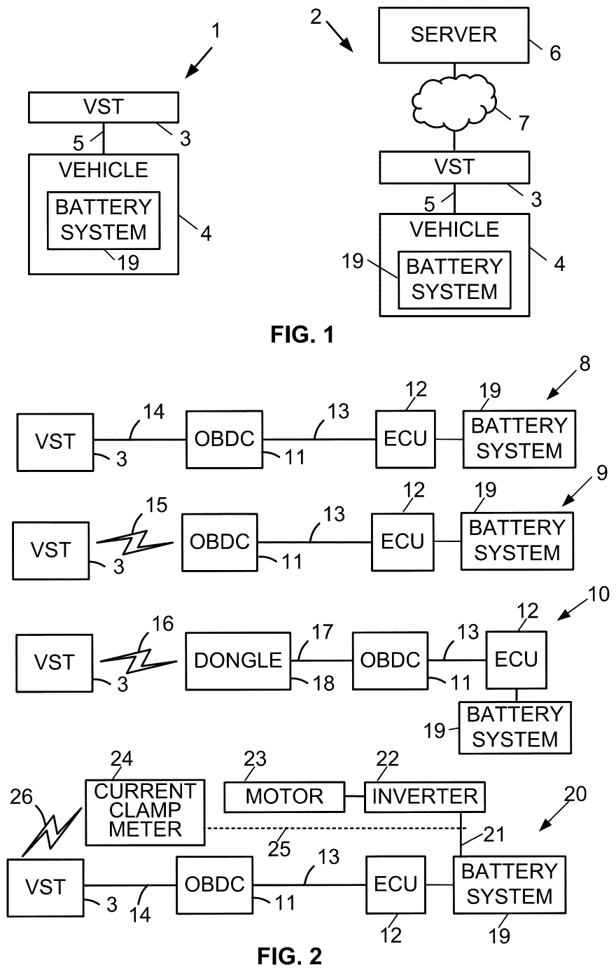

FIG. 1 shows a system 1, 2 in accordance with the example embodiments. The system 1 includes a vehicle service tool (VST) 3, a vehicle 4, and a communication link 5. The system 2 includes the VST 3, the vehicle 4, the communication link 5, a server 6, and a communication network 7. In at least some embodiments, the VST 3 includes and/or is arranged as a computing system. In at least some embodiments, the VST 3 is a part of a computing system, such as a computing system including the VST 3 and the server 6. In at least some embodiments, the VST 3 includes and/or is arranged as a vehicle scan tool, such as a vehicle scan tool configured to transmit and receive vehicle data messages (VDMs) for diagnosing and/or servicing a vehicle. In at least some embodiments, the VST 3 is arranged to perform component tests. In accordance with at least some of those embodiments, the VST 3 is also arranged as a vehicle scan tool configured to transmit and receive vehicle data messages for diagnosing and/or servicing a vehicle.

The vehicle 4 includes a battery system 19. Accordingly, the vehicle 4 can include an electric vehicle or a hybrid vehicle. The battery system 19 stores energy, such as energy converted from regenerative braking, an internal combustion engine in the hybrid vehicle, or energy provided from a charging system external to the vehicle 4. The battery system 19 can include one or more battery pack components including battery cells, and a battery management system. The battery system 19 can include a battery pack including one or more battery pack components. In general, a battery cell includes an anode, a cathode, a separator between the anode and the cathode, and an electrolyte. In accordance with at least some embodiments (such as embodiments in which battery cells are not individually replaceable), a battery pack component within the battery system 19 can be the smallest individual unit including battery cells that is replaceable within the battery system 19. In accordance with at least some embodiments, the battery system 19 includes a battery block having multiple individually replaceable battery pack components, such as multiple battery pack modules and/or multiple battery cells. The sub-components comprising multiple cells of a battery pack are referred to as “battery blocks” by some manufacturers and “battery pack modules” or more simply “battery modules” by other manufacturers. Other manufacturers could use other term(s) to refer to such sub-components.

In accordance with at least some embodiments, the battery management system of the battery system 19 outputs data indicating voltage values corresponding to different quantities of cells and arrangement of cells within the battery system 19. For example, the battery management system in some vehicles outputs data indicating voltage values at the battery cell level. As another example, the battery management system in some vehicles outputs data indicating a voltage value indicating a sum of all cells within the battery pack (e.g., at the battery pack level). As yet another example, the battery management system in some vehicles outputs data indicating a voltage value of a sum of multiple cells, but not all cells within the battery pack. Unless the context requires otherwise, for this description a voltage value of a battery pack component corresponds to the voltage value of a sum of multiple cells (e.g., the cells of a battery block or the cells of a battery pack module).

The communication network 7 can include one or more wireless networks and/or one or more wired networks. The wireless network(s) can carry communications using a wireless communication standard or protocol, examples of which are discussed below. The wired network(s) can carry communications using a wired communication standard or protocol, examples of which are discussed below. The communication network 7 can include one or more networks within the internet and/or a cloud computing network.

The VST 3 is operable to service the vehicle 4. The VST 3 can transmit a vehicle data message (VDM) to the vehicle 4 and can receive a VDM from the vehicle 4. The VST 3 can transmit a message to the server 6 to request information for servicing the vehicle 4 and can receive a message from the server 6 including the information for servicing the vehicle 4. The VST 3 can display at least a portion of the information for servicing the vehicle 4. As an example, the service information can include a test thresholds, a vehicle specification (e.g., a battery system specification), a diagnostic flowchart, a technical service bulletin, an original equipment manufacturer (OEM) position statement, a video, a schematic diagram, a component location diagram, a repair tip, a commonly-replaced parts graph, PID definitions, a PID graph, a diagnostic trouble code (DTC) definition, a safety warning, a repair order, or some other type of service information. As another example, the information can include an index value (or more simply, an index) to information stored at the VST 3, and the VST 3 can retrieve and then display the information based on the index. As an example, the index can indicate a test threshold, a battery system specification, or a GUI. The index can be one of multiple indices sent to the VST 3.

The VST 3 can transmit a message to the server 6 to request data for configuring the VST 3 to service the vehicle 4. The VST 3 can receive a message from the server including the data for configuring the VST 3 to service the vehicle 4. As an example, the data for configuring the VST 3 can include a GUI, information to populate a GUI, information to configure a GUI, an index value or indices, or mapping data. As another example, the data for configuring the VST 3 can include a file, such as a mark-up language file including data to populate and/or generate a GUI. As an example, a mark-up language file can include a hypertext mark-up language (HTML) file.

The vehicle 4 can include any vehicle described in this description. The vehicle 4 can include a vehicle that includes a vehicle system, component or other aspect described in this description as being a part of a vehicle. In at least some embodiments, the vehicle 4 includes at least a portion of the communication link 5.

The server 6 can operate on a computing system. The server 6 can include the computing system on which it operates. The server 6 can include one or more servers. As an example, the server 6 can be configured to provide a web service to another computing system, such as the VST 3 or a computing system within the vehicle 4. As an example, the web service can include a web service to provide the VST 3 with information for servicing the vehicle. The web service can output a GUI including containers having a descriptor of a PID, a functional test, a component test, a reset procedure. The web service can output a GUI such as any GUI shown the drawings.

The communication link 5 can include a wireless communication link and/or a wired communication link. As an example, the wireless communication link can include a communication link configured to carry communications using a wireless communication standard or protocol, examples of which are discussed below. As another example, the wired communication link can include a communication link configured to carry communications using a wired communication standard or protocol, examples of which are discussed below. The communication link 5 can include and/or be arranged as the wired communication link 14, the wireless communication link 15, and/or the wireless communication link 16, each of which is shown in FIG. 2.

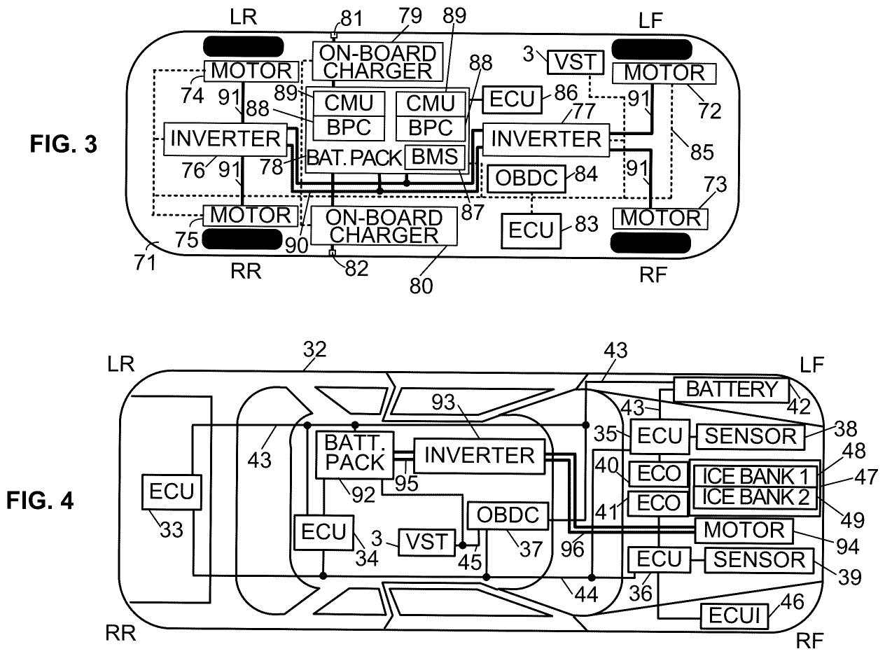

Next, FIG. 2 shows an arrangement 8, 9, 10, 20 for operatively connecting the VST 3 to component(s) in a vehicle (e.g., the vehicle 4 shown in FIG. 1). In the arrangement 8, 9, 10, 20, an on-board diagnostic connector (OBDC) 11 is operatively connected to an electronic control unit (ECU) 12 using a vehicle network 13. The ECU 12 can include one or more ECUs in the vehicle, such as an ECU 83, 86 shown in FIG. 3, or an ECU 33, 34, 35, 36 shown in FIG. 4, or any other ECU described in this description. The ECU 12 is connected to the battery system 19. The vehicle network 13 can include or be a part of the communication link 5 shown in FIG. 1 and FIG. 2.

In the arrangement 8, the VST 3 is connected directly to the OBDC 11 using a wired communication link 14. As an example, the wired communication link 14 can be contained within a harness with multiple wires, at least one of which is configured to carry a VDM between the VST 3 and the OBDC 11. The harness can include a connector removably attachable to the OBDC 11. The wired communication link 14 can include one or more wires.

In the arrangement 9, the VST 3 is connected directly to the OBDC 11 using a wireless communication link 15. The wireless communication link 15 can include an air interface established to carry a VDM between the VST 3 and the OBDC 11. The wireless communication link 15 and the air interface can be configured in accordance with a wireless communication standard or protocol, such as any wireless communication standard or protocol described in this description.

In the arrangement 10, the VST 3 is connected indirectly to the OBDC 11 using a wireless communication link 16 and a dongle 18. The dongle 18 includes a connector 17 removably attachable to the OBDC 11 and a wireless transceiver and a wired transceiver. The wireless communication link 16 can include an air interface established to carry a VDM between the VST 3 and the dongle 18. The wireless communication link 16 and the air interface can be configured in accordance with a wireless communication standard or protocol, such as any wireless communication standard or protocol described in this description. The wired transceiver of the dongle 18 can receive a VDM transmitted to the OBDC 11 over the vehicle network 13 from an ECU and can transmit a VDM onto the vehicle network 13 for transmission to an ECU connected to the OBDC 11.

In the arrangement 20, the VST 3 is connected directly to the OBDC 11 using the wired communication link 14, and the OBDC 11 is connected to the ECU 12 via the vehicle network 13. The ECU 12 is connected to the battery system 19. The battery system 19 is connected to an inverter 22 via a bus 21. The inverter 22 is connected to a motor 23 (e.g., one or more motors). A current clamp meter 24 is operatively coupled to the VST 3. The arrangement 20 shows the current clamp meter 24 and the VST being coupled to each other via a wireless link 26. In other arrangements, the current clamp meter 24 and the VST 3 can couple to one another for communicating with each other using a wired link. The current clamp meter 24 is configured to measure an electrical current, such as a current flowing in the bus 21. The current clamp meter 24 can communicate current measurements to the VST via the wireless link 26.

A person having ordinary skill in the art will understand that the current clamp meter 24 can be used within the arrangement 9, 10, and the bus 21, the inverter 22, and the motor 23 can be included within the arrangement 9, 10 similar to how those aspects are shown in arrangement 20.

Next, FIG. 3 shows a vehicle 71 and placement of the VST 3 within the vehicle 71 in accordance with the example embodiments. The vehicle 4 shown in FIG. 1 can be arranged like the vehicle 71. The vehicle 71 is an electrical vehicle.

As shown in FIG. 3, the vehicle 71 includes a motor 72 at a left front location of the vehicle 71, a motor 73 at a right front location of the vehicle 71, a motor 74 at a left rear location of the vehicle 71, and a motor 75 at a right rear location of the vehicle 71. The vehicle 71 also includes an inverter 76, 77, a battery pack 78, an on-board charger 79, 80, a charge port 81, 82, the ECU 83, 86, an OBDC 84, and a vehicle network 85. As an example, the charge port 81 can include an AC voltage charge port and the charge port 82 can include a DC voltage charge port.

The battery pack 78 or any other battery described in this description can include multiple battery pack components (BPC) (e.g., a BPC 88) and multiple cell monitoring units (CMU) (e.g., a CMU 89). A CMU, such as the CMU 89, can determine parameters regarding a corresponding battery pack component, such as a battery voltage, a battery temperature, or a battery internal resistance. A battery pack, such as the battery pack 78, can include a battery management system (BMS), such as the BMS 87. A BMS can perform various functions, such as voltage monitoring, temperature monitoring, current monitoring, state-of-charge monitoring, energy management, state-of-health monitoring, battery cell balancing, thermal management, overcharge protection, and vehicle communications with other ECUs in the vehicle and the VST 3. The VST 3 can send vehicle messages to the BMS to request battery voltage and current values, and other values such as state-of-charge values and battery temperature values. In some electric vehicles, individual battery pack components within a battery pack are configured to be separately replaceable.

A battery pack module can include multiple battery cells. As an example, a first battery pack module can include twelve individual battery cells. As another example, a second battery pack module with twelve battery cells can be configured with those battery cells arranged in three strings of four battery cells connected in series with each other. A BMS can be configured to make one or more voltage measurements with respect to those example battery pack modules. For example, a BMS can measure a voltage across each battery cell with the first and second battery pack modules such that the BMS makes twelve voltage measurements for a particular data point (e.g., a first instance in time). As another example, a BMS can make voltage measurements across the three strings of the second battery pack module such that the BMS makes three voltage measurements for each data point. As yet another example, a BMS can make a single voltage measurement across all twelve battery cells for each data point. In that regard, the twelve battery cells can be considered a string of twelve battery cells. In some electric vehicles, individual strings within a battery pack module are configured to be separately replaceable. In some electric vehicles, individual cells within a battery pack module are configured to be separately replaceable.

A battery pack can include switches or fixed conductors to allow for strings of a battery pack module to be connected in series, in parallel or in a combination of series and parallel connections. Likewise, a battery pack can include switches or fixed conductors to allow for battery pack modules to be connected in series, in parallel or in a combination of series and parallel connections.

One or more of the motor 72, 73, 74, 75, the inverter 76, 77, the charge port 81, 82, the battery pack components 88, and/or one or more other components (e.g., a conductor or connector connected to the motor 72, 73, 74, 75, the inverter 76, 77, the charge port 81, 82, the battery pack 78) can include a high-voltage component. A direct current (DC) bus 90 connects the battery pack 78 to the inverter 76, 77. An alternating current (AC) bus 91 (e.g., one or more busses) connects the inverter 76, 77 to one or more motors within the vehicle 71.

Next, FIG. 4 shows a vehicle 32 and placement of the VST 3 within the vehicle 32 in accordance with the example embodiments. In at least some embodiments, the vehicle 4 shown in FIG. 1 can be arranged like at least a portion of the vehicle 32. In at least some embodiments, the vehicle 32 can be included within the system 1, 2 in place of or in addition to the vehicle 4. The vehicle 32 can comprise a hybrid vehicle.

The vehicle 32 includes an internal combustion engine (ICE) 47 including a bank 48, 49. As an example, the bank 48 can be referred to as “bank 1”, “left bank,” and/or “front bank,” and the bank 49 can be referred to as “bank 2,” “right bank,” and/or “rear bank.” The vehicle 32 includes a battery pack 92, an inverter 93, a motor 94, and a bus 95, 96. The battery pack 92 includes multiple battery pack components (i.e., BPCs) and connects to the inverter 93 via the bus 95, a DC bus. The inverter 93 connects to the motor 94 via the bus 96, an alternating current (AC) bus.

The vehicle 32 includes an ECU 33, 34, 35, 36, an OBDC 37, a sensor 38, 39, an ECU controlled output (ECO) 40, 41, a battery 42, and a battery-connected circuit 43. The battery 42 is a low voltage battery (e.g., 12 or 42 volts) relative to the voltage of the battery pack 92 (e.g., 350 to 800 volts).

The ECU 33, 34, 35, 36 is operatively connected to the OBDC 37 via the vehicle network 44 to allow transmission of a VDM between the OBDC 37 and the ECUs connected to the vehicle network 44. The vehicle network 44 can include a wired and/or wireless network and/or can include or be arranged like the vehicle network 13 shown in FIG. 2. The vehicle 32 also includes an ECU input (ECUI) 46. An ECUI (e.g., the ECUI 46) can include a vehicle component (e.g., a sensor, a key cylinder) operatively connected to an input pin of an ECU.

In at least some embodiments, the OBDC 37 is located within a passenger compartment of the vehicle 32, within an engine compartment of the vehicle 32, or within a storage compartment within the vehicle 32 in front of or behind the passenger compartment. The VST 3 can be removably attachable to the OBDC 37. The VST 3 can connect to the OBDC 37 via a communication link 45. In at least some embodiments, the VST 3 includes the communication link 45 (e.g., a harness). The VST 3 is typically removed after the vehicle 32 has been serviced. In that way, the VST 3 can be used to diagnose other vehicles. The OBDC 37 can be configured like and/or include the OBDC 11 shown in FIG. 2 and the communication link 45 can be configured like and/or include the wired communication link 14, the wireless communication link 15, and/or the wireless communication link 16 and the dongle 18 (all shown in FIG. 2).

The battery-connected circuit 43 can include one or more electrical circuits (e.g., one or more power circuits). FIG. 4 shows the battery-connected circuit 43 extending between the battery 42 and the following vehicle components: the ECU 33, 34, 35, the OBDC 37, and the battery pack 92. The battery 42 can provide power for a battery management system within the battery pack 92. For clarity of FIG. 4, other examples of the battery-connected circuit 43 that extend between the battery 42 and some other vehicle component of the vehicle, such as the ECU 36, the sensor 38, 39, the ECO 40, 41 and the ECUI 46 are not shown in FIG. 4. The battery-connected circuit 43 between the battery 42 and the OBDC 37 can provide an electrical current to provide operational power for the VST 3.

The sensor 38, 39 is a device that provides a signal to the ECU 35, 36, respectively. The signal represents some characteristic of a vehicle the ECU 35, 36 is configured to monitor. As an example, the sensor 38, 39 can include one from among: an accelerometer, a camshaft position sensor, a crankshaft position sensor, a current sensor, a fluid level sensor, a fluid pressure sensor, a fluid temperature sensor, a hall effect sensor, an infrared sensor, a knock sensor, a mass air flow sensor, an oil pressure sensor, an oxygen sensor, a photo transistor, a piezoelectric sensor, a position sensor, a pressure sensor, a rain sensor, a refrigerant sensor, a temperature sensor, a thermistor, a throttle position sensor, a tire pressure sensor, a vehicle speed sensor, a voltage sensor, a wheel speed sensor, a yaw rate sensor, or some other typo of sensor. The signal provided by the sensor 38, 39 can be a target signal that corresponds to a selected functional test. The ECU 35 can output a VDM that includes a data value representative of the signal on an electrical circuit connecting the ECU 36 and the sensor 30. Likewise, the ECU 36 can output a VDM that includes a data value representative of the signal on an electrical circuit connecting the ECU 36 and the sensor 39.

The ECO 40, 41 is a device controlled by the ECU 35, 36, respectively. The ECU 35, 36 can control the ECO 40, 41, respectively, using an output signal or an output condition. The output signal from an ECU can be a target signal that corresponds to a selected functional test. As an example, the ECO 40, 41 can include one from among: a fuel injector, a motor, a pump, a relay, solenoid, a transformer, or a valve. In accordance with at least some embodiments, an ECU is selectable to perform a functional test and/or provide a DTC in accordance with an industry standard, such as the SAE J1979_201202 and/or ISO 15031-5 standards for E/E diagnostic test modes. As an example, the output condition can include establishing a particular voltage level on an electrical circuit operatively connected or connectable to the ECO 40, 41. For instance, the particular voltage level can be a nominal 5-volt reference signal, a nominal 12-volt reference signal, or an electrical ground level signal (e.g., a nominal 0-volt reference level).

The output signal of the ECU 35, 36 (i.e., the ECU output signal) can be any of a variety of electrical or output signals. As an example, the ECU output signal can include an analog or digital electrical signal. As a more particular example, the ECU output signal can include a pulse-width modulated signal, a triangular waveform signal, a saw tooth waveform signal, a rectangular waveform signal, a square waveform signal, or a sinusoidal waveform signal, among others. As another example, the ECU output signal can include a video signal or an audio signal. As yet another example, the digital electrical signal can include a data transmission. As an example, a data transmission can be communicated using a serial peripheral interface (SPI) interface, an inter-integrated circuit (I²C) interface, or a universal asynchronous receiver transmitter (UART) interface, among others. In response to receiving a functional test command, a processor in the ECU can execute program instructions or logic to cause the ECU output condition or output signal to appear at and/or on the ECO 40, 41.

An ECU, such as the ECU 36 can receive from the VST 3 a VDM including an identifier of a reset procedure and responsively send an output signal to the ECO 41 or the ECUI 46 to reset the ECO 41 or the ECUI 46, respectively.

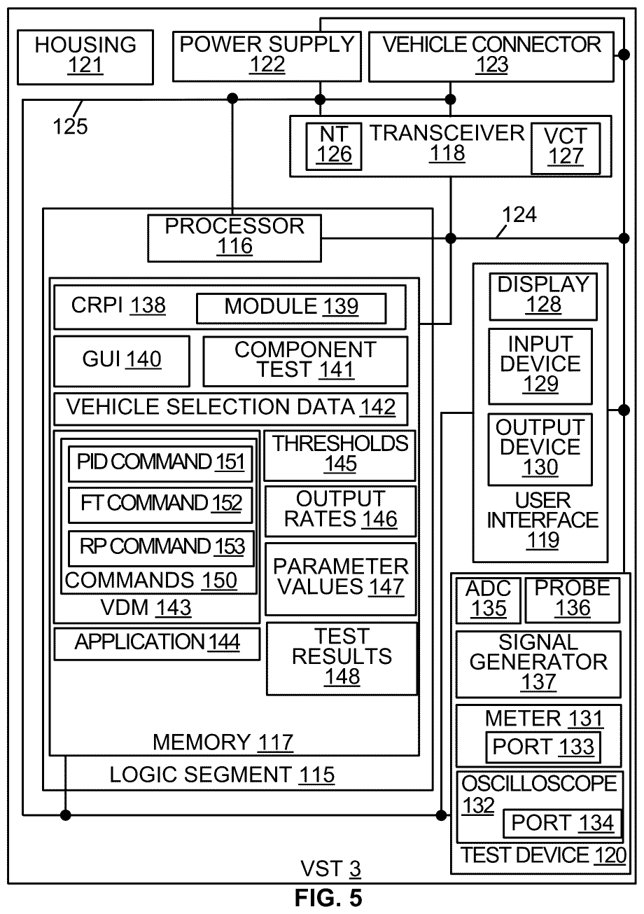

Next, FIG. 5 is a block diagram of the VST 3 in accordance with at least some of the example embodiments. The VST 3 includes a computing system operable to service a vehicle (e.g., the vehicle 4, 32, 71).

The VST 3 can include a logic segment 115 including a processor 116 and a memory 117. The VST 3 can also include a transceiver 118, a user interface 119, a test device 120, a housing 121, a power supply 122, a vehicle connector 123, a data bus 124, and/or an electric circuit 125. The data bus 124 can operatively connect two or more of the processor 116, the memory 117, the transceiver 118, the user interface 119, the test device 120, the power supply 122, or the vehicle connector 123 to one another. In other words, the data bus 124 can provide an operative connection between two or more of the processor 116, the memory 117, the transceiver 118, the user interface 119, the test device 120, the power supply 122, and/or the vehicle connector 123. An operative connection allows for the operatively connected devices to communicate with one another.

### A. Processor

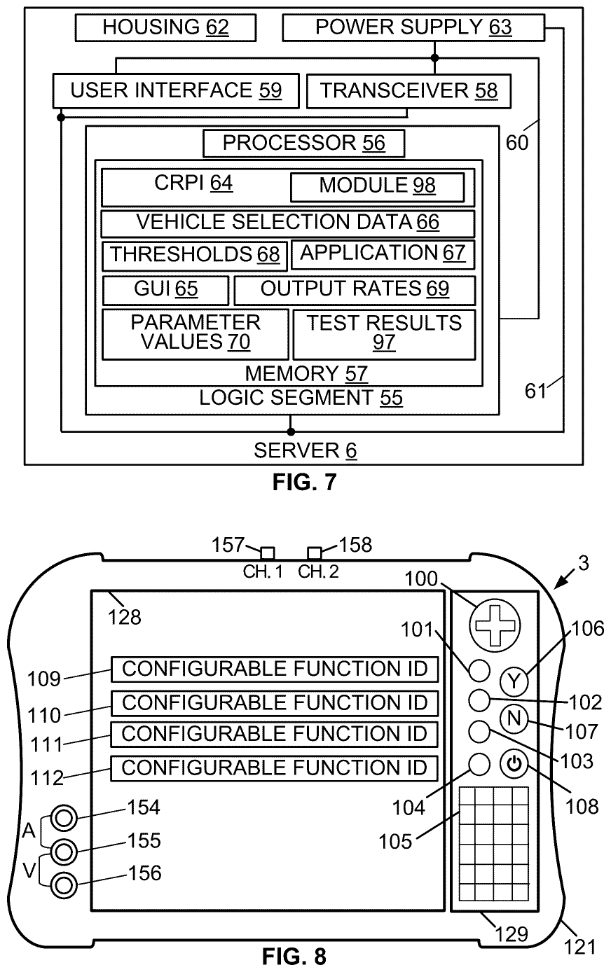

A processor, such as the processor 116, the processor 56 shown in FIG. 7, or any other processor discussed in this description, can include one or more processors. Any processor discussed in this description can thus be referred to as “at least one processor” and/or “one or more processors.” Furthermore, any processor discussed in this description can include a general purpose processor (e.g., an INTEL® single core microprocessor or an INTEL® multicore microprocessor), and/or a special purpose processor (e.g., a digital signal processor, a graphics processor, an embedded processor, or an application specific integrated circuit (ASIC) processor). Furthermore still, any processor discussed in this description can include or be operatively connected to a memory controller that controls a flow of data going to and from a memory, such as the memory 117 or the memory 57 shown in FIG. 7.

Any processor discussed in this description can be operable to execute computer-readable program instructions (CRPI). Any CRPI discussed in this description can, for example, include assembler instructions, machine instructions, machine dependent instructions, microcode, firmware instructions, state-setting data, and/or either source code or object code written in one or any combination of two or more programming languages. As an example, a programming language can include an object oriented programming language such as Java, Python, or C++, or a procedural programming language, such as the “C” programming language. Any processor discussed in this description can be operable to execute hard-coded functionality in addition to or as an alternative to software-coded functionality (e.g., via CRPI). In at least some embodiments of the VST 3, the processor 116 is a specific processor that is programmed to perform any function(s) described in this description as being performed by the VST 3 and/or with respect to a module.

An embedded processor refers to a processor with a dedicated function or functions within a larger electronic, mechanical, pneumatic, and/or hydraulic device, and is contrasted with a general purpose computer. The embedded processor can include a central processing unit chip used in a system that is not a general-purpose workstation, laptop, or desktop computer. In some embodiments, the embedded processor can execute an operating system, such as a real-time operating system (RTOS). As an example, the RTOS can include the SMX® RTOS developed by Micro Digital, Inc., such that the embedded processor can include (a) an advanced RISC (reduced instruction set computer) machine (ARM) processor (e.g., an ATSAMS70-DTE processor provided by the Atmel Corporation, San Jose, California), or (b) a COLDFIRE® processor (e.g., a 52259 processor) provided by NXP Semiconductors N.V., Eindhoven, Netherlands. A general purpose processor, a special purpose processor, and/or an embedded processor can perform analog signal processing and/or digital signal processing.

A processor can include one or more terminals to receive an electronic signal that indicates whether a USC is selected. Accordingly, a processor or the VST receiving or determining a selection of a USC can include the processor or the VST determining that the electronic signal received on the one or more terminals has a value that indicate the USC is selected. The electronic signal can comprise an analog signal or a digital value.

### B. Memory

A memory, such as the memory 117, the memory 57 shown in FIG. 7, or any other memory discussed in this description, can include one or more memories. Any memory discussed in this description can thus be referred to as “at least one memory” and/or “one or more memories.” A memory can include a non-transitory memory, a transitory memory, or both a non-transitory memory and a transitory memory. A non-transitory memory, or a portion thereof, can be located within or as part of a processor (e.g., within a single integrated circuit chip). A non-transitory memory, or a portion thereof, can be separate and distinct from a processor.

A non-transitory memory can include a tangible, volatile or non-volatile, storage component, such as an optical, magnetic, organic or other memory or disc storage component. Additionally or alternatively, a non-transitory memory can include or be operable as a random-access memory (RAM), a read-only memory (ROM), a programmable read-only memory (PROM), an erasable programmable read-only memory (EPROM), a flash memory, an electrically erasable programmable read-only memory (EEPROM), or a compact disk read-only memory (CD-ROM). The RAM can include static RAM or dynamic RAM. A non-transitory memory can be operable as a removable storage device, a non-removable storage device, or a combination thereof. A removable storage and/or a non-removable storage device can include a magnetic disk device such as a flexible disk drive or a hard-disk drive (HDD), an optical disk drive such as a compact disc (CD) drive and/or a digital versatile disk (DVD) drive, a solid state drive (SSD), or a tape drive.

A transitory memory can include, for example, CRPI or a module provided over a communication network (e.g., the communication network 7), a communication link (e.g., the communication link 5, the wired communication link 14 or the wireless communication link 15, 16), or a data bus (e.g., the data bus 124).

A “memory” can be referred to by other terms such as a “computer-readable memory,” a “computer-readable medium,” a “computer-readable storage medium,” a “data storage device,” a “memory device,” “computer-readable media,” a “computer-readable database,” “at least one computer-readable medium,” or “one or more computer-readable mediums.” Any of those alternative terms can be preceded by the prefix “transitory” if the memory is transitory or “non-transitory” if the memory is non-transitory. For a memory including multiple memories, two or more of the multiple memories can be the same type of memory or different types of memories.

### C. Transceiver

A transceiver, such as the transceiver 118, the transceiver 58 shown in FIG. 7, or any other transceiver discussed in this description, can include one or more transceivers. Each transceiver includes one or more transmitters operable to transmit data onto a data bus within the computing system (e.g., the VST 3 or the server 6) including the transceiver. Each transceiver includes one or more receivers operable to receive data or a communication carried over a data bus within computing system (e.g., the VST 3 or the server 6) including the transceiver. Unless stated differently, any data described as being transmitted to a device or system is considered to be received by that device or system. Similarly, unless stated differently, any data described as being received from a device or system is considered to be transmitted by that device or system directly or indirectly to the receiving device or system. For some embodiments, a transceiver can include a transmitter and a receiver in a single semiconductor chip. In at least some of those embodiments, the semiconductor chip can include a processor.

For purposes of this description and with respect to a particular vehicle (e.g., the vehicle 4, 32, 71), a network can be operable as a vehicle network, a non-vehicle network, or a multi-purpose network. The vehicle network is at least partly on-board the particular vehicle and has an OBDC and one or more electronic controls units interconnected to the OBDC and/or to each other. In at least some embodiments, the VST 3 includes a harness that operatively connects to the OBDC in the particular vehicle and allows the VST 3 to be disposed outside of the particular vehicle. In those or in other embodiments, the VST 3 is operable to communicate with the OBDC and can be disposed within or outside of the particular vehicle. The non-vehicle network is off-board of the particular vehicle and includes one or more network nodes outside of the particular vehicle. The multi-purpose network is contained at least partly within the particular vehicle and at least partly off-board the particular vehicle. The multi-purpose network can include a vehicle network and a non-vehicle network.

In at least some of the example embodiments, a transmitter, such as a transmitter within any transceiver described in this description, transmits radio signals carrying data, and a receiver, such as a receiver within any transceiver described in this description, receives radio signals carrying data. A transceiver with a radio transmitter and radio receiver can include one or more antennas and can be referred to as a “radio transceiver,” an “RF transceiver,” or a “wireless transceiver.” “RF” represents “radio frequency.”

A radio signal transmitted or received by a radio transceiver can be arranged in accordance with one or more wireless communication standards or protocols such as an Institute of Electrical and Electronics Engineers (IEEE®) standard, such as (i) an IEEE® 802.11 standard for wireless local area networks (wireless LAN) (which is sometimes referred to as a WI-FI® standard) (e.g., 802.11a, 802.11ac, 802.11ad, 802.11ax, 802.11b, 802.11g, or 802.11n), (ii) an IEEE® 802.15 standard (e.g., 802.15.1, 802.15,3, 802.15.4 (ZIGBEE®), or 802.15.5) for wireless personal area networks (PANs), (iii) a BLUETOOTH® version 5.1, 5.2, 5.3, or 5.4 standard developed by the Bluetooth Special Interest Group (SIG) of Kirkland, Washington, (iv) a cellular wireless communication standard such as a long term evolution (LTE) standard, (v) a code division multiple access (CDMA) standard, (vi) an integrated digital enhanced network (IDEN) standard, (vii) a global system for mobile communications (GSM) standard, (viii) a general packet radio service (GPRS) standard, (ix) a universal mobile telecommunications system (UMTS) standard, (x) an enhanced data rates for GSM evolution (EDGE) standard, (xi) a multichannel multipoint distribution service (MMDS) standard, (xii) an International Telecommunication Union (ITU) standard, such as the ITU-T G.9959 standard referred to as the Z-Wave standard, (xiii) a 6LoWPAN standard, (xiv) a Thread networking protocol, (xv) an International Organization for Standardization (ISO/International Electrotechnical Commission (IEC) standard such as the ISO/IEC 18000-3 standard for Near Field Communication (NFC), (xvi) the Sigfox communication standard, (xvii) the Neul communication standard, (xviii) the LoRaWAN communication standard, or (xix) a 5G new radio (5G NR) communication standard by the 3rd Generation Partnership Project (3GPP) standards organization, such as the 5G NR, phase one or 5G NR, phase two communication standard. Other examples of the wireless communication standards or protocols are possible.

In at least some of the embodiments, a transmitter, such as a transmitter within any transceiver described in this description, can be operable to transmit a signal (e.g., one or more signals or one or more electrical waves) carrying or representing data onto an electrical circuit (e.g., one or more electrical circuits). Similarly, a receiver, such as a receiver within any transceiver described in this description, can be operable to receive via an electrical circuit a signal carrying or representing data over the electrical circuit. The electrical circuit can be part of a non-vehicle network, a vehicle network, or a multi-purpose network. The signal carried over an electrical circuit can be arranged in accordance with a wired communication standard such as a Transmission Control Protocol/Internet Protocol (TCP/IP), an IEEE® 802.3 Ethernet communication standard for a LAN, a data over cable service interface specification (DOCSIS standard), such as DOCSIS 4.0, a universal serial bus (USB) specification, such as a USB4 standard, a vehicle data message (VDM) protocol, or some other wired communication standard or protocol. Examples of a VDM protocol are listed in elsewhere in this description. An electrical circuit can include a wire, a printed circuit on a circuit board, and/or a network cable (e.g., a single wire, a twisted pair of wires, a fiber optic cable, a coaxial cable, a wiring harness, a power line, a printed circuit, a CAT5 cable, and/or CAT6 cable). The wire can be referred to as a “conductor”. Transmission of data over the conductor can occur electrically and/or optically.

In accordance with at least some embodiments, the transceiver 118 includes a network a network transceiver (NT) 126 and a vehicle communications transceiver (VCT) 127. The network transceiver is operable to communicate over a non-vehicle network and/or a multi-purpose network. The vehicle communications transceiver is operable to communicate over a vehicle network and/or a multi-purpose network. The transceiver 118, 58 can be operable as a gateway to communicate over a multi-purpose network. The transceiver 118 is configured to communicate over the data bus 124.

In at least some embodiments, the network transceiver includes a modem, a network interface card, a local area network (LAN) on motherboard (LOM), and/or a chip mountable on a circuit board. As an example, the chip can include a CC3100 Wi-Fi® network processor available from Texas Instruments, Dallas, Texas, a CD256MODx Bluetooth® Host Controller Interface (HCl) module available from Texas instruments, or a different chip for communicating via Wi-Fi®, Bluetooth® or another communication protocol.

A network node that is within and/or connected to a non-vehicle network and/or that communicates via a non-vehicle network or a multi-purpose network using a packet-switched technology can be locally configured for a next ‘hop’ in the network (e.g., a device or address where to send data to, and where to expect data from). As an example, a device (e.g., a transceiver) operable for communicating using an IEEE® 802.11 standard can be configured with a network name, a network security type, and a password. Some devices auto-negotiate this information through a discovery mechanism (e.g., a cellular phone technology).

The network transceiver 126 can be arranged to transmit a request and/or receive a response using a transfer protocol, such a hypertext transfer protocol (i.e., HTTP), an HTTP over a secure socket link (SSL) or transport layer security (TLS) (i.e., HTTPS), a file transfer protocol (i.e., FTP), or a simple mail transfer protocol (SMTP). The network transceiver 126 can be arranged to transmit an SMS message using a short message peer-to-peer protocol or using some other protocol.

The data transmitted by the transceiver 118 can include a destination identifier or address of a computing system to which the data is to be transmitted. The data or communication transmitted by the transceiver 118 can include a source identifier or address of the VST 3. The source identifier or address can be used to send a response to the VST 3. As an example, this data or communication can include a user identifier corresponding to a user of the VST 3, credential data corresponding to a user of the VST 3, a VDM, a GUI, or other data instead or as well.

### D. User Interface

In at least some embodiments, the user interface 119 includes a display 128, an input device 129, and/or an output device 130.

The display 128 can include one or more displays. As an example, each display of the one or more displays includes a capacitive touch screen display, a resistive touch screen display, a plasma display, a light emitting diode (LED) display, a cathode ray tube display, an organic light-emitting diode (OLED) display (such as an active-matrix OLED or a passive-matrix OLED), a liquid crystal display (LCD) device (such as include a backlit, color LCD device), a touch screen display with the LCD device, a capacitive touch screen display, or a resistive touch screen display. The display 128 can include a different type of display as well or instead. Each display can include one or more display screens.

In at least some embodiments, the display 128 is affixed (e.g., removably affixed) to a substrate of the housing 121 and/or to the housing 121. In those or in other embodiments, the display 128 is worn and/or within a wearable device, such as a pair of glasses or goggles, a head-mountable display, or a wrist display, such as a wristwatch (e.g., a smartwatch).

The display 128 is operable to display displayable content. Examples of displayable content are provided throughout this application by describing objects displayed by the display 128. As an example, the display 128 is operable to display a GUI, content of a GUI, a USC of a GUI and/or the user interface 119, a test result, a test status, a message, a notification, a configurable function identifier, an indicator of a PID condition, a sub-container, a container, a PID, a parameter value, a PID condition, service information, or some other type of information or data.

The display 128 can also be operable to display a still image (such as a visible light image, a thermal image, and/or a blended image based on a visible light image and a thermal image), a video, a text file (such as a text file with a portable document format (PDF) file extension or an extensible markup language (XML) file extension), a hypertext markup language file, a web page (such as a web page including a search bar and/or a cursor), and/or a GUI. In at least some embodiments, the display 128 is operable to display a horizontal scroll bar and/or a vertical scroll bar. The horizontal scroll bar and the vertical scroll bar can be used to cause the display 128 to display content not currently displayed on the display 128. A web page displayable on the display 128 can include any content shown in or described with respect to any one or more of the GUIs shown in the drawings and/or described in this description. Other examples of content displayable on the display 128 are also possible.

The input device 129 is operable to receive user inputs from a user of the VST 3. As an example, the input device 129 includes a keyboard or keypad including one or more keys operable to be pressed or otherwise manipulated by the user (e.g., a keypad user-selectable control 105 shown in FIG. 8). As another example, the input device 129 includes a microphone operable to receive sound waves, such as sound waves produced by the user speaking words in a vocabulary of the VST 3. In the embodiments in which the display 128 is operable as a touch screen display, the display 128 can receive user inputs from a user of the VST 3, such as a selection of a USC. Accordingly, the input device 129 can include the display 128 when operable as a touch screen display. As another example, the input device 129 can include a camera to capture images (e.g., an image of a user fingerprint, a user face, a vehicle, a vehicle component, a bar code, or a matrix code).

In the embodiments that include the output device 130, the output device 130 can include one or more speakers operable to convert electrical signals to audible sounds. In those or in other embodiments, the output device 130 can include wired headphones and/or wireless headphones. The wired headphones can connect to an audio plug operatively connectable to an audio jack. The wireless headphones can include in-ear headphones, such as the AIRPODS PRO® in-ear headphones by Apple Inc. In the embodiments that include the output device 130, the output device 130 can include the display 128 to display content (e.g., GUIs and service information) output by the processor 116.

### E. Test Device

The test device 120 can include one or more test devices, such as one or more test devices to test the vehicle 4, 32, 71. As an example, the test device 120 can include a meter 131 and/or an oscilloscope 132. The meter 131 can include a port 133 (e.g., one or more ports). The oscilloscope 132 can include a port 134 (e.g., one or more ports). The meter 131 can include a digital volt-ohm meter (DVOM). Additionally or alternatively, the meter 131 can include a current (i.e., amperage) meter (e.g., a current clamp meter). The meter 131 includes and/or is operatively connected to the port 133. The port 133 includes one or more ports for receiving an end of a meter lead. An opposite end of the meter lead is connectable to a component on a vehicle. The oscilloscope 132 can include one or more channels. The port 134 includes a port for each channel of the oscilloscope 132. Each port of the port 134 is operable to receive an end of an oscilloscope test lead. An opposite end of the oscilloscope test lead is connectable to a component on a vehicle.

The meter 131 within and/or part of the VST 3 can include a meter within a particular category (CAT) rating. Popular Cat ratings include CAT I, CAT II, CAT III, and CAT 1V. Meters having a CAT III or CAT IV rating can be more suitable for some high voltage circumstances as compared to meters having a CAT I or CAT II rating. The VST 3 can include a CAT III or CAT IV meter if the component test 141 includes one or more guided component tests for high voltage components or for some other reason.

Similarly, the oscilloscope 132 within and/or part of the VST 3 can include an oscilloscope within a particular category (CAT) rating. Popular Cat ratings include CAT I, CAT II, CAT III, and CAT 1V. Oscilloscope having a CAT III or CAT IV rating can be more suitable for some high voltage circumstances as compared to meters having a CAT I or CAT II rating. The VST 3 can include a CAT III or CAT IV oscilloscope if the component test 141 includes one or more guided component tests for high voltage components or for some other reason.

Additionally, the test device 120 can include one or more of the following: an analog-to-digital converter (ADC) 135, a probe 136, and a signal generator 137. The signal generator 137 can output a signal onto a meter lead connected to the port 133 and/or onto an oscilloscope test lead connected to the port 134. The output signal can be used to measure a signal. For instance, the signal generator 137 can output a voltage differential across two meter leads connected to the port 133 (e.g., a red meter lead and a black meter lead) and onto a circuit for use in measuring a resistance of the circuit. The ADC 135 can be operable to convert an analog signal received via a meter lead or an oscilloscope test lead into a digital signal. A digital signal representing a signal detected by the ADC 135 can be output onto the data bus 124 for transmission to the processor 116.

The probe 136 can include one or more probes. As an example, the probe 136 can include a temperature probe, such as a temperature probe including a thermocouple and a connector connectable to the port 133, 134, and/or a temperature adaptor and probe, item EEDMTEMP-1 available from Snap-on Incorporated, Kenosha, Wisconsin. As another example, the probe 136 can include a pressure probe, such a pressure adaptor for digital multimeter, item EEDM5030, available from Snap-on Incorporated, a pressure transducer and cable, item EEPV302AT, or a pressure transducer adaptor, item EEMS324PSA, each available from Snap-on Incorporated. As another example, the probe 136 can include an exhaust probe, such as a standard exhaust probe, item HHGA-7; a 5-gas exhaust probe, item HHGA-9; or a motorcycle exhaust probe, item HHGA-8; each of which is available from Snap-on Incorporated. As yet another example, a probe can include an air velocity and temperature probe, such as a wireless air velocity vane probe, item TPI-555, available Test Products International Inc., Beaverton, Oregon. As still yet another example, a probe can include a current clamp meter.

### F. Additional Components

A power supply, such as the power supply 122, a power supply 63 shown in FIG. 7, or any other power supply discussed in this description, can be arranged in any of a variety of configurations. As an example, the power supply can be operable to include circuitry to receive AC current from an AC electrical supply (e.g., electrical circuits operatively connected to an electrical wall outlet) and convert the AC current to a DC current for supplying to one or more from among the components connected to the power supply. As another example, the power supply can be operable to include a battery or be battery operated. As yet another example, the power supply can be operable to include a solar cell or be solar operated. Moreover, a power supply can be operable to include and/or connect to a power distribution circuit to distribute electrical current throughout the device or system including that power supply. In at least some embodiments of the VST 3, the power distribution circuit includes the electric circuit 125 (i.e., one or more electrical circuits) that connects to the processor 116, the memory 117, the transceiver 118, the user interface 119 the test device 120, and/or the vehicle connector 123. Other examples of a power supply are also possible.

In at least some embodiments, the housing 121 surrounds at least a portion of the following: the processor 116, the memory 117, the transceiver 118, the user interface 119, the test device 120, the power supply 122, the vehicle connector 123, the data bus 124, and/or the electric circuit 125. The housing 121 can support a substrate, such as a printed circuit board. In at least some example embodiments, at least a portion of the following: the processor 116, the memory 117, the transceiver 118, the user interface 119, the power supply 122, the vehicle connector 123, the data bus 124, and/or the electric circuit 125 is/are mounted on and/or connected to a substrate of the housing 121. The housing 121 can be made from various materials. For example, the housing 121 can be made from a plastic material (e.g., acrylonitrile butadiene styrene (ABS)) and a thermoplastic elastomer used to form a grip on the housing 121.

The vehicle connector 123 includes one or more vehicle connectors connectable to a vehicle, such as the vehicle 4, 32, 71. The vehicle connector 123 can include a vehicle connector configured to connect to an OBDC. The vehicle connector 123 can include a dongle, such as the dongle 18 shown in FIG. 2.

### G. Memory Content

The example embodiments can determine, generate, store (e.g., write into a memory), transmit, read, receive, and/or otherwise use a variety of computer-readable data. At least some of the computer-readable data can be stored in a memory, such as the memory 117, 57.

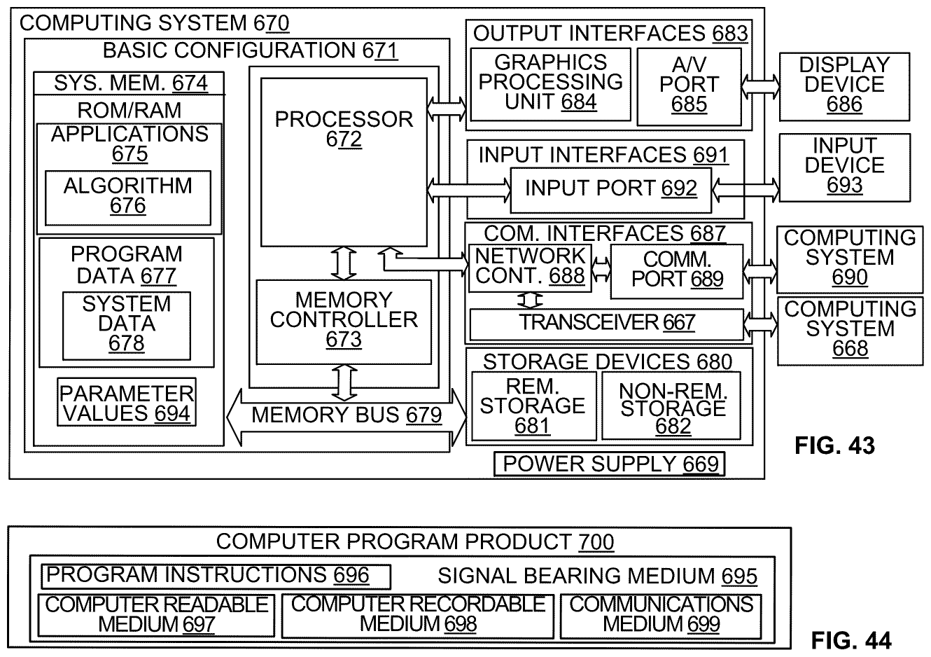

As an example, the memory 117 contains computer-readable programming instructions (CRPI) 138, a module 139 (i.e., one or more modules), a GUI 140 (i.e., one or more GUI), a component test 141 (i.e., one or more component tests), vehicle selection data 142, a vehicle data message 143 (i.e., one or more VDMs or data for generating one or more VDMs), an application 144, thresholds 145, output rates 146, parameter values 147, and test results 148. Additionally, the memory 117 can contain any of the content within the system memory 674 shown in FIG. 43 and/or within the computer program product 700 shown in FIG. 44.

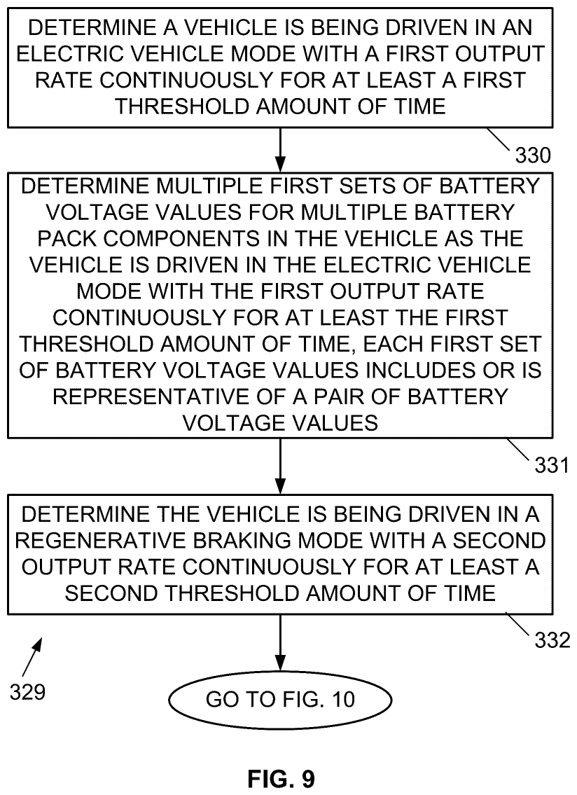

The CRPI 138 can include program instructions executable by a processor, such as the processor 116. As an example, the CRPI 138 can include program instructions that are executable to cause the VST 3 to perform any function described as being performed by the VST 3, by the processor 116, and/or by some other component of the VST 3. As an example, the CRPI 138 can include program instructions executable by the processor to perform any one or more or all functions shown in FIG. 9 to FIG. 22. In at least some embodiments, the CRPI 138 can include the module 139. In at least some embodiments, the module 139 includes at least a portion of the CRPI 138.

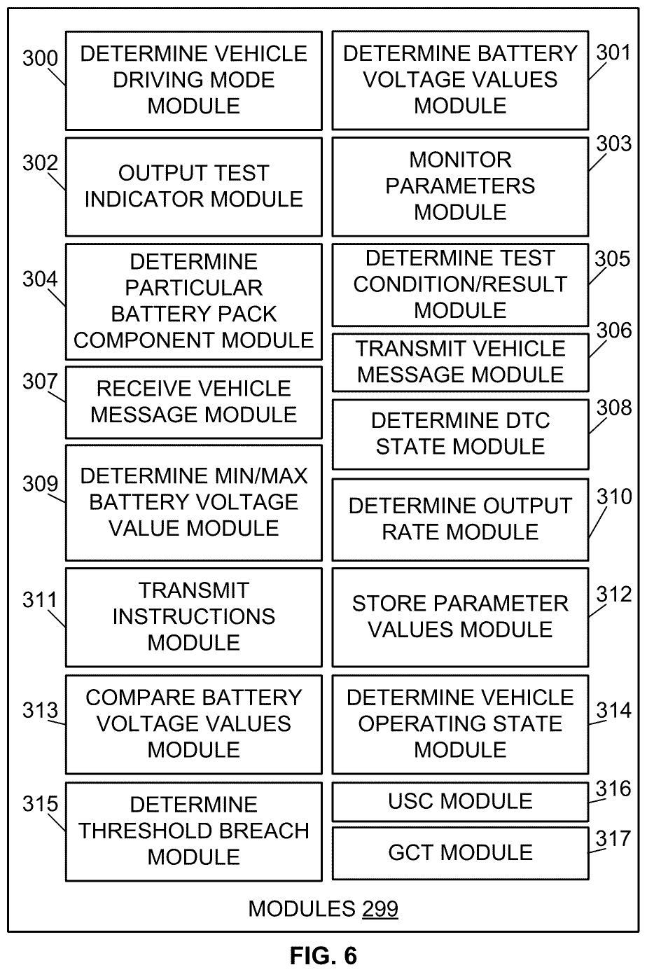

The module 139 can include one or more modules. Examples of modules within the module 139 are shown in FIG. 6. In at least some embodiments, multiple modules are arranged as an application. In accordance with at least some of those embodiments, that application can include the application 144.

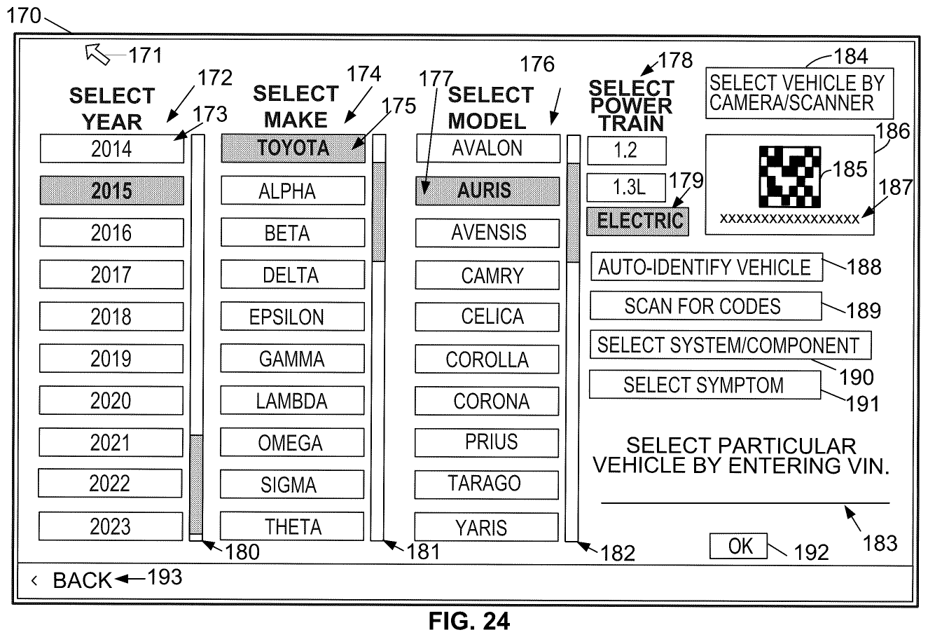

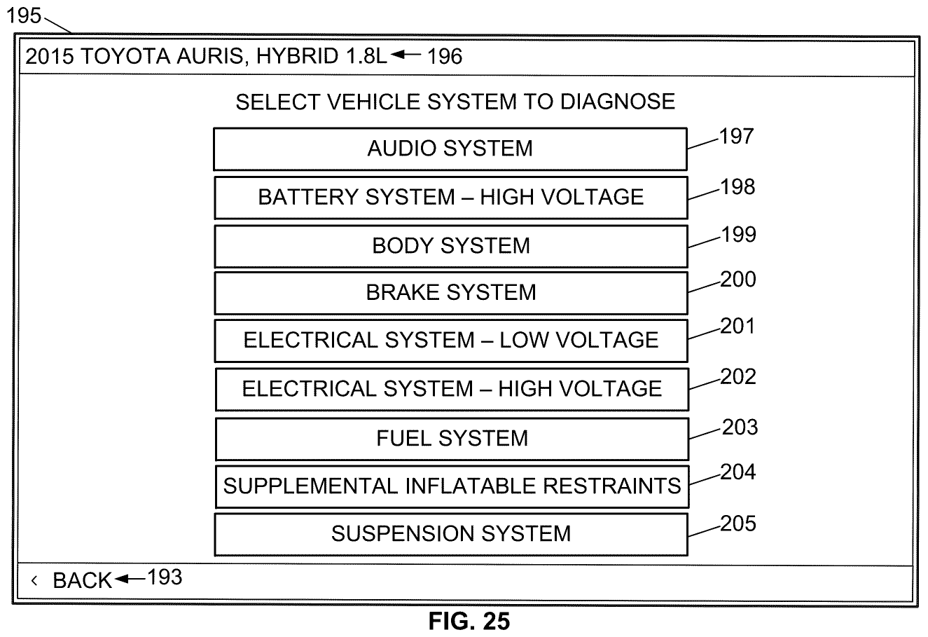

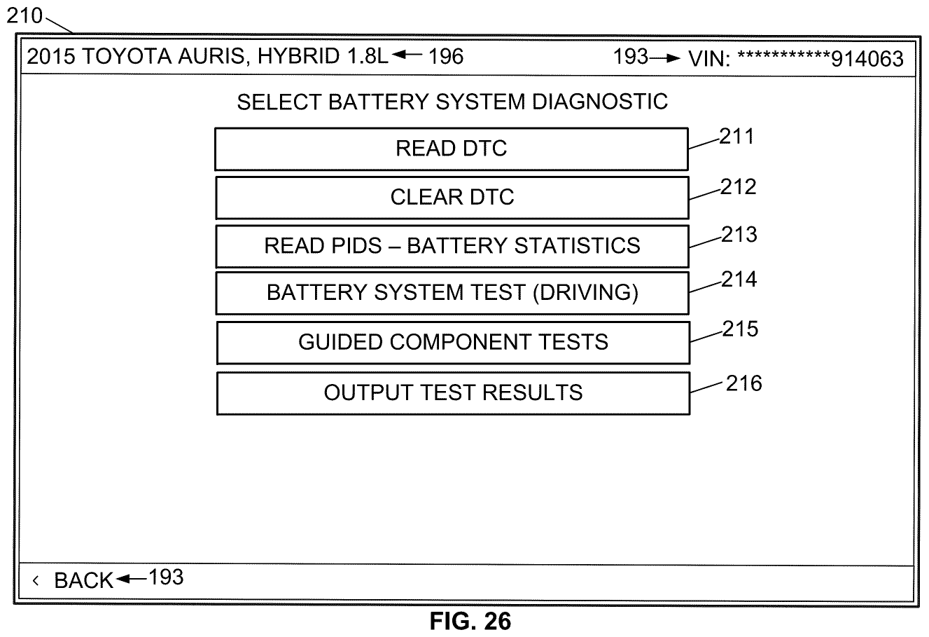

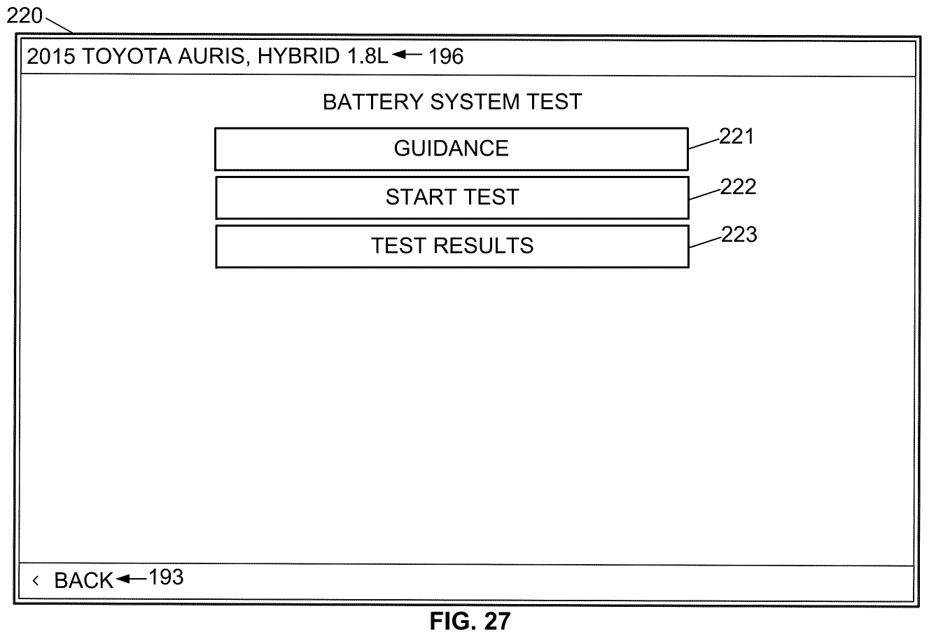

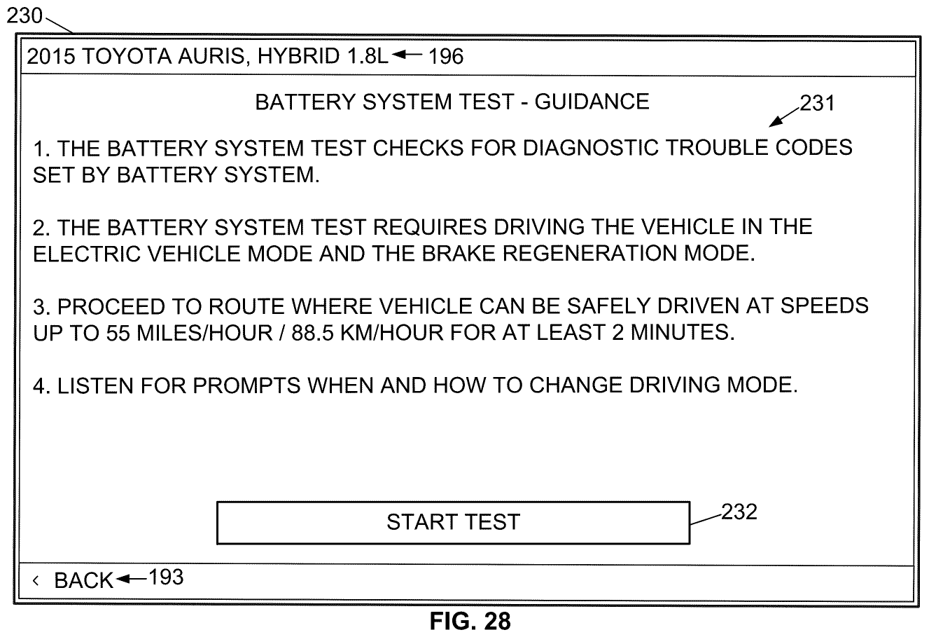

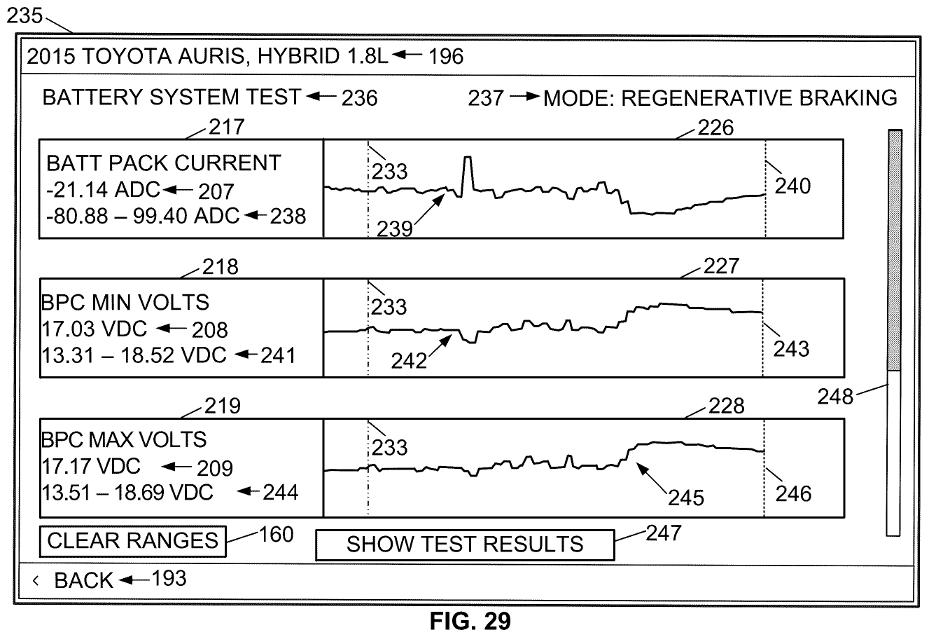

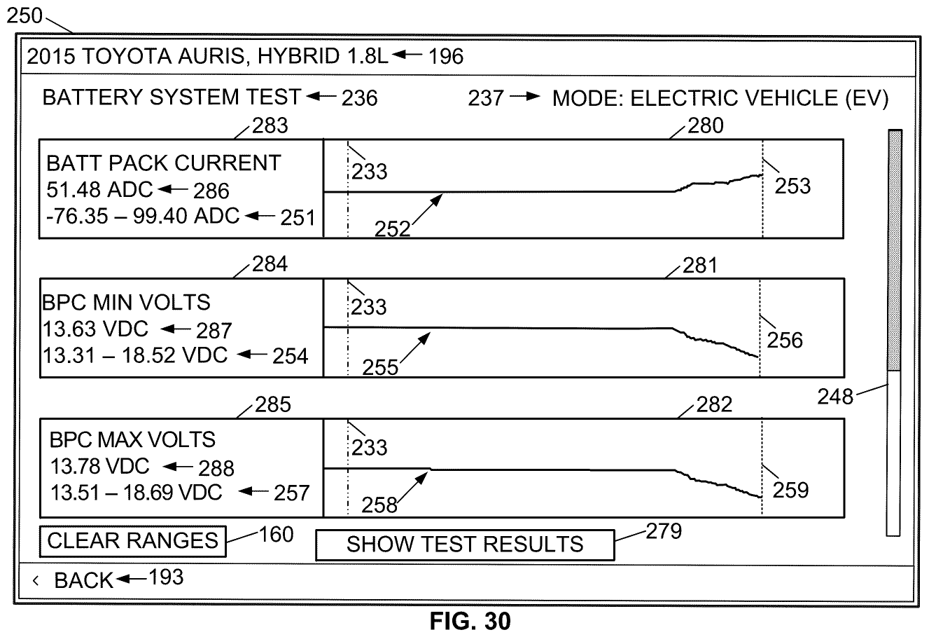

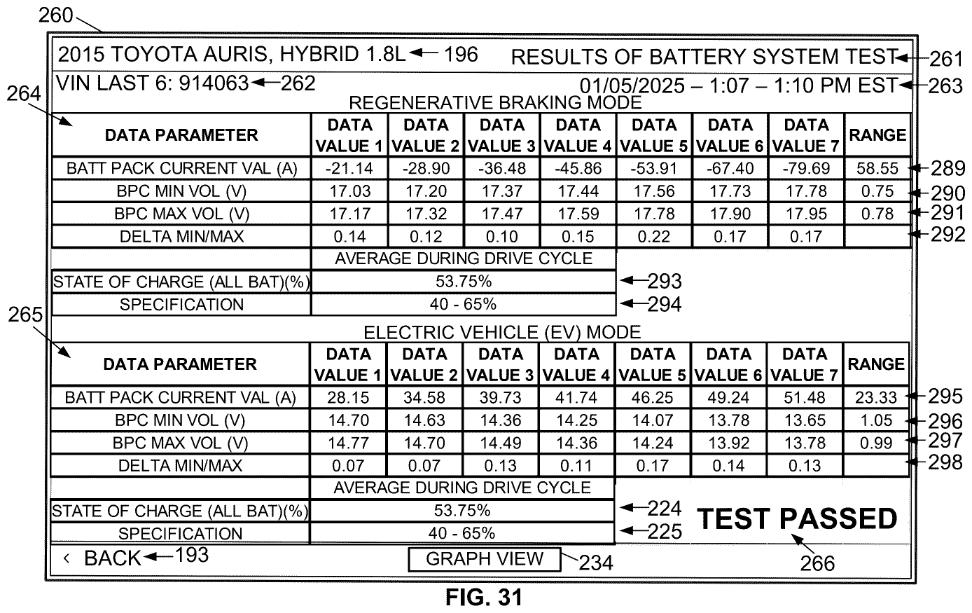

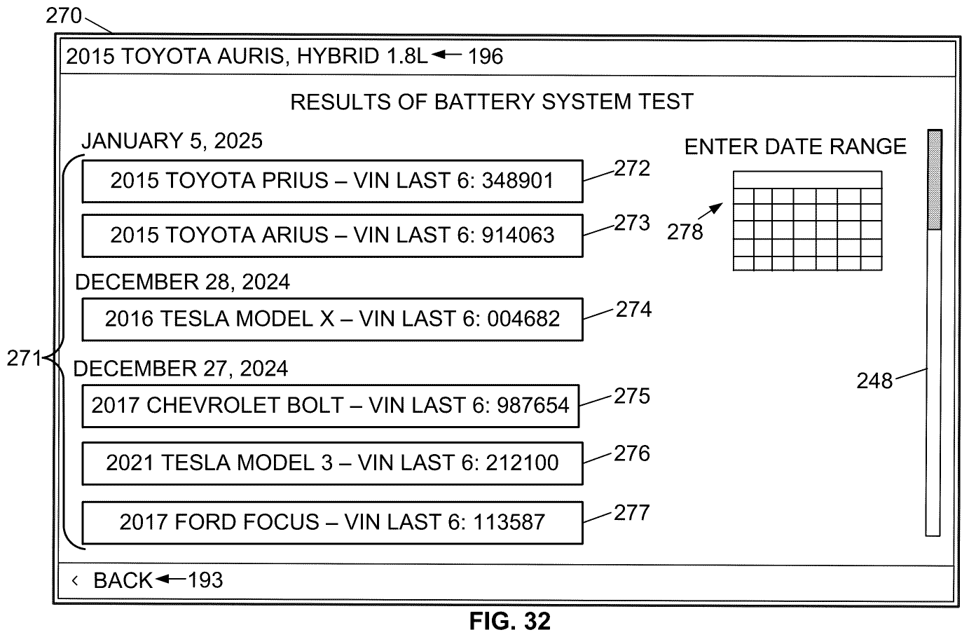

The GUI 140 can include one or more GUIs and/or data for generating one or more GUIs. In at least some embodiments, the GUI 140 includes a GUI transmitted to the VST 3 from the server 6. Examples of a GUI contained within and/or generated based on data contained within the GUI 140 are shown in FIG. 24 to FIG. 38. In at least some embodiments, each GUI corresponds to one or more types of vehicles, one or more systems, one or more vehicle components, one or more symptoms, and/or one or more DTCs. In at least some embodiments, a GUI is populated with vehicle identifying information regarding one or more types of vehicles and/or USCs corresponding to one or more systems or vehicle components. The GUI 140 can include a data map that indicates which type(s) of vehicle(s), vehicle system(s), vehicle component(s), symptoms, or DTCs corresponds to a GUI. The processor can determine the GUI based on the mapping data and data indicative of the type(s) of vehicle(s), system(s), vehicle component(s), symptom(s) or DTC(s).

The component test 141 can include one or more component tests, such as one or more guided component tests. Each component test can include computer-readable program instructions executable to perform the component test. Execution of a component test module can include configuring a test device for performing the component test for the component and/or vehicle to be tested. As an example, a component test can include a voltage test, an amperage test, a frequency test, a resistance test, a duty cycle test, or a pressure test. As another example, a component test can be specified for a particular component, such as a fuel pump voltage test or a fuel pump pressure test. As yet another example, a component test can be specified for a particular vehicle on a particular vehicle, such as a fuel pump voltage test on a 2018 Jeep Cherokee (4WD) with 3.6 L engine, or a fuel pump pressure test on a 2018 Jeep Cherokee (4WD) with a 3.6 L engine.

A guided component test can include a component test performed by the test device 120 (e.g., a test performed by the meter 131 or the oscilloscope 132). The guided component test can include one or more setup instructions executable by the processor 116 or the test device 120 to configure the meter 131 or the oscilloscope 132 to perform a particular component test. As an example, the setup instructions can include an instruction for the processor to select the meter 131 or the oscilloscope 132. As another example, the setup instructions can include an instruction to put the meter 131 in a particular measurement mode (e.g., a voltage measurement mode, a current measurement mode, or a resistance measurement mode). As another example, the setup instructions can include an instruction to configure the oscilloscope 132 with a particular display setting, such as a particular sweep rate or volts per division. As yet another example, the setup instructions can include an instruction to configure the oscilloscope 132 with a particular trigger mode.

A guided component test can also include test instructions. As an example, the test instructions can include an instruction to sample input signals received at the test device 120. The instruction to sample input signals can be based on whether the guided component test is for measuring a direct current signal or an alternating current signal. Such instruction can specify a sampling rate for sampling the input signals. As another example, the test instructions can include an instruction for storing the input signal samples in a memory. As yet another example, the test instructions can include an instruction to output a representation of the input signal samples on a display. In accordance with embodiments in which the test device 120, the meter 131 or the oscilloscope 132 is remote from the VST 3, the setup instructions and the test instructions can include an instruction for establishing a communication link between the VST 3 and the test device 120, the meter 131, or the oscilloscope 132 and instruction for transmitting or receiving a communication corresponding to a guided component test via the communication link.

In at least some embodiments, the guided component test includes displayable information, such as test procedures, test device connection guidance, connector views, a graph showing a known good waveform for a component corresponding to the guided component test, a graph showing a known bad waveform for a particular component corresponding to the guided component test, or expected test results.

In at least some embodiments, the guided component test includes a component test specified to be performed using a meter or oscilloscope having a CAT III or CAT IV rating. As an example, the guided component test can include a high voltage battery pack measurement with the meter or oscilloscope set automatically by the VST 3 for a particular measurement range, such as 300 VDC to 800 VDC. As another example, the guided component test can include a high voltage battery pack measurement with the meter or oscilloscope manually set for a particular measurement range, such as 300 VDC to 800 VDC.

In at least some embodiments, the component test 141 includes multiple sets of test device configuration parameters and each set of test device configuration parameters is associated with an index value. The server 6 can determine which set of device configuration parameters is to be used to set up the test device 120 for performing a test of a vehicle component. The server can transmit the determined set of test device configuration parameters to the VST 3. Alternatively, the server 6 can transmit an index value associated with the determined set of test device configuration parameters to the VST 3. In this alternative arrangement, the computing system can determine the appropriate test device configuration parameters for the vehicle ID session based on the index value received at the VST 3. Table A shows example categories of component tests and example component tests. The current probe tests can be performed with a current probe connectable to the test device 120. The two-channel tests are configured to measure or compare two signals. The transducer tests can be performed using a transducer connected to the test device 120. A component test can also include a voltage test.

TABLE A

| Component Test Category | Component Test |
|---|---|
| Current probe test | Fuel injector current ramp |
| Current probe test | Fuel pump current ramp |
| Current probe test | Fuel pump RPM calculation |
| Current probe test | Ignition coil current ramp |
| Current probe test | Parasitic draw |
| Two-channel test | CAN-bus high low |
| Two-channel test | Crankshaft and camshaft relationship |
| Two-channel test | EGR solenoid and position sensor |
| Two-channel test | EVAP solenoid and diagnostic switch |
| Two-channel test | FlexRay bus |
| Two-channel test | Injector and oxygen sensor |
| Two-channel test | Knock sensor and EST |
| Two-channel test | MC dwell and oxygen sensor |
| Two-channel test | Pre and post cat oxygen sensors |
| Two-channel test | Throttle positions 1 & 2 |
| Two-channel test | Wheel speed sensor (Hall effect type) |
| Transducer test | A/T line pressure and shift solenoid |
| Transducer test | A/T line pressure test |
| Transducer test | EGR temperature sensor and EGR valve |
| Transducer test | Exhaust back pressure test |
| Transducer test | Fuel pressure and fuel pump current |
| Transducer test | Fuel pressure and fuel pump voltage |
| Transducer test | Fuel pressure test |

The vehicle selection data 142 can include one or more vehicle selection menus or data for generating the one or more vehicle selection menus that can be output on and/or within a GUI of the GUI 140. The processor 116 can output a vehicle selection menu on the display 128 to allow a user to select a type of vehicle or a particular vehicle. The vehicle selection data 142 can also include data that represents relationships between vehicle model years and the types of vehicles that were built for and/or during each model year. For instance, for a given model year, the vehicle selection data 142 can include data that indicates all vehicle makes that include at least one type of vehicle for the given model year, and for each of those vehicle makes, the vehicle selection data 142 can include data that indicates all vehicle models that correspond to one of the vehicle makes that built at least one type of vehicle for the given model year. FIG. 25 and other figures show a vehicle identifier 196 within a GUI. In at least some embodiments, the vehicle identifier 196 can be output on the GUI based on selections made using one or more vehicle selection menus based on the vehicle selection data 142. As an example, at least a portion of the vehicle selection data 142 can be output on and/or within a GUI, such as the GUI 170 shown in FIG. 24.

The vehicle data message 143 includes one or more vehicle data messages (VDMs) and/or data to generate the one or more VDMs to be transmitted by the VST 3. A VDM within the vehicle data message 143 can include a VDM received by the vehicle communications transceiver 127. A VDM within the vehicle data message 143 can include a VDM that is to be or has been transmitted by the VST 3. The vehicle data message 143 can include a message map for decoding a VDM received by the VST 3 and/or for encoding a VDM that is to be transmitted by the VST 3. The message map can include a formula for converting data in one or more fields of a VDM to a value represented by the one or more fields. The message map can indicate which field in the VDM is a PID and which field(s) are a PID parameter value. The message map can include a textual description corresponding to each PID so that the processor can know which container or sub-container including PID is to be populated with the textual description and a parameter value corresponding to the PID. As an example, the fields can represent a battery voltage, a battery temperature, a battery state-of-charge percentage, a battery pack current, a maximum battery voltage, a minimum battery voltage, or any PID represented within a GUI, such as the GUI 235, 250, 260 shown in FIG. 29 to FIG. 31.

The vehicle data message 143 can include one or more buffers to store PIDs and corresponding parameter values. In at least some embodiments, the buffer(s) store the PIDs and corresponding parameter values in a first in, first out (FIFO) format. The processor can read parameter values from the buffer and output the parameter values within a GUI to show a historical representation of the parameter values.

The vehicle data message 143 can include commands 150 can include a PID command 151 (i.e., one or more PID commands), a functional test command 152 (i.e., one or more functional test commands), and a reset procedure command 153 (i.e., one or more reset procedure commands). A PID command can include a PID. A functional test command can include an identifier of a functional test. A reset procedure command can include an identifier of a reset procedure. An identifier of a PID, a functional test identifier, a reset identifier, a component test identifier can be included within mapping data or an index described in this description.

The PID command 151 includes data that indicates how a VDM should be arranged to request a PID parameter value from the vehicle 4 for a particular PID. As an example, the PID command 151 can indicate a particular VDM protocol that is to be used to generate the VDM. As another example, the PID command 151 can include an ECU identifier of the ECU from which the PID parameter value is to be requested. As yet another example, the PID command 151 can include the PID. The processor 116 can determine the PID command 151 based on an index value corresponding to a PID. The PID command 151 can include a PID group identifier for one or more PIDs so that the processor 116 can determine which PIDs belong to a PID group and can populate a container with PID data regarding PIDs in the PID group.

As an example, a VDM can be arranged as $07 $DF $02 $01 $31 $42 $00 $00 $00 $00. In that example VDM, the fifth byte is the PID, the sixth byte is a parameter value. In at least some embodiments, the PID command 151 includes formulas for converting a PID parameter value to a value represented by the PID parameter value. Unless the context indicates otherwise, the use of the term PID value refers to the PID parameter value corresponding to a PID rather than to the numerical value that represents the PID itself.

The functional test command 152 includes data that indicates how a VDM should be arranged for requesting the vehicle 4 to perform a particular functional test. As an example, the functional test command 152 can indicate a particular VDM protocol that is to be used to generate the VDM. As another example, the functional test command 152 can include an ECU identifier of the ECU that is configured to perform the functional test. As yet another example, the functional test command 152 can include the functional test identifier. The processor 116 can determine the functional test command 152 based on an index value corresponding to a functional test identifier. One or more functional test commands can correspond to a notification the processor 116 outputs on the display 128 before the processor 116 transmits the functional test command. As an example, the notification can include a safety alert, or a set-up instruction.

Additionally or alternatively, the processor 116 can determine the functional test command 152 based on a menu selection and program code or data that corresponds to the menu selection. The processor 116 can use data indicating a VDM protocol to determine which VCT of multiple VCTs is to be used to transmit a functional test command and/or the format for generating a VDM including the functional test command.

The reset procedure command 153 includes data that indicates how a VDM should be arranged for requesting the vehicle 4 to perform a particular reset procedure. As an example, the reset procedure command 153 can indicate a particular VDM protocol that is to be used to generate the VDM. As another example, the reset procedure command 153 can include an ECU identifier of the ECU that is configured to perform the reset procedure. As yet another example, the reset procedure command 153 can include the reset procedure identifier. The processor 116 can determine the reset procedure command 153 based on an index value corresponding to a reset procedure identifier. As an example, performing a reset procedure can include modifying a setting within an ECU (e.g., a setting that indicates the oil life setting is 100%, resetting an advanced driver assistance system (ADAS) component after a vehicle collision, or resetting a fuel injector).

As for particular commands, a reset procedure command can include a command to reset a high voltage interlock (HVIL) circuit or system on the vehicle. As another example, a reset procedure command can include a command to reset a BMS within the vehicle. This reset procedure command is required in some vehicles after replacing a battery pack component or making some other repair. As yet another example, a reset procedure command can include a command to reset an electric powertrain component (e.g., an inverter or motor). As still yet another example, a reset procedure command can include a command to reset a charging system within the vehicle. As still yet another example, a reset procedure command can include a command to reset a thermal management system component in the battery system within the vehicle.

The reset procedure command 153 can include other reset procedure commands as well or in addition to the example commands listed above. For example, the reset procedure command can include commands for reprogramming an ECU within the vehicle. For instance, reprogramming the ECU can include flash programming a software calibration file into the ECU and/or flash programming an ECU according to SAE standard J2534. In at least some embodiments, performing the reset can include scanning a matrix code (e.g., a QR code), decoding the matrix code, requesting a software download for a component that is to be reprogrammed, receiving the software download, and reprogramming the component with the software download. As another example, a reset procedure command can include a command to reset or re-zero a sensor, such as a steering wheel angle sensor, or commands to reset an angle or height of a headlight in the vehicle.

The application 144 can include one or more applications. As an example, the application 144 can include a browser application. As another example, the application 144 can include an application with an application programming interface (API), such as an API configured to transmit a list identifier to a server and to receive a group of diagnostic descriptors.

The application 144 can include and/or execute in conjunction with one or more application drivers. If the application driver(s) are considered to be distinct from an application, then the CRPI 138 can include the application driver. Each application driver can include CRPI that are executable for an application and a device to communicate with each other. As an example, the device can include the display 128 arranged as a touch screen display and the application driver can translate electrical signals resulting from a user contacting the display 128 to a digital value corresponding to an area of the display 128 where the user contact occurred. If the contacted area corresponds to a USC or a portion of a USC, the processor can determine the USC has been selected based on the application driver outputting the digital value.

The thresholds 145 can include multiple thresholds for use during a test of a vehicle battery system. As an example, the thresholds can include multiple thresholds for one or more different types of vehicles having a battery system that can be tested using the VST 3. In at least some embodiments, the VST 3 requests thresholds from the server 6 when those thresholds are needed to test a battery system of a vehicle selected to be tested. In at least some embodiments, the memory 117 contains thresholds for multiple different types of vehicles, including the vehicle selected to be tested, such that the VST 3 does not have to request the thresholds prior to testing the selected vehicle.

As another example, the thresholds 145 can include threshold amounts of time for use in determining whether the vehicle 4, 32, 71 has been driven in a particular driving mode (e.g., an EV driving mode or a regeneration braking mode) for a sufficient amount of time for testing the battery system within the vehicle.

As yet another example, the thresholds 145 can include a threshold amount of time that equals an amount of time it takes for a battery voltage of a particular battery pack component (e.g., a battery block, a battery pack module, a string, or a cell) to decay by a threshold percentage of the maximum battery voltage while the vehicle is being driven in the electric vehicle mode with a particular output rate.

As still yet another example, the thresholds 145 can include a voltage comparison threshold for comparing to differences in pairs of battery voltage values determined from battery voltage values obtained while the vehicle is driven in the electric vehicle mode with a particular output rate. If the differences exceed the voltage comparison threshold, a processor can determine one or more battery pack components in the multiple battery pack component should be replaced.

As a further example, the thresholds 145 can include electrical current thresholds, such as first and second electrical current thresholds for comparison to parameter values that indicate electrical current within a circuit of the vehicle. Parameter values that exceed those electrical current thresholds can indicate that the vehicle is being driven in the EV mode or the regenerative braking mode. As an example, the vehicle circuit can include a power bus that connects a battery pack to an inverter within the vehicle 4, 32, 71.

The output rates 146 can include multiple output rates for use during a test of vehicle battery system. As an example, the output rates can include multiple output rates for one or more different types of vehicles having a battery system that can be tested using the VST 3. In at least some embodiments, the VST 3 requests output rates from the server 6 when those output rates are needed to test a battery system of a vehicle selected to be tested. In at least some embodiments, the memory 117 contains output rates for multiple different types of vehicles, including the vehicle selected to be tested, such that the VST 3 does not have to request the output rates prior to testing the selected vehicle. The output rates can indicate an amount of current flowing in a bus connected to a battery pack. The output rates can indicate a range of currents flowing in the bus.

The parameter values 147 can include raw data values contained within vehicle data messages received by execution of a receive vehicle message module 307 and/or stored by execution of the store parameter values module 312 (both shown in FIG. 6). The parameter values 147 can include metadata regarding battery data values stored therein. As an example, the metadata can include a time stamp, such as a time stamp indicating when a battery data value was received or stored. As another example, the metadata can include a string identifier, a battery pack module identifier, or a cell identifier indicating which string, battery pack module, or cell of a battery pack that corresponds to the battery data value. As yet another example, the metadata can include a vehicle identifier corresponding to a vehicle that includes the battery whose string, battery pack module, or cell was measured to obtain the battery data value. As still yet another example, the metadata can include a comparison indicator, such a comparison indicator that indicates a battery voltage value is a maximum voltage value for a particular time frame or a battery voltage value is a minimum voltage value for a particular time frame. Other examples of the metadata are also possible.

The parameter values 147 can include current values, such as current values that indicate how much current and a direction of current within an electrical circuit, such as a bus connected to a battery pack, an inverter or a motor. In at least some embodiments, the current values are obtained from vehicle messages. In at least some other embodiments, the current values are obtained from a current clamp meter operatively coupled to the VST 3.

The parameter values 147 can includes other parameter values obtained while testing a battery including parameter values obtained while determining whether a vehicle is in an electric vehicle mode or a regenerative braking mode. As an example, the parameter values 147 can include battery temperature parameter values or state-of-charge parameter values.

The test results 148 can include test results for one or more battery tests performed on a vehicle battery system. The test results can be for one or more different vehicles. The processor 116 can upload test results to the server 6 for subsequent retrieval by the VST that performed the battery test or a different VST or computing system configured to display the test results. The VST 3 is configured to display test results (e.g., in GUI, such as the GUI 260 shown in FIG. 31 or the GUI 460 shown in FIG. 33). The VST 3 can display a GUI, such as the GUI 270 shown in FIG. 32, to allow a user to select from different test results and/or to search for test results.

The test results 148 can include calculated values. As an example, the calculated values can include a range of a battery pack current measured during a test, a range of battery pack component minimum voltages measured during a test, a range of battery pack component maximum voltages measured during a test, and delta values indicating differences between battery pack component minimum and maximum voltages. As another example, the calculated values can include a state-of-charge percentage. The test results 148 can include a state-of-charge specification for comparison to the state-of-charge percentage. The test results 148 can include data indicating a determined result of the test, such as test passed, test failed, or test inconclusive.

### H. Example Modules

Next FIG. 6 shows a module set 299 (e.g., a set of modules). The module 139 shown in FIG. 5 and/or a module 98 shown in FIG. 7 can include any one or more or all modules of the module set 299. The module set 299 includes a determine vehicle driving mode module 300, a determine battery voltage values module 301, an output test indicator module 302, a monitor parameters module 3023, a determine particular battery pack component module 304, a determine test condition/result module 305, a transmit vehicle message module 306, a receive vehicle message module 307, a determine DTC state module 308, a determine min/max battery voltage value module 309, a determine output rate module 310, a transmit instructions module 311, a store parameter values module 312, a compare battery voltage values module 313, a determine vehicle operating state module 314, a determine threshold breach module 315, a USC module 316, and a guided component test (GCT) module 317. A logic segment, such as the logic segment 115, and/or a processor, such as the processor 116, can execute any one or more or all modules of the module set 299. In that regard, any functionality described with respect to a module of the module set 299 can include functionality performed by the logic segment and/or the processor. An input to any module of the module set 299 can be output to one or more other modules of the module set 299. Data indicative of a determination or calculation made by any module of the module set can be output to one or more other modules of the module set 299.

### 1) Determine Vehicle Driving Mode Module

The determine vehicle driving mode module 300 can be configured to determine a driving mode in which a vehicle is being driven. The vehicle can comprise a vehicle being driven by a human being. The vehicle can comprise a vehicle being driven autonomously. The vehicle can be configured like any vehicle described in this description and/or shown in the drawings. For example, the vehicle can include an electric or hybrid vehicle. The vehicle can include a battery pack with multiple battery pack components (i.e., BPCs) containing multiple battery strings, battery pack modules, or cells.

The processor 116 can transmit one or more VDMs with one or more PIDs to the vehicle to request parameter values from the vehicle. The parameter values represent a current value, such as current value of an electrical circuit (e.g., the bus 90 connected to the battery pack 78 or the bus 95 connected to the battery pack 92). The current value can be positive or negative. The determine vehicle driving mode module 300 can be configured to determine whether the current flowing in the electrical circuit connected to the battery is equal to or exceeds a threshold current corresponding to a driving mode.

As an example, the determine vehicle driving mode module 300 can be configured to determine a vehicle is being driven in an electric vehicle mode with a first output rate continuously for at least a first threshold amount of time. The first output rate can be any positive current equal to or more positive (i.e., greater than) a positive threshold current.

As another example, the determine vehicle driving mode module 300 can be configured to determine the vehicle is being driven in a regenerative braking mode with a second output rate continuously for at least a second threshold amount of time. The second output rate can be any negative current equal to or more negative (i.e., less than) than a negative threshold current.

A threshold amount of time, such as the first and second threshold amounts of time, can be specified within program instructions. Alternatively, the threshold amounts of time can be stored in a memory and read by a processor when executing program instructions to determine a driving mode, and/or as part of executing the determine vehicle driving mode module 300.

An output rate, such as the first and second output rates, can be specified within program instructions. Alternatively, the output rates can be stored in a memory and read by a processor when executing program instructions to determine a driving mode, and/or as part of executing the determine vehicle driving mode module 300.

As another example, the first threshold amount of time can equal an amount of time it takes for a battery voltage of a particular battery pack component (e.g., a battery block, a battery pack module, a string or a cell) to decay by a threshold percentage of the maximum battery voltage while the vehicle is being driven in the electric vehicle mode with the first output rate. The particular battery pack component can be a battery pack component in the multiple pack components having a maximum battery voltage compared to the battery voltage of each of the other battery pack component in the battery. The particular battery pack component can be determined by execution of the determine particular battery pack component module 304.

The determine vehicle driving mode module 300 can be configured to determine a vehicle identifier corresponding to the vehicle and determine the first and second output rates and the first and second threshold amounts of time based on the vehicle identifier.

The determine vehicle driving mode module 300 can be configured to output a notification to guide a driver of the vehicle how to drive the vehicle. As an example, the notification can be output via the display 128 and/or output device 130 (both shown in FIG. 5). As another example, the notification can indicate an approximate distance needed to drive the vehicle during the test drive and a speed range expected to be reached during the test drive. As yet another example, the notification can indicate an output rate needed for the test has not been achieved continuously for a threshold amount of time and that some portion of the test drive needs to be repeated and/or started again.

The determine vehicle driving mode module 300 can be configured to determine the vehicle is driven in the electric vehicle mode with the first output rate continuously for at least the first threshold amount of time, and then determine the vehicle is being driven in the regenerative braking mode with the second output rate continuously for at least the second threshold amount of time. Accordingly, determining the multiple first sets of battery voltage values for multiple battery pack components in the vehicle as the vehicle is driven in the electric vehicle mode with the first output rate can occur before determining the vehicle is being driven in the regenerative braking mode.

Alternatively, determine vehicle driving mode module 300 can be configured to determine the vehicle is being driven in the regenerative braking mode with the second output rate continuously for at least the second threshold amount of time, and then determine the vehicle is driven in the electric vehicle mode with the first output rate continuously for at least the first threshold amount of time. Accordingly, determining the multiple first sets of battery voltage values for multiple battery pack components in the vehicle as the vehicle is driven in the electric vehicle mode with the first output rate occurs after determining the vehicle is being driven in the regenerative braking mode.

The determine vehicle driving mode module 300 can be configured to request execution of the determine DTC state module 308 to determine whether any DTCs corresponding to a component of the battery system within the vehicle is set active. In at least some embodiments, if such DTC is set active, the determine vehicle driving mode module 300 can be configured to output a notification indicating the determine vehicle driving mode module 300 will not proceed with determining the driving mode until the DTC is inactive. In other embodiments, if such DTC is set active, the determine vehicle driving mode module 300 can be configured to output a notification indicating the determine vehicle driving mode module 300 will determine the driving mode, but will flag such DTC active for reporting along with a test result.

The determine vehicle driving mode module 300 can be configured to a vehicle driving mode (e.g., the electric vehicle mode or the regenerative braking mode) based on parameters monitored by execution of the monitor parameters module 303. Those parameters can be determined from VDMs and/or from a current clamp meter.

In accordance with at least some embodiments, the determine vehicle driving mode module 300 can be configured to determine the vehicle is being driven in the electric vehicle mode with the first output rate continuously for at least the first threshold amount of time based on determining a first set of parameters received from the vehicle indicate electrical current within a circuit of the vehicle equals or exceeds a first electrical current threshold. Moreover, the determine vehicle driving mode module 300 can be configured to determine the vehicle is being driven in the regenerative braking mode with the second output rate continuously for at least the second threshold amount of time based on determining a second set of parameters received from the vehicle indicate electrical current within the circuit of the vehicle equals or exceeds a second electrical current threshold. The first set of parameters includes first and second parameters corresponding to a particular PID, and the second set of parameters includes third and fourth parameters corresponding to the particular PID. Additionally, an amount of time between when the computing system receives the first and second parameters equals or exceeds the first threshold amount of time, and an amount of time between when the computing system receives the third and fourth parameters equals or exceeds the second threshold amount of time.

In accordance with at least some embodiments, such as the embodiments discussed in the preceding paragraph, one or more other parameters of the first set of parameters correspond to the particular PID and are received by the VST between receiving the first and second parameters, and the one or more other parameters of the first set of parameters indicate electrical current within the circuit of the vehicle equals or exceeds the first electrical current threshold. Additionally or alternatively, one or more other parameters of the second set of parameters correspond to the particular PID and are received by the VST between receiving the third and fourth parameters, and the one or more other parameters of the second set of parameters indicate electrical current within the circuit of the vehicle equals or exceeds the second electrical current threshold.

In accordance with at least some embodiments, such as the embodiments discussed in two paragraphs above, determining the multiple first sets of battery voltage values can include determining battery voltage values from vehicle messages received at the VST between the VST receiving a first vehicle message including the first parameter and a second vehicle message including the second parameter. Moreover, determining the multiple second sets of battery voltage values can include determining battery voltage values from vehicle messages received at the VST between the VST receiving a third vehicle message including the third parameter and a fourth vehicle message including the fourth parameter.

In accordance with at least some embodiments, the processor 116 executes the determine vehicle driving mode module 300 in response to starting a battery system test, which can occur in response to selection of a USC, such as the USC 222 shown in FIG. 27 or the USC 232 shown in FIG. 28. In accordance with at least some other embodiments, the processor 116 executes the determine vehicle driving mode module 300 in response to determining the sets of battery voltage values (e.g., a third set of battery voltage values determined while the vehicle is parked and operating in an operating state in which vehicle power is turned on and electrical accessories are turned off) equal or exceed the threshold battery voltage.

In accordance with at least some embodiments, the vehicle includes a hybrid vehicle and determining the vehicle is being driven in the electric vehicle mode with the first output rate continuously for at least the first threshold amount of time occurs after determining a button in the hybrid vehicle to select electric vehicle mode has been selected. As an example, determining the button in the hybrid vehicle to select electric vehicle mode has been selected can be based on a vehicle message transmitted by the hybrid vehicle and received by the receive vehicle message module 307. As an example, the vehicle message can include a parameter value that indicates the button has been selected or a parameter value that indicates the engine RPM is zero. Other examples of the parameter values are also possible.

### 2) Determine Battery Voltage Values Module

The determine battery voltage values module 301 can be configured to determine sets of battery voltage values for multiple battery pack components in the vehicle. The determine battery voltage values module 301 can be executed while the vehicle is parked, as well as while the vehicle is being driven in an electric vehicle mode or in a regenerative braking mode.

As an example, the determine battery voltage values module 301 can be configured to determine multiple first sets of battery voltage values for multiple battery pack components in the vehicle as the vehicle is driven in the electric vehicle mode with the first output rate continuously for at least the first threshold amount of time. Each first set of battery voltage values includes or is representative of a pair of battery voltage values. The first sets of battery voltage values can be determined before or after the second sets of battery voltages discussed in the next paragraph are determined.

As another example, the determine battery voltage values module 301 can be configured to determine multiple second sets of battery voltage values for the multiple battery pack components in the vehicle as the vehicle is driven in the regenerative braking mode. Each second set of battery voltage values includes or is representative of a pair of battery voltage values. Each pair of battery voltage values among the first set of battery voltage values includes or is representative of minimum and maximum battery voltage values from each first set of battery voltage values. The second sets of battery voltage values can be determined before or after the first sets of battery voltages discussed in the previous paragraph are determined. The regenerative braking mode can occur when an output rate of the vehicle is a second output rate continuously for at least a second threshold amount of time.

As an example, the first output rate discussed above can include a range of output rates, such as 35 to 75 amps or some other current range. As another example, the first output rate can be specified as a given percentage of a specified peak output current of electrical motor(s) in the vehicle, or a range of currents including the specified peak output current of electrical motor(s) in the vehicle. As yet another example, the second output rate can include a range of output rates, such as −35 to −75 amps or some other current range.

The determine battery voltage values module 301 can be configured to determine the multiple first and second sets of battery voltage values at the same time. In that regard, the store parameter values module 312 can store parameter values indicative of battery voltages for data points corresponding to current values that indicate the vehicle was driven in the electric vehicle mode and the regenerative braking mode and after execution of the determine vehicle driving mode module 300 has determined those two driving modes occurred, the determine battery voltage values module 301 can determine which battery voltage values correspond to the electric vehicle mode and which battery voltage values corresponds to the regenerative braking mode.

The determine battery voltage values module 301 can be configured to receive battery voltage values for at least some battery pack components within the battery pack to determine a particular first set of battery voltage values before receiving battery voltage values for at least some battery pack components within the battery pack to determine a next first set of battery voltage values. The processor 116 can execute the determine battery voltage values module 301 in this manner in response to the determine vehicle driving mode module 300 determining the vehicle is being driven in the electric vehicle mode. The processor 116 can stop and restart execution of the determine battery voltage values module 301 in response to the vehicle exiting the electric vehicle mode before the first threshold amount of time is reached and then re-entering the electric vehicle mode. As an example, the battery pack components within the battery pack can include battery pack modules or battery blocks.

The determine battery voltage values module 301 can be configured to receive battery voltage values for at least some battery pack components within the battery pack to determine a particular second set of battery voltage values before receiving battery voltage values for at least some battery pack components within the battery pack to determine a next second set of battery voltage values. The processor 116 can execute the determine battery voltage values module 301 in this manner in response to the determine vehicle driving mode module 300 determining the vehicle is being driven in the regenerative braking mode. The processor 116 can stop and restart execution of the determine battery voltage values module 301 in response to the vehicle exiting the regenerative braking mode before the second threshold amount of time is reached and then re-entering the regenerative braking mode.

The determine battery voltage values module 301 can be configured to determine multiple third sets of battery voltage values for the multiple battery pack components while the vehicle is operating in a particular operating state (e.g., an operating state in which vehicle power is turned on and electrical accessories are turned off). Each third set of battery voltage values includes a battery voltage value for each battery pack component (e.g., battery pack module, string or battery cell).

In accordance with at least some embodiments, the determine battery voltage values module 301 can be configured to transmit VDMs to the vehicle 4 with PIDs to request parameter values indicative of the battery voltage values corresponding to the multiple battery pack modules in the vehicle 4. In accordance with at least some other embodiments, the determine battery voltage values module 301 can be configured to receive parameter values indicative of the battery voltage values from another module that receives the parameter values from the vehicle, such as the receive vehicle message module 307. In accordance with at least some of those other embodiments, the determine battery voltage values module 301 can be configured to trigger another module, such as the transmit vehicle message module 306, to transmit VDMs to the vehicle 4 with PIDs to request the parameter values.

An example set of battery voltage values for multiple battery pack modules in a vehicle is shown in Table C2 and Table C3. In that example, the vehicle has fourteen battery pack modules and voltages values for those battery pack modules are captured as fifty-six groups (e.g., data points) of voltage values, each group having one voltage value for each of the battery pack modules. In at least some cases, the fourteen battery voltage values for each data point after the first data point are determined before determining any voltage values for the next data point.

Another example set of battery voltage values for multiple battery pack components in the vehicle is shown in Table D2 and Table D3. In those tables, the voltages values for the fourteen battery pack modules are captured as fifty-six groups (e.g., data points) of voltage values, each group having one voltage value for each of the battery pack modules. In at least some cases, the fourteen battery voltage values for each data point after the first data point are determined before determining any voltage values for the next data point.

Another example set of battery voltage values for multiple battery pack components in a different vehicle is shown in Table E2. In that example, the vehicle has nine battery pack modules and voltages values for those battery pack modules are captured as thirty-one groups (e.g., data points) of voltage values, each group having one voltage value for each of the battery pack modules. In at least some cases, the nine battery voltage values for each data point after the first data point are determined before determining any voltage values for the next data point.

Another example set of battery voltage values for multiple battery pack modules in the vehicle discussed with respect to Table E2 is shown in Table F2. In that example, the voltages values for the nine battery pack modules are captured as thirty-one groups (e.g., data points) of voltage values, each group having one voltage value for each of the battery pack modules. In at least some cases, the nine battery voltage values for each data point after the first data point are determined before determining any voltage values for the next data point.

The determine battery voltage values module 301 can be configured to determine battery voltages for each set of battery voltage values for at least some battery pack components before repeating determining battery voltage values for a next set of battery voltage values.

As an example, the first sets of battery voltage values are determined sequentially (while the vehicle is driven in the electric vehicle mode). The battery voltage values for each first set of battery voltage values can be referred to and/or stored as battery voltage values for a particular data point. Tables D2, D3, F2 show example data points for battery voltage values, some of which can be part of a first set of battery voltage values if the current value indicated in Table D1 or F1 equal or exceed an applicable first output rate. Each first set of battery voltage values is associated with an output rate within the first range of output rates. For instance, the output rate within the first range of output rates can include current values that equal or exceed thirty (30.0) amps. Receiving battery voltage values for at least some battery pack components within the multiple battery pack (e.g., battery pack components with a battery pack module) to determine a particular first set of battery voltage values can occur before receiving battery voltage values for at least some battery pack components within the multiple battery pack to determine a next first set of battery voltage values.

As another example, the second sets of battery voltage values are determined sequentially (while the vehicle is driven in the regenerative braking mode). The battery voltage values for each second set of battery voltage values can be referred to and/or stored as battery voltage values for a particular data point. Tables C2, C3, E2 show example data points for battery voltage values, some of which can be part of a second set of battery voltage values if the current value indicated in Table C1 or E1 equal or are more negative than an applicable second output rate. Each second set of battery voltage values is associated with an output rate within the second range of output rates. For instance, the output rate within the second range of output rates can include current values that equal or are more negative than negative thirty (−30) amps. Receiving battery voltage values for at least some battery pack components within the multiple battery pack (e.g., battery pack components with a battery pack module) to determine a particular second set of battery voltage values can occur before receiving battery voltage values for at least some battery pack components within the multiple battery pack to determine a next second set of battery voltage values.

### 3) Output Test Indicator Module

The output test indicator module 302 can be configured to output an indicator (e.g., an indication) regarding a test, such as a test result, a test instruction, or a recommendation corresponding to a test result. The output test indicator module 302 can be configured to output a GUI, a USC within a GUI, a still image, or an audio file.

The output test indicator module 302 can be configured to output a test indicator regarding a state of a battery pack including the multiple battery pack components (e.g., multiple battery pack module) based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Each pair of battery voltage values among the second set of battery voltage values includes or is representative of minimum and maximum battery voltage values from each second set of battery voltage values. As an example, differences in pairs of battery voltages can be represented as delta min/max data 292, 298 as shown in FIG. 31, or as delta min/max data 469, 475, as shown in FIG. 33.

As an example, the test indicator can indicate whether any of the differences exceed a threshold voltage value, such as 0.3 volts or some other threshold voltage value that indicates a degraded condition of the battery pack. As another example, the test indicator can indicate whether a threshold percentage (e.g., 10%) of the voltage differences exceed a threshold voltage value, such as 0.3 volts or some other threshold voltage value that indicates a degraded condition of the battery pack.

In accordance with at least some embodiments, the test indicator regarding the state of a battery pack includes a recommendation to rebalance two or more battery pack modules, strings or cells in the battery pack or replacement of one or more battery pack modules, strings or cells in the battery pack. The recommendation of the replacement of one or more battery pack modules, strings or cells in the battery pack can be based on differences in pairs of battery voltage values decreasing while the vehicle is driven in the electric vehicle mode with a first output rate by more than a voltage comparison threshold.

The output test indicator module 302 can be configured to output, in response to determining the vehicle was driven in the electric vehicle mode and in the regenerative braking mode and determining the multiple first and second sets of battery voltage values, an audible or visual notification indicating a test of the battery pack is complete.

The output test indicator module 302 can be configured to output a notification indicating the battery pack failed a battery test in response to determining at least some battery voltages of the third sets of battery voltage do not equal or exceed the threshold battery voltage.

The output test indicator module 302 can be configured to output a notification indicating a test result is inconclusive. Such notification could be output for various reasons, such as the test was not completed or the battery system set a diagnostic trouble code during performance of the test.

The output test indicator module 302 can be configured to output a GUI, such as a GUI shown in FIG. 24 to FIG. 38 or a GUI including any content shown in the drawings and/or discussed in this description.

A test instruction output by the output test indicator module 302 can comprise an instruction such as an instruction indicating how to connect a current clamp meter to the VST 3 and/or to the vehicle 4, an instruction how to connect the VST to a diagnostic connector in the vehicle, an instruction how to drive the vehicle, an instruction shown in the GUI 230 shown in FIG. 28, or some other instruction.

### 4) Monitor Parameters Module

The monitor parameters module 303 can be configured to monitor parameters from the vehicle. The monitored parameters can comprise parameters contained within vehicle messages. As an example, the monitored parameters can comprise parameters obtained via execution of the receive vehicle message module 307 and/or by reading parameters stored within a memory via the store parameter values module 312. Examples of monitored parameters are shown in Table C1, C2, C3, D1, D2, D3, E1, E2, F1, F2, and in FIG. 31 and FIG. 33.

As an example, the monitored parameters can include a first set of parameters indicative of a first electrical current and a system voltage within the vehicle, and a second set of parameters indicative of a second electrical current and the system voltage. The first electrical current is different than the second electrical current, although the first and second electrical currents can flow in the same electrical circuit. The first set of parameters can be used to determine the vehicle is being driven in the electric vehicle mode with the first output rate. The second set of parameters can be used to determine the vehicle is being driven in the regenerative braking mode with the second output rate. As an example, the first output rate can be a current greater than or equal to 30 amps, and the second output rate can be a more negative than or equal to −30 amps.

As an example, the system voltage can be a sum of all battery pack module voltages for the vehicle. As another example, the system voltage can be provided by the vehicle.

The monitor parameters module 303 can be configured to begin monitoring parameters in response to initiation of battery test via selection of a USC on the VST 3, the USC 222 shown in FIG. 27, or the USC 232 shown in FIG. 28.

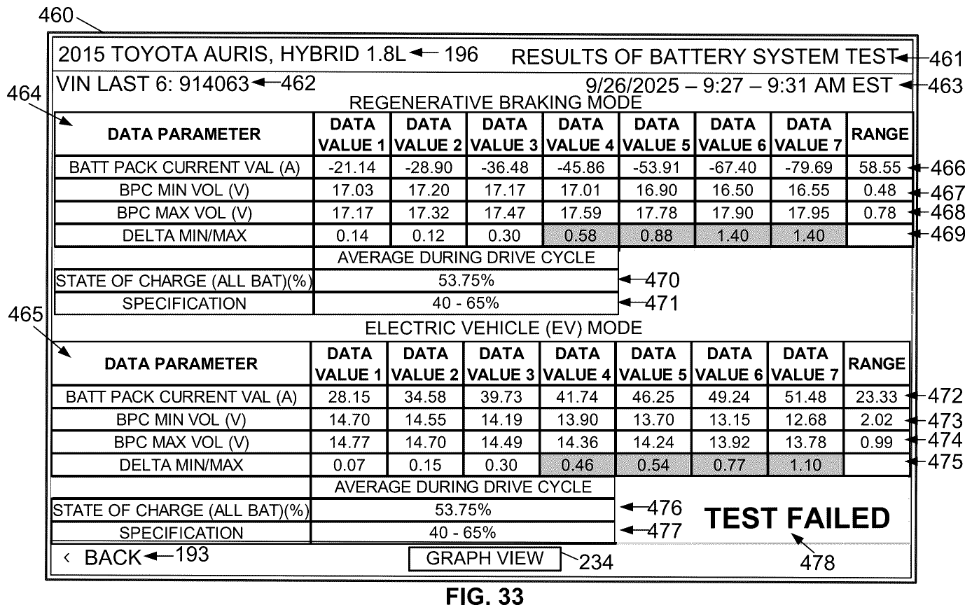

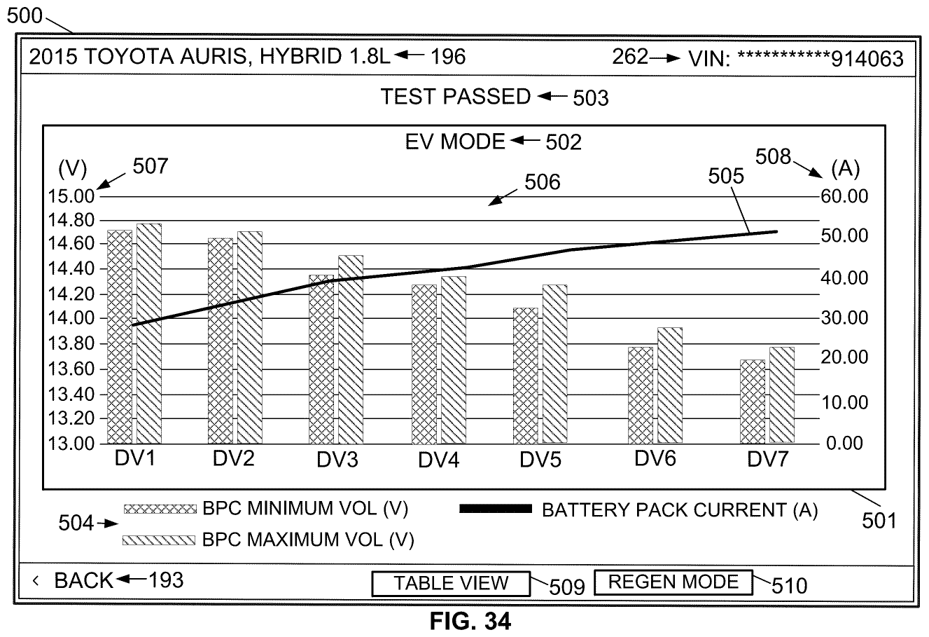

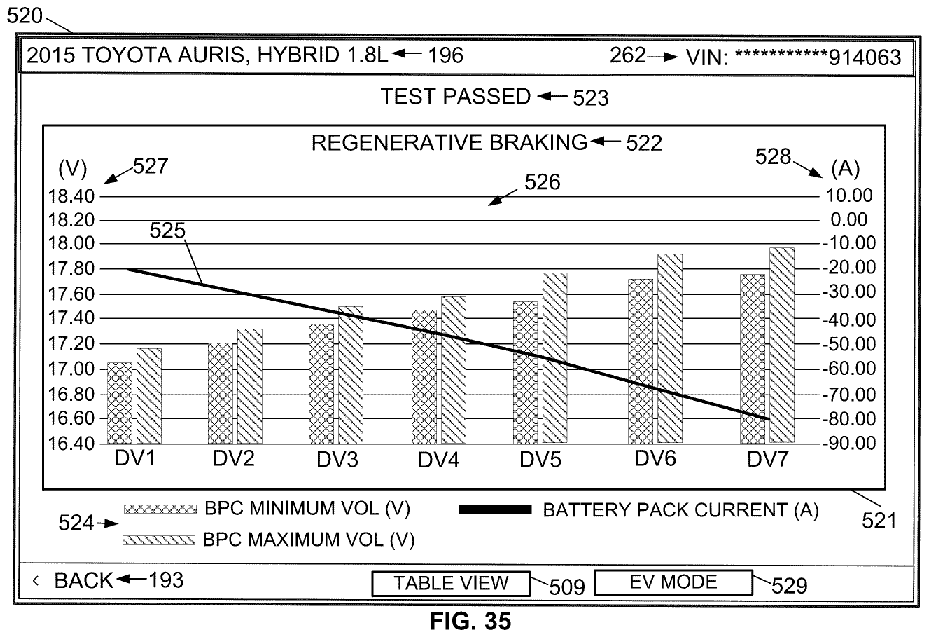

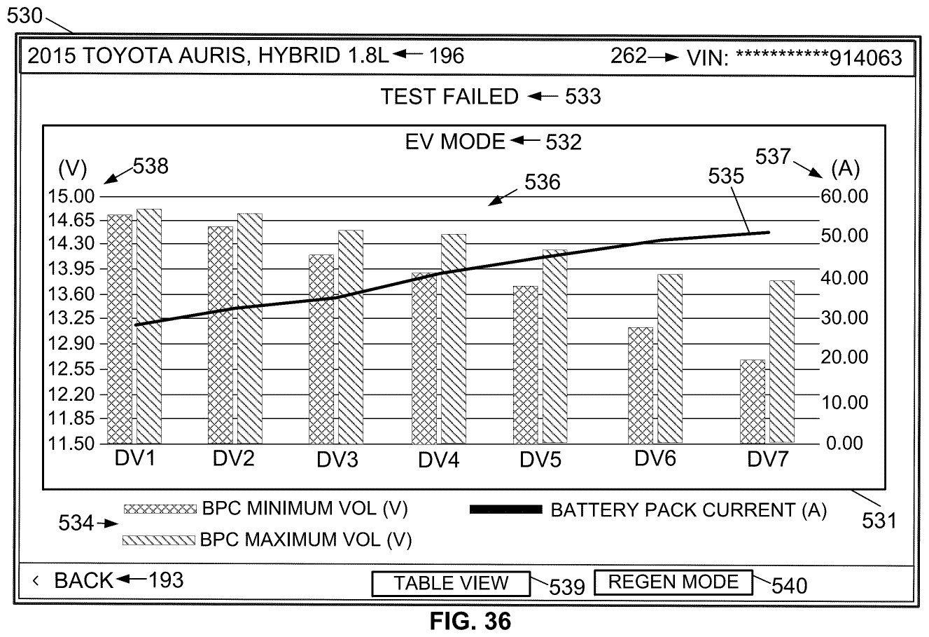

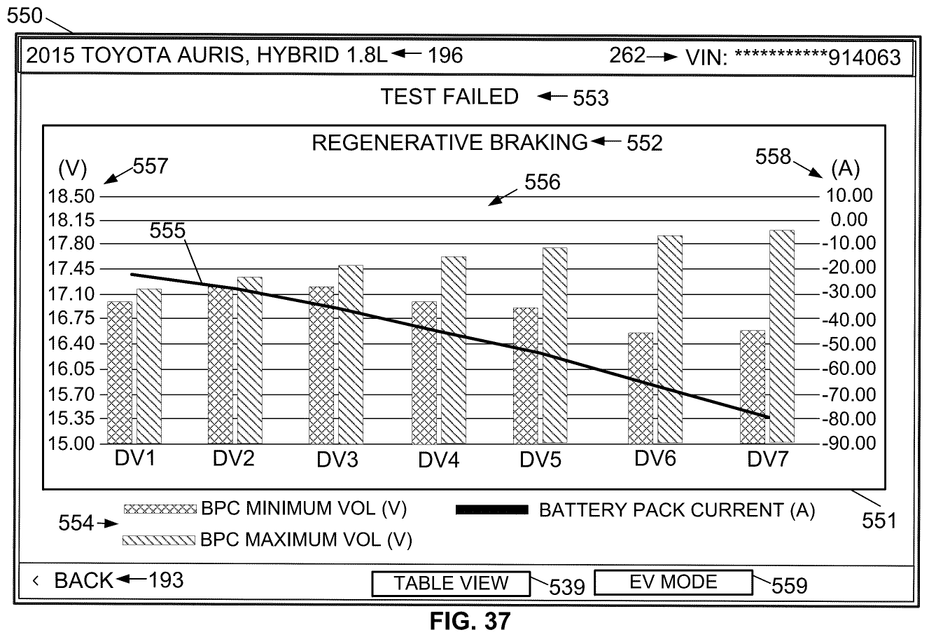

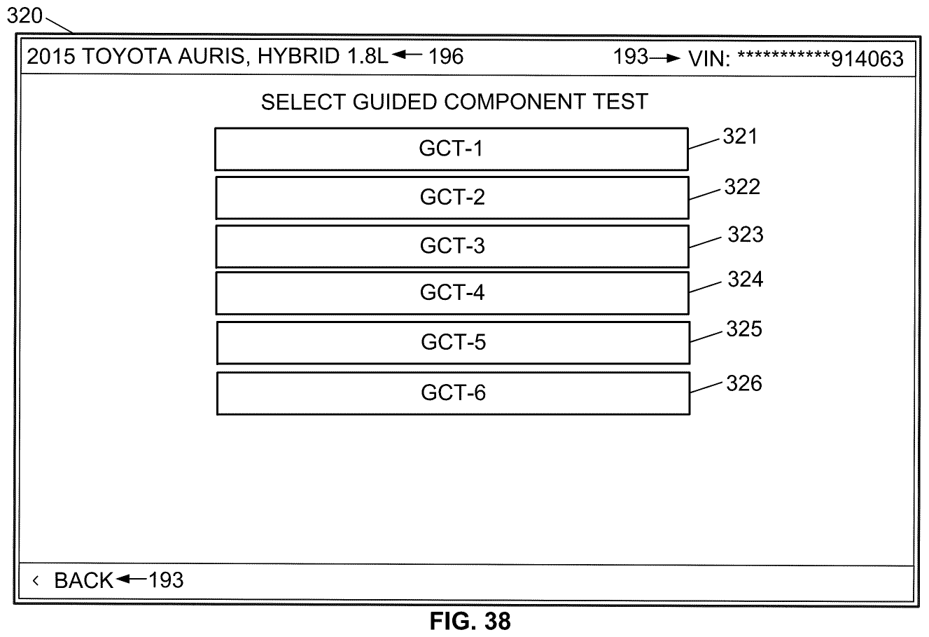

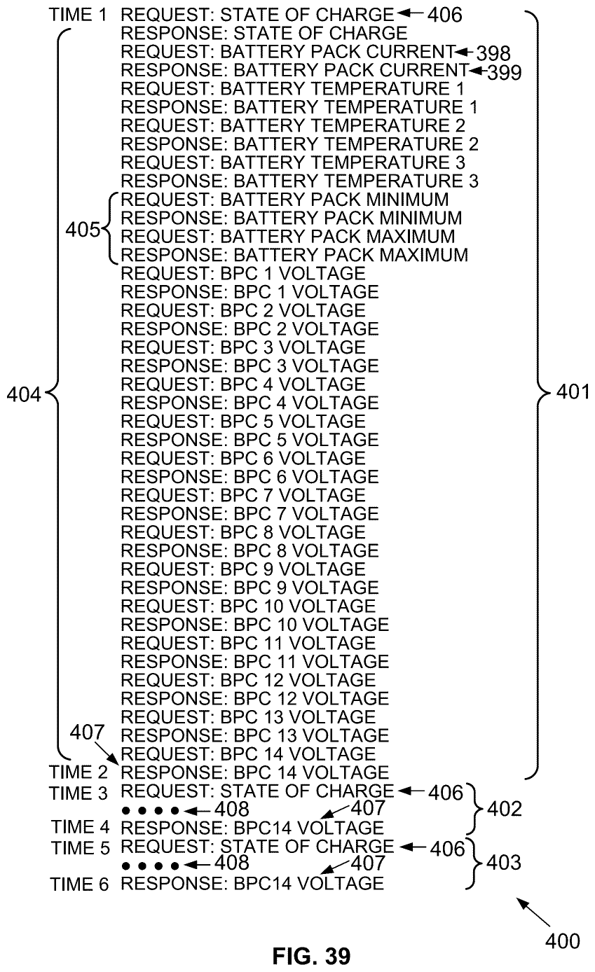

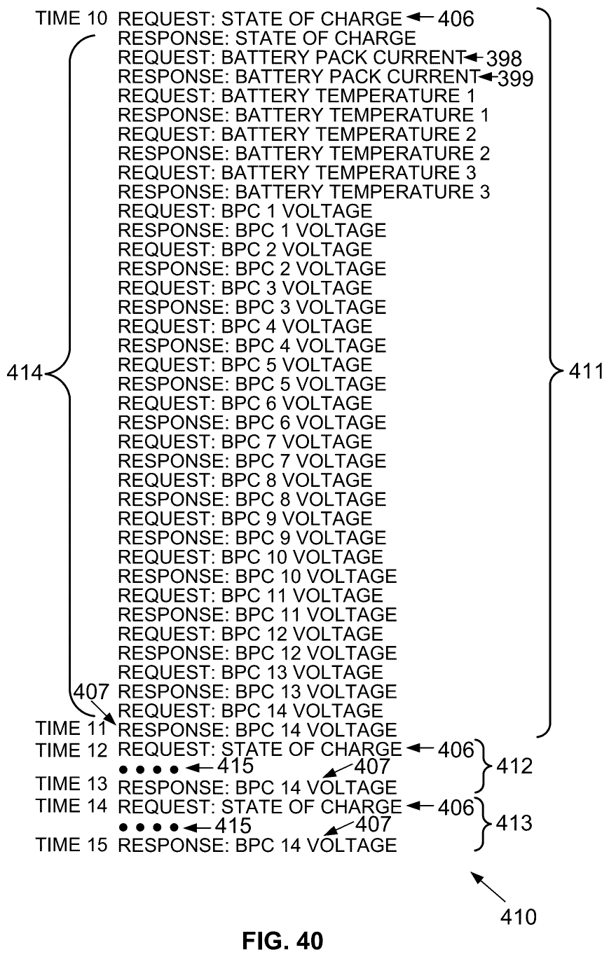

The monitor parameters module 303 can be configured to determine battery voltage values for the multiple battery pack components (e.g., multiple battery pack modules) that include groups of battery voltage values. Each group of battery voltages can include a respective battery voltage value for one or more battery pack modules, strings or cells in the vehicle battery pack. Each respective battery voltage value in each group of battery voltage values correspond to each other temporally. FIG. 39 and FIG. 40 show vehicle message flows that include response vehicle messages. Parameter values contained in the response message of each group of vehicle messages can indicate battery voltage values that correspond to each other temporally. A group of vehicle message that include parameter values that indicate battery voltages that correspond to each other temporally can include additional vehicle messages if the vehicle messages include parameter values indicating battery voltage values of individual battery blocks, battery pack modules, strings, or cells within the battery pack.

In accordance with at least some embodiments, the monitor parameters module 303 is configured to monitor parameters from multiple sources. As an example, a first source can comprise a vehicle network that carries vehicle messages indicative of battery pack components, and a second source can comprise a current clamp meter that measures electrical current flowing within a circuit, such as a bus connected to a battery pack. The monitor parameters module 303 can associate parameters received from multiple sources with each other so that the processor 116 can use the associated parameters to determine whether the vehicle is being driven in the electric vehicle mode or the regenerative vehicle mode.

The multiple sources may be configured to provide individual parameters at different rates. For instance, the current clamp meter may provide just parameters indicative of the current, whereas the vehicle network may carry vehicle messages for with parameters indicative of voltages and temperatures for multiple battery pack modules. As an example, the first source can provide one voltage measurement and one temperature measurement for each of fourteen battery pack modules over a period of 0.5 seconds and the second source can provide one hundred current measurements over the period of 0.5 seconds. When testing a battery system in a vehicle, the monitor parameters module 303 can compare all of the current measurements to the first and second thresholds to determine whether all of the current measurements equal or exceed one of those thresholds for an applicable threshold amount of time.

In accordance with embodiments in which the monitor parameters module 303 obtains more than one current value for each set of battery voltage values, the monitor parameters module 303 can associate one or more (e.g., all) current values with the battery voltage values. In accordance with at least some embodiments, the monitor parameters module 303 associates data with the battery voltage values that indicate the current value(s) exceed the first or second threshold value. That data can indicate the current values or can include data bits to indicate whether the current values exceed the first threshold, exceed the second threshold, or do not exceed any of the first and second thresholds.

In accordance with at least some embodiments, the monitor parameters module 303 is configured to overwrite parameter values stored within the parameter values 147. In some cases, execution of the monitor parameters module 303 causes the processor 116 to write a null character into the each data address of the parameter values 147. As an example, the processor 116 can execute the monitor parameters module 303 in that manner when a new test has been requested or started or in response to a selection of a USC 160 (shown in FIG. 29 and FIG. 30) to clear ranges. In some other cases, execution of the monitor parameters module 303 causes the processor 116 to overwrite parameter values in a first-in-first-out (FIFO) manner when the data addresses designated for the parameter values 147 have had parameter values written thereto.

### 5) Determine Particular Battery Pack Component Module

The determine particular battery pack component module 304 can be configured to determine a particular battery pack component, a battery voltage of the particular battery pack component cell, and whether the battery voltage of the particular battery pack component is a maximum battery voltage relative other battery.

The determine particular battery pack component module 304 can be configured to determine a particular battery pack component in the multiple pack (e.g., a particular battery pack component in a battery pack module) has a maximum battery voltage. The first threshold amount of time (used to determine the vehicle is being driven in the electric vehicle mode) equals an amount of time it takes for a battery voltage of the particular battery pack component to decay by a threshold percentage of the maximum battery voltage while the vehicle is being driven in the electric vehicle mode with the first output rate.

As an example, a processor executing the determine particular battery pack component module 304 can be configured to transmit one or more VDMs to request PID parameter values indicative of battery voltages corresponding to battery pack components within the multiple battery pack modules. In response to transmitting the one or more VDMs, the processor can receive VDMs including the PID parameter values and write the PID parameter values into memory. Execution of determine particular battery pack component module 304 can include comparing the PID parameter values indicative of the battery voltages to determine which battery pack component has the maximum battery voltage at a given time or data point. The battery voltages can be stored such that the processor can determine which battery voltages correspond to the given time or data point. For instance, the battery voltages corresponding to the given time or data point can be stored with time stamps and/or within a separate buffer within the memory.

As another example, a vehicle may transmit a VDM including PID parameter value(s) that indicate which battery pack component has a maximum voltage for a given time. The determine particular battery pack component module 304 can be configured to transmit VDM(s) to request those PID parameter value(s). In some situations, multiple battery pack components can have the maximum battery voltage for a given time. In at least some embodiments, the determine particular battery pack component module 304 is configured to determine each battery pack component having the maximum battery voltage for the given time. In at least some other embodiments, the determine particular battery pack component module 304 is configured to determine a single particular battery pack component having the maximum battery voltage for the given time and determining that no other battery pack component of the multiple battery pack components has a battery voltage exceeding the maximum batter voltage for the given time.

The determine particular battery pack component module 304 can repeatedly determine the particular battery pack component in the multiple battery pack components having a maximum battery voltage throughout a test of a vehicle battery system including the multiple battery pack components. Likewise, the determine particular battery pack component module 304 can repeatedly determine the particular battery pack component in the multiple battery pack components having a minimum battery voltage throughout the test of the vehicle battery system.

### 6) Determine Test Condition/Result Module

The determine test condition/result module 305 can be configured to determine one or more conditions of the vehicle and/or a component of the vehicle, such as a battery pack or a component of the battery pack, before beginning a test of the vehicle and/or the vehicle component.

As an example, the determine test condition/result module 305 can be configured to determine, based on one or more parameter values corresponding to a particular parameter identifier, whether the vehicle is in a condition for testing a battery pack and/or a battery system. For instance, the determine test condition/result module 305 can be configured to determine, based on one or more parameter values corresponding to a particular PID, whether the vehicle is in a condition for testing the battery pack. The one or more parameter values corresponding to the particular PID can be representative of a battery state-of-charge, a battery temperature, or some other condition of the battery pack.

The determine test condition/result module 305 can be configured to determine one or more test results based on performance of a test or on failure to initiate or complete a test. As an example, the determine test condition/result module 305 can be configured to compare pairs of battery voltage values representing a minimum and maximum battery voltage value for each data point during performance of a battery system test to determine a difference in those voltage values for each data point, and to further compare the difference to a voltage threshold. A test result can indicate or be based on whether one or more calculated differences equals or exceeds the voltage threshold. As another example, the determine test condition/result module 305 can be configured to determine a test result is a failed or inconclusive because the test was not performed or was not performed completely, because of an improper test condition being detected by the determine test condition/result module 305 and/or a DTC being detected by the determine DTC state module 308.

The determine test condition/result module 305 can be configured to determine any or all test results described within this description and/or as shown in a drawing, such as FIG. 31 and FIG. 33.

### 7) Transmit Vehicle Message Module

The transmit vehicle message module 306 can be configured to transmit vehicle messages (i.e., VDMs) to the vehicle. In general, the vehicle messages transmitted by execution of the transmit vehicle message module 306 can include any vehicle message described in this description using any VDM protocol described in this description or otherwise known to a person having ordinary skill in the art.

As an example, the transmit vehicle message module 306 can be configured to transmit, to the vehicle, a vehicle message to the vehicle to request vehicle identification information, such as a VIN.

As another example, the transmit vehicle message module 306 can be configured to transmit, to the vehicle, one or more vehicle messages to request diagnostic trouble code data from the vehicle.

As yet another example, the transmit vehicle message module 306 can be configured to transmit, to the vehicle, one or more vehicle messages to request parameter values from the vehicle. Those message(s) can include a PID that indicates which type of parameter values are to be sent to the VST 3. For instance, the PID can indicate battery voltage values of a battery pack, current values of electrical circuits connected to and/or within the battery pack, minimum battery voltage values for a battery pack module, string, or cell, or maximum battery voltage values for a battery pack module, string, or cell. Transmission of a vehicle message to request a parameter value can occur before, while, and after an ECU within a vehicle performs a functional test so that parameter values received in response can be analyzed to determine how performance of the functional test affected a component corresponding to the parameter values.

As still yet another example, the transmit vehicle message module 306 can be configured to transmit, to the vehicle, one or more vehicle messages to request performance of a functional test or reset procedure by an ECU within the vehicle.

### 8) Receive Vehicle Message Module

The receive vehicle message module 307 can be configured to receive vehicle messages (e.g., VDMs) from the vehicle 4, 32, 71. The vehicle messages can include any and all vehicle messages described in this description. As an example, the vehicle messages can include normal vehicle messages transmitted by ECUs within the vehicle to other ECUs in the vehicle. As another example, the vehicle messages can include diagnostic mode messages transmitted by an ECU. In some vehicles, the diagnostic mode messages are addressed to the VST 3. For example, the diagnostic mode messages can include diagnostic data, such as data indicative of battery voltages, battery temperatures, battery states-of-charge, or current measurements.

The receive vehicle message module 307 can be configured to receive, from the vehicle, one or more other vehicle messages including diagnostic trouble code data. The diagnostic trouble code data can indicate whether a battery system ECU in the vehicle has detected a malfunction. The VST 3 can output a notification advising a user to repair the malfunction before testing the battery system. In some cases, the diagnostic trouble code data can indicate that no battery system DTC is currently set in the vehicle.

### 9) Determine DTC State Module

The determine DTC state module 308 can be configured to determine whether a vehicle connected to the VST 3 has any DTC set within an ECU, such as an ECU within a system selected to be tested using the VST 3. The determine DTC state module 308 can be configured to determine whether a DTC is currently active (i.e., a current DTC) or previously set active, but not currently active (i.e., a history DTC).

The determine DTC state module 308 can be configured to determine no DTCs are currently set active in a battery management system of the vehicle. The determine DTC state module 308 can make that determination based on DTC data contained within vehicle messages received using the receive vehicle message module 307.

### 10) Determine Min/Max Battery Voltage Value Module

The determine min/max battery voltage value module 309 can be configured to determine which voltage(s) of a set of battery voltages are the minimum battery voltage value(s) and the maximum battery voltage value(s). In at least some embodiments, the determine min/max battery voltage value module 309 is configured to determine a single minimum and a single maximum voltage value from among a set of battery voltage values. In at least some other embodiments, the determine min/max battery voltage value module 309 is configured to determine all minimum and all maximum voltage values from among a set of battery voltage values. Each set of battery voltage values can correspond to a respective data point. Examples of such battery voltage values and data points are shown in Tables C2, C3, D2, D3, E2, F2.

As an example, the determine min/max battery voltage value module 309 can be configured to determine the minimum and maximum battery voltage values from each first set of battery voltage values based on minimum and maximum PID parameter values of each respective first set of vehicle messages. A set of battery voltages, such as the first set of battery voltage values, can be a single battery voltage value for each voltage measurement made by the BMS for a single data point. As an example, a battery pack can include fourteen battery pack modules, each battery pack module having twelve battery cells arranged in three strings of four battery cells.

If the BMS can make one voltage measurement for each battery pack module, then the BMS makes fourteen voltage measurements for each data point. Tables C2, C3, D2, D3 show example data according to such an arrangement. On another hand, if the BMS can make a voltage measurement for each string of four battery cells, then the BMS can make forty-two voltage measurements for each data point. On yet another hand, if the BMS can make a voltage measurement for each battery cell, then the BMS can make one hundred sixty-eight voltage measurements for each data point.

As another example, the determine min/max battery voltage value module 309 can be configured to determine the minimum maximum battery voltage values from each second set of battery voltage values based on minimum and maximum PID parameter values of each respective second set of vehicle messages.

The first and second sets of battery voltages can include battery voltage values corresponding to different data points that occur while the vehicle is driven in the electric vehicle and regenerative braking mode, respectively. In accordance with at least some embodiments, the different data points include a respective battery voltage value for each battery pack module within a battery pack. Considering the example data shown in Table C2 and Table C3 below, an example battery pack includes fourteen battery pack modules and a respective battery voltage value is determined for each battery pack module at each data point. Table C2 and Table C3 show example data for fifty-six data points. Table C1 below shows battery pack current values for each of the fifty-six data points. The determine vehicle driving mode module 300 can determine the vehicle is operating in the electrical vehicle and regenerative braking modes based on those battery pack current values.

In accordance with at least some embodiments, the determine min/max battery voltage value module 309 can be configured to determine the minimum and maximum battery voltage values for each first set of battery voltage values by determining the minimum and maximum battery voltage values for each data point by comparing the individual battery voltage values for each data point to each other when the corresponding battery pack current values for those data points indicate the vehicle is being driven in the electric vehicle mode. Likewise, the determine min/max battery voltage value module 309 can be configured to determine the minimum and maximum battery voltage values for each second set of battery voltage values by determining the minimum and maximum battery voltage values for each data point by comparing the individual battery voltage values for each data point to each other when the corresponding battery pack current values for those data points indicate the vehicle is being driven in the regenerative braking mode.

In accordance with at least some other embodiments, the determine min/max battery voltage value module 309 can be configured to determine the minimum and maximum battery voltage values for the different data points based on minimum and maximum battery voltage values reported directly by the vehicle. For example, the receive vehicle message module 307 can receive vehicle messages containing parameter values indicative of the minimum and maximum battery voltage values for the different data points, the monitor parameters module 303 can determine that the received vehicle messages includes those parameter values, and the store parameter values module 312 can be stored in a memory in a form like Table C1 or in some other form.

Once the minimum and maximum voltage values determined, the determine min/max battery voltage value module 309 can be configured to determine the minimum and maximum battery voltage values for each first set of battery voltage values by determining the minimum and maximum battery voltage values indicated in Table D1 for each data point that corresponds to battery pack current values that indicate the vehicle is being driven in the electric vehicle mode. Similarly, the determine min/max battery voltage value module 309 can be configured to determine the minimum and maximum battery voltage values for each second set of battery voltage values by determining the minimum and maximum battery voltage values indicated in Table C1 for each data point that corresponds to battery pack current values that indicate the vehicle is being driven in the regenerative braking mode.

In accordance with at least some embodiments, the processor 116 executes the determine min/max battery voltage value module 309 in response to the determine vehicle driving mode module 300 outputting data that indicates the vehicle is being driven in the electric vehicle mode or the regenerative braking mode.

In accordance with at least some embodiments, the minimum and maximum battery voltage values of each pair of battery voltage values within the first sets of battery voltage values correspond to each other temporally (e.g., for a single data point). The first sets of battery voltage values are those determined while the vehicle is driven in the electric vehicle mode with the first output rate continuously for at least the first threshold amount of time. Similarly, the minimum and maximum battery voltage values of each pair of battery voltage values within the second sets of battery voltage values correspond to each other temporally (e.g., for a single data point). The second sets of battery voltage values are those determined while the vehicle as the vehicle is driven in the regenerative braking mode.

In accordance with at least some embodiments, the minimum and maximum battery voltage values of each pair of battery voltage values within the first sets of battery voltage values are determined from a respective first set of vehicle messages received from the vehicle. The first sets of battery voltage values are those determined while the vehicle is driven in the electric vehicle mode with the first output rate continuously for at least the first threshold amount of time. Similarly, the minimum and maximum battery voltage values of each pair of battery voltage values within the second sets of battery voltage values are determined from a respective second set of vehicle messages received from the vehicle. The second sets of battery voltage values are those determined while the vehicle as the vehicle is driven in the regenerative braking mode.

In accordance with at least some embodiments, such as those discussed in the preceding paragraph, each respective first set of vehicle messages includes PID parameter values corresponding to first, second, third, and fourth PIDs, and each respective second set of vehicle messages includes PID parameter values corresponding to the first, second, third, and fourth PIDs. The first PID corresponds to a maximum battery voltage of a battery pack module, string, or cell within the multiple battery pack components having the maximum battery voltage at a respective time. The second PID corresponds to a battery identifier of the battery pack module, string, or cell within the multiple battery pack components having the maximum battery voltage at a respective time. The third PID corresponds to a minimum battery voltage of a battery pack module, string, or cell within the multiple battery pack components having the minimum battery voltage at the respective time. The fourth PID corresponds to a battery identifier of the battery pack module, string, or cell within the multiple battery pack components having the minimum battery voltage at the respective time.

In accordance with at least some embodiments, such as those discussed two paragraphs above, each respective first set of vehicle messages includes PID parameter values corresponding to a battery voltage of each battery pack module, string, or cell within the multiple battery pack components at a respective time as the vehicle is being driven in the electric vehicle mode with the first output rate. Moreover, each respective second set of vehicle messages includes PID parameter values corresponding to a battery voltage of each battery pack module, string, or cell within the multiple battery pack components at a respective time as the vehicle is driven in the regenerative braking mode with the second output rate. The determine min/max battery voltage value module 309 can be configured to determine the minimum and maximum battery voltage values from each first set of battery voltage values based on minimum and maximum PID parameter values of each respective first set of vehicle messages. The determine min/max battery voltage value module 309 can also be configured to determine the minimum maximum battery voltage values from each second set of battery voltage values based on minimum and maximum PID parameter values of each respective second set of vehicle messages.

In accordance with at least some embodiments, such as those discussed in the three preceding paragraphs, the minimum and maximum battery voltage values for each pair of battery voltage values among the first set of battery voltage values are voltage values corresponding to different battery strings or cells of the battery pack. Similarly, the minimum and maximum battery voltage values for each pair of battery voltage values among the second set of battery voltage values are voltage values corresponding to different battery strings or cells of the battery pack.

12) Determine output rate module

The determine output rate module 310 can be configured to determine output rates of the vehicle. The output rates can be determined while the vehicle is parked as well as while the vehicle is being driven. As an example, the output rates can indicate rates of current flowing into or out of a battery pack, such as rates of current flowing in a bus connected to the battery pack, such as the bus 90 shown in FIG. 3 or the bus 95 shown in FIG. 4. As another example, the output rates can indicate rates of current flowing within the battery pack. As yet another example, the output rates can indicate rates of current flowing into, out of, or within an inverter. An output rate can include a positive current or a negative current.

The data values of the battery pack current values and range data 289 and the data values of the battery pack current values and range data 295 (all shown in FIG. 31) can be used to determine the first and second output rates of the vehicle. Likewise, the data values of the battery pack current values and range data 466 and the data values of the battery pack current values and range data 472 (all shown in FIG. 33) can be used to determine the first and second output rates of the vehicle during another test or a different vehicle. As an example, the first output rate used to determine the vehicle is being driven in the electric vehicle mode can include positive current values equal to or above a threshold positive current value, such as 35 amperes. As another example, the second output rate used to determine the vehicle is being driven in the regenerative braking mode can include negative current values being equal to more negative than a negative threshold current value, such as −35 amperes.

In accordance with at least some embodiments, the determine output rate module 310 is configured to determine a first output rate based on first current samples obtained using a current clamp meter and determining a second output rate based on second current samples obtained using the current clamp meter. The first output rate includes multiple output rates within a range of positive current rates. The second output rate includes multiple output rates within a range of negative current rates.

As another example, the determine output rate module 310 can be configured to determine output rates, such as the first and second output rates, based on parameter values indicative of the output rates determined by execution of the monitor parameters module 303. As an example, the parameter values indicative of battery pack current can be received via a vehicle message, such as the vehicle message 399 shown in FIG. 39 and FIG. 40.

In accordance with at least some embodiments, the determine output rate module 310 can be configured to determine current values received from a current clamp meter or via vehicle messages to a first current threshold corresponding to positive currents and a second current threshold corresponding to negative currents. The determine output rate module 310 can be configured to start a timer when a current value received by the determine output rate module 310 equals or exceeds the first or second current threshold. So long as the current values subsequently received by the determine output rate module 310 equal or exceed the same threshold, the timer continues to run. When a current value received by the determine output rate module 310 no longer equals or exceeds the same threshold, the determine output rate module 310 stops the timer. If the timer runs longer than the first threshold amount of time because current values equal or exceeded the first current threshold, then the determine output rate module 310 can output an indication the vehicle is in the electric vehicle mode. If the timer runs longer than the second threshold amount of time because current values equal or exceeded the second current threshold, then the determine output rate module 310 can output an indication the vehicle is in the regenerative braking mode.

In accordance with at least some embodiments, the first output rate is specified as a given percentage of a specified peak output current of electrical motor(s) in the vehicle, or a range of currents including the specified peak output current of electrical motor(s) in the vehicle. Most electric vehicles having multiple electrical motors used for propulsion connect the motors in a parallel configuration to allow for independent control and optimal performance. In such vehicles, the measured battery current can be based on a sum of the specified peak output current of electrical motor(s). For an electric vehicle including a single electrical motor used for propulsion, the measured battery current can be based on the specified peak output current of the electrical motor.

### 13) Transmit Instructions Module

The transmit instructions module 311 can be configured to transmit instructions to an electronic control unit a vehicle, such as an autonomous vehicle, a hybrid vehicle, or an electric vehicle.

As an example, the transmit instructions module 311 can be configured to transmit, to an electronic control unit in the autonomous vehicle, instructions for controlling the vehicle to operate in the electric vehicle mode and the regenerative braking mode.

As another example, the transmit instructions module 311 can be configured to transmit, to an electronic control unit in a vehicle instructions to control a vehicle component based on a command within the functional test command 152 or within the reset procedure command 153 (shown in FIG. 5).

### 14) Store Parameter Values Module

The store parameter values module 312 can be configured to store the multiple parameter values in a non-transitory computer-readable memory (e.g., the memory 57, 117 or the system memory 674 shown in FIG. 43). As an example, the store parameter values module 312 can be configured to store at least some or all of the parameters monitored using the store monitor parameters module 312, voltages values determined by the min/max battery voltage value module 309, or voltage values compared using the compared battery voltage values module 313.

As an example, the store parameter values module 312 can be configured to store multiple first sets of battery voltage values and multiple second sets of battery voltage values in the non-transitory computer-readable memory. The multiple first sets can include battery voltage values for multiple battery pack components (e.g., battery pack modules, strings, or cells) in the vehicle as the vehicle is driven in the electric vehicle mode with the first output rate continuously for at least the first threshold amount of time. The multiple second sets can include battery voltage values for the multiple battery pack components (e.g., battery pack modules, strings, or cells) in the vehicle as the vehicle is driven in the regenerative braking mode. These battery voltage values of the first and second sets can include or is represent a pair of battery voltage values.

As another example, the store parameter values module 312 can be configured to store multiple first sets of current values and multiple second sets of current values in the non-transitory computer-readable memory. These multiple first sets can include current values for an electrical circuit(s) connected to a battery pack in the vehicle as the vehicle is driven in the electric vehicle mode with the first output rate continuously for at least the first threshold amount of time. These multiple second sets can include current values for the electrical circuit(s) connected to the battery pack as the vehicle is driven in the regenerative braking mode.

As yet another example, the store parameter values module 312 can be configured to store battery values and current values prior to the vehicle entering the electric vehicle mode and battery values and current values prior to the vehicle entering the regenerative braking mode as these values are monitored to determine whether the current values breach a threshold that indicate the vehicle has entered the electric vehicle or regenerative braking mode.

### 15) Compare Battery Voltage Values Module

The compare battery voltage values module 313 can be configured to compare all battery voltage values corresponding to each battery pack component (e.g., battery pack module, string, or cell) of the multiple battery pack components from among a set of battery voltage values to each other to determine the minimum and maximum battery voltage values for each pair of battery voltage values among that set of battery voltage values.

For example, the compare battery voltage values module 313 can be configured to compare all battery voltage values corresponding to each battery pack component (e.g., battery pack module, string, or cell) of the multiple battery pack components from among each first set of battery voltage values to each other to determine the minimum and maximum battery voltage values for each pair of battery voltage values among the first sets of battery voltage values.

As another example, the compare battery voltage values module 313 can be configured to compare all battery voltage values corresponding to each battery pack component (e.g., battery pack module, string, or cell) of the multiple battery pack components from among each second set of battery voltage values to each other to determine the minimum and maximum battery voltage values for each pair of battery voltage values among the second sets of battery voltage values.

### 16) Determine Vehicle Operating State Module

The determine vehicle operating state module 314 can be configured to one or more different operating states of the vehicle. In some cases, an operating state of the vehicle comprises an operating state of the vehicle when it's not being driven. In some other cases, an operating state of the vehicle comprises an operating state of the vehicle when it's being driven. In accordance with at least some embodiments, the VST 3 tests a battery system of the vehicle in operating states in which the battery system load is relatively low and the vehicle is not being driven. If the VST 3 determines the battery system fails such test, a technician may not need to go through the effort of testing the battery system during a test drive of the vehicle.

As an example, the determine vehicle operating state module 314 can be configured to determine the vehicle is parked and operating in an operating state in which vehicle power is turned on and electrical accessories are turned off. In many instances, so long as the battery system of the vehicle is not malfunctioning, a load on the battery system in this operating state is typically lower than when one or more vehicle accessories are turned on and/or the vehicle is being driven.

As yet another example, the determine vehicle operating state module 314 can be configured to determine an operating state of a hybrid vehicle in which the engine is off (i.e., zero RPM), the hybrid vehicle is parked, vehicle power is turned on, and electrical accessories are turned off.

### 17) Determine Threshold Breach Module

The determine threshold breach module 315 can be configured to determine when a threshold, such as a threshold within the thresholds 145 or a threshold with the CRPI 138 is breached. As an example, the threshold can be breached by a parameter value received by the receive vehicle message module 307, a minimum or maximum battery voltage value determined by the determine min/max battery voltage value module 309, an output rate (e.g., a current) determined by the determine output rate module 310, an amount of time counted by a counter, or some other value. Based on those examples, the threshold could include a threshold voltage, a threshold current, or a threshold amount of time. Other examples of thresholds are possible.

As an example, the determine threshold breach module 315 can be configured to determine that sets of battery voltage values (e.g., first, second, or third sets of battery voltages) equal or exceed a threshold battery voltage, or that at least some battery voltages of the sets of battery voltage do not equal or exceed the threshold battery voltage.

As another example, the determine threshold breach module 315 can be configured to determine a vehicle is being driven in a particular mode with a particular output rate continuously for at least a threshold amount of time. As an example, the particular mode can include an electric vehicle mode or a regenerative braking mode. As another example the particular output rate can include a first output rate corresponding to the electric vehicle mode and a second output rate corresponding to the regenerative braking mode.

In accordance with at least some embodiments, the first threshold amount of time is a first fixed amount of time stored in the non-transitory computer-readable memory and the second threshold amount of time is a second fixed amount of time stored in the non-transitory computer-readable memory. In some cases, the first and second fixed amounts of time are identical. In other cases, the first and second fixed amounts of time are different.

### 18) USC Module

The USC module 316 can be configured to provide a user-selectable control at the VST 3 and to determine when a user-selectable control at the VST is selected. In some implementations, providing a USC at the VST 3 can include outputting the USC within a GUI on the display 128. In those or in other implementations, providing a USC at the VST 3 can include configuring a hardware key or button at the VST 3 to be selectable to trigger performance of particular functionality, such as functionality indicated by the configurable function identifier 109, 110, 111, 112.

As an example, the USC module 316 can be configured to provide at the VST 3 a user interface including a user-selectable control selectable to launch an application to test a battery within an electric vehicle. The application is in an un-launched state when the user-selectable control is selectable.

### 19) GCT Module

The GCT module 317 can be configured to provide a user-selectable control at the VST 3 and to determine when a user-selectable control at the VST is selected. In some implementations, providing a USC at the VST 3 can include outputting the USC within a GUI on the display 128, such as the GUI 320 shown in FIG. 38. In those or in other implementations, providing a USC at the VST 3 can include configuring a hardware key or button at the VST 3 to be selectable to trigger performance of particular functionality, such as functionality indicated by the configurable function identifier 109, 110, 111, 112. The GCT module 317 can be configured to configure a test device (e.g., an oscilloscope or a multimeter) with settings specified for a particular guided component test, such as a test within the component test 141. As an example, test device settings can include a voltage scale, amperage scale, ohms scale, a trigger mode, a time scale or some other setting configurable on a test device. In accordance with at least some embodiments, the test device includes a category III or IV oscilloscope or a category III or IV multimeter.

### I. Example Server

Next, FIG. 7 is a block diagram of the server 6 (also shown in FIG. 1) in accordance with at least some of the example embodiments. The server 6 includes a logic segment 55 including a processor 56 and a memory 57. The server 6 also includes a transceiver 58, a user interface 59, a data bus 60, an electrical circuit 61, a housing 62, and/or a power supply 63. The data bus 60 can operatively connect the logic segment 55 (e.g., the processor 56 and/or the memory 57), the transceiver 58, the user interface 59, and/or the power supply 63 to one another. In other words, the data bus 60 can provide an operative connection between two or more of the logic segment 55 (e.g., the processor 56 and/or the memory 57), the transceiver 58, the user interface 59, or the power supply 63. Examples of the processor 56, the memory 57, and the transceiver 58 are described elsewhere in this description. In at least some embodiments of the server 6, the processor 56 is a specific processor that is programmed to perform any function(s) described in this description as being performed by the server 6.

The electrical circuit 61 (e.g., one or more electrical circuits) is configured to distribute electrical current throughout the server 6 and/or provide a voltage within various nodes of electrical components within the server 6. For example, the electrical circuit 61 can comprise one or more electrical circuits for carrying an electrical current from the power supply 63 to the processor 56, the memory 57, the transceiver 58, and/or the user interface 59, and one or more electrical circuits for carrying an electrical current from the processor 56, the memory 57, the transceiver 58, and/or the user interface 59 to the power supply 63. Examples of the power supply 63 are described elsewhere in this description. The transceiver 58 is configured to communicate over the data bus 60.

The housing 62 surrounds at least a portion of the following: the logic segment 55 (e.g., the processor 56 and/or the memory 57), the transceiver 58, the user interface 59, the data bus 60, the electrical circuit 61 and/or the power supply 63. The housing 62 can support a substrate. In at least some example embodiments, at least a portion of the following: the logic segment 55 (e.g., the processor 56 and/or the memory 57), the transceiver 58, the user interface 59, the data bus 60, the electrical circuit 61 and/or the power supply 63 is/are mounted on and/or connected to a substrate of the housing 62. The housing 62 can include a server rack.

The user interface 59 can include an input device and an output device. The user interface 59 can include a display. Examples of a display described elsewhere in this description are applicable to the display of the user interface 59. The display can be configured as an input device and/or an output device. The user interface 59 can display a GUI output by the processor 56. The input device is configured to allow a user to input data into the processor 56.

The memory 57 can include CRPI 64, a GUI 65, vehicle selection data 66, an application 67, thresholds 68, output rates 69, parameter values 70, and test results 97. The CRPI 64 can include a module 98 (e.g., one or more modules). The module 98 can include one or more modules of the module set 299 shown in FIG. 6.

The CRPI 64 can include program instructions executable by a processor, such as the processor 56. As an example, the CRPI 64 can include program instructions that are executable to cause the server 6 to perform any function described as being performed by the server 6, by the processor 56, and/or by some other component of the server 6. As an example, the CRPI 64 can include program instructions executable by the processor to perform at least a portion of one or more functions shown in FIG. 9 to FIG. 22.

The GUI 65 includes one or more GUIs. The GUI 65 can include a GUI that the server 6 transmits (as a service) to the VST 3. As an example, the GUI 65 can include one or more GUI in the GUI 140 shown in FIG. 5. The GUI 65 can include information the server 6 provides to the VST 3 to populate within a GUI on the display 128, such as any GUI shown in FIG. 24 to FIG. 38. The server 6 can transmit GUIs for display at multiple VSTs.

The vehicle selection data 66 can include and/or be arranged as the vehicle selection data 142 shown in FIG. 5. The vehicle selection data 66 can include vehicle selection data for different types of vehicles (e.g., vehicles identified by different year, make and model characteristics). The vehicle selection data can be used when the VST 3 is determining what type of vehicle is connected thereto.

The application 67 can include one or more applications or software packages including multiple executable files, configuration files, and/or modules. As an example, the application 67 can include a server software package, such as an Apache hyper-text transfer protocol (HTTP) server software package or an HTTP web server by Suse LLC of Nuremberg, Germany. As an example, an HTTP web server can be used to transfer and/or receive a file including battery test data, such as a Java Script Object Notation (JSON) or XML file including battery test data. As another example, the application 67 can include a file transfer protocol (FTP) server software package configured for uploading and downloading files to and from the VST.

The thresholds 68 can include thresholds used by any module within the module 98, 139. Examples of such thresholds are described with respect to the module set 299. The thresholds 68 can includes sets of thresholds for different types of vehicles. The server 6 can provide a particular set of thresholds corresponding to a particular type of vehicle when the VST 3 is connected to and/or being used to test a battery system within the particular type of vehicle.

The output rates 69 can include output rates used by any module within the module 98, 139. Examples of such output rates are described with respect to the module set 299. The output rates 69 can includes sets of output rates for different types of vehicles. The server 6 can provide a particular set of output rates corresponding to a particular type of vehicle when the VST 3 is connected to and/or being used to test a battery system within the particular type of vehicle.

The parameter values 70 can include parameter values the VST 3 obtains and/or calculates while testing a battery system with a vehicle. In accordance with at least some embodiments, the VST 3 streams parameter values while performing the battery system test. In accordance with those embodiments, the processor 56 can execute a module within the module 98 to make a determination or perform such other function by the module to carry out the battery system test. In accordance with at least some other embodiments, the VST 3 streams parameter values to the server 6 after completing the battery system test locally. The parameter values can include parameter values provided by multiple VSTs configured to test battery systems in accordance with the example embodiments.

The test results 97 can include test results the VST 3 determines while testing a battery system with a vehicle. In accordance with at least some embodiments, the server 6 determines at least a portion of the test results for a battery system test performed on a particular vehicle. The test results 97 can include test results provided by multiple VSTs configured to test battery systems in accordance with the example embodiments. The server 6 can receive from the VST 3 a request for test results within the test results 97. The server 6 can determine which test results within the test results 97, if any, correspond to the VST 3 requesting the test results or a user associated with the VST 3. The server 6 can provide a list of available test results to the VST 3 for displaying within a GUI at the VST, such as the GUI 270 shown in FIG. 32. The server 6 can provide test results to the VST 3 in response to receiving a selection of particular set of test results.

### J. Example Vehicle Service Tool

Next, FIG. 8 shows the VST 3 in accordance with at least some of the example embodiments. As shown in FIG. 8, the VST 3 includes the housing 121, the display 128, and the input device 129. As shown in FIG. 8, the input device 129 includes a directional user-selectable control 100, a push button user-selectable control 101, 102, 103, 104, a keypad user-selectable control 105, a push button user-selectable control 106 to enter a YES input, a push button user-selectable control 107 to enter a NO input, and a power button 108. FIG. 8 shows a configurable function identifier 109, 110, 111, 112 that corresponds to the push button user-selectable control 101, 102, 103, 104, respectively. The CRPI 138 can include instructions executable to configure the push button user-selectable control 101, 102, 103, 104 to perform functionality indicated by the configurable function identifier 109, 110, 111, 112 when selected. Execution of the USC module 316 can also configure the push button user-selectable control 101, 102, 103, 104 in a like manner. As an example, the push button user-selectable control 101, 102, 103, 104 can be configured to trigger performance of any functionality described with respect to a USC shown in FIG. 24 to FIG. 38.

FIG. 8 shows example aspects of the port 133 of the meter 131 and the port 134 of the of the oscilloscope 132, all shown in FIG. 5. In particular the port 133 can include a port 154, 155, 156. The port 154 and the port 155 can be used when measuring current. The port 155 and the port 156 can be used when measuring voltage. The port 155 can be referred to as a common port. The port 134 can include a port 157 corresponding to channel 1 of the oscilloscope 132 and a port 158 corresponding to channel 2 of the oscilloscope 132.

### III. Example Graphical User Interfaces

As noted, the computing systems (e.g., the VST 3, and/or the server 6) can include a display for displaying a GUI. The drawings show various aspects of GUIs in accordance with the example embodiments. Those aspects include a USC configured to trigger a processor to perform function(s) corresponding to the USC. In at least some embodiments, a USC includes an icon indicative of a function corresponding to the USC FIG. 24 to FIG. 38 shows various views of GUIs in accordance with the example embodiments.

In accordance with at least some embodiments, the processor executes program instructions to output a GUI (such as any GUI described in this description) on a display. If the GUI includes a USC, then the processor can execute program instructions to arm the USC such that selection of the USC while the GUI is output on the display causes a signal change at the processor to interrupt the processor to cause the processor to execute program instructions corresponding to the USC. The program instructions to arm the USC can arm other USCs within the GUI such that selection of the other USCs while the GUI is output on the display causes a signal change at the processor to interrupt the processor to cause the processor to execute program instructions corresponding to the other USCs. The processor can execute program instructions to disarm the USC when the GUI is no longer output on the display.

FIG. 24 shows a GUI 170 that includes a vehicle selection menu. The vehicle selection data 66, 142 shown in FIG. 5 and FIG. 7 can also include data that represents relationships between vehicle model years and the types of vehicles that were built for and/or during each model year. For instance, for a given model year, the vehicle selection data 66, 142 can include data that indicates all vehicle makes that include at least one type of vehicle for the given model year, and for each of those vehicle makes, the vehicle selection data 66, 142 can include data that indicates all vehicle models that correspond to one of the vehicle makes that built at least one type of vehicle for the given model year. In at least some implementations, the vehicle selection data 66, 142 can include data that indicates all engines that are used in each vehicle model. The vehicle selection data 66, 142 can include data that indicates other criteria that can be used to distinguish different groups of common (i.e., like) vehicles. The processor 56, 116 can generate a vehicle selection menu based on the other data within the vehicle selection data 66, 142.

The GUI 170 can include a cursor 171 movable to point to a USC or another item of the GUI 170. The processor 56, 116 can detect the USC or the other item of the GUI 170 is selected when the cursor 171 is disposed on the USC or the other item of the GUI 170. The other GUIs shown in the figures can also include a cursor, similar to the cursor 171, for use in selecting an item of that GUI. For implementations in which the display 128 includes a touch screen display, the GUIs shown in FIG. 24 to FIG. 38 may or may not include a cursor.

As shown in FIG. 24, the GUI 170 includes a year selection menu 172 in which a year selector 173 representing the year 2015 has been selected. The GUI 170 includes a make selection menu 174 in which a make selector 175 representing a make Toyota has been selected. The GUI 170 includes a model selection menu 176 in which a model selector 177 representing the model Auris has been selected. The GUI 170 includes a powertrain selection menu 178 in which an electric selector USC 179 representing an electric vehicle powertrain has been selected. The year selection menu 172 includes a scroll bar 180 to cause the year selection menu 172 to display year(s) not currently shown in the year selection menu 172. Similarly, the make selection menu 174 includes a scroll bar 181 to cause the make selection menu 174 to display make(s) not currently shown in the make selection menu 174. Likewise, the model selection menu 176 includes a scroll bar 182 to cause the model selection menu 176 to display model(s) not currently shown in the model selection menu 176. Other examples of a selected year, make, model, and engine are also possible.

In at least some implementations, the make selection menu 174 is populated with vehicle makes after a year is selected from the year selection menu 172. Similarly, in at least some implementations, the model selection menu 176 is populated with vehicle models after a year is selected from the year selection menu 172 and after a make is selected from the make selection menu 174. Similarly, in at least some implementations, the powertrain selection menu 178 is populated with powertrain identifiers after a model is selected from the model selection menu 176 is populated with vehicle models after a year is selected from the year selection menu 172 and after a make is selected from the make selection menu 174. In alternative implementations, each of the year selection menu 172, the make selection menu 174, the model selection menu 176, or the powertrain selection menu 178 is in a separate GUI without the other of the year selection menu 172, the make selection menu 174, the model selection menu 176, and the powertrain selection menu 178.

In at least some implementations, the GUI 170 also includes a VIN USC 183 for entering an identifier of a particular vehicle. As an example, the VIN USC 183 can be used to type or key-in a vehicle identification number (VIN) associated with the particular vehicle. As another example, the VIN USC 183 can be used to cause the VCT 127 to request a VIN from an ECU in the vehicle 4, 32, 71. The processor 116 can receive the requested VIN and determine at least a year, make, model, and a serial number of the particular vehicle from the VIN.

The GUI 170 includes a vehicle selector USC 184 for capturing a visual indication of a particular vehicle. As an example, in response to selection of the vehicle selector USC 184, the processor 116 can cause a camera of the input device 129 to capture an image, such as an image of a code 185 representing a VIN, and to cause a GUI, such as the GUI 170 or a different GUI, to display a container 186 showing the image of code 185 and to display a representation of the alpha-numeric representation of the VIN 187 as determined by the processor 116 decoding the code 185. As yet another example, in response to selection of the vehicle selector USC 184, the processor 116 can cause a scanner of the user interface 119 to generate an image, such as an image of the code 185, and to cause a GUI, such as the GUI 170 or a different GUI, to display the container 186 showing the image of the code 185 and to display a representation of the alpha-numeric representation of the VIN 187 as determined by the processor 116 decoding the code 185.

The GUI 170 can include a USC 188 selectable to cause the VCT to transmit a VDM to the vehicle 4, 32, 71 to request a VIN corresponding to the vehicle and to cause the processor to identify the vehicle based on a response to the VDM sent to the vehicle. In at least some embodiments, the processor 116 can populate the year selection menu 172, the make selection menu 174, the model selection menu 176, and the powertrain selection menu 178 with selections based on the VIN received in the response to the VDM.

The GUI 170 can include a USC 189 selectable to cause the VCT 127 to transmit one or more VDMs to one or more ECUs in the vehicle 4, 32, 71 to request DTCs from those ECUs and to output DTCs reported to the VST 3 from the ECU(s) within the GUI 170.

The GUI 170 can include a USC 190 selectable to cause the GUI 170 to display USCs selectable to select system(s) and/or component(s) of interest to a user of the VST 3.

The GUI 170 can include a USC 191 selectable to cause the GUI 170 to display USCs selectable to select symptom(s) of interest to a user of the VST 3. The GUI 170 can include a USC 192 that is selectable to enter selections made via the GUI 170.

The GUI 170 (and other GUIs shown in the drawings) includes a back USC 193 selectable to cause the processor 116 to output a previously-displayed GUI (e.g., a most-recently displayed GUI).

Next, FIG. 25 shows a GUI 195 in accordance with the example embodiments. The GUI 195 (and other GUIs shown in the drawings) includes a vehicle identifier 196. The GUI 195 can be output on the display 128. As an example, the GUI 195 can be output on the display in response to making a selection from the GUI 170, such as a selection of the USC 188 or the USC 192 (after prior selections using the year selection menu 172, the make selection menu 174, the model selection menu 176, and the powertrain selection menu 178.

The GUI includes a system selection USC 197, 198, 199, 200, 201, 202, 203, 204, 205 selectable to select an audio system, a high voltage battery system, a body system, a brake system, a low voltage electrical system, a high voltage electrical system, a fuel system, a supplemental inflatable restraints system, and a suspension system, respectively. The systems identified by user-selectable controls shown in the GUI 195 are example systems in accordance with at least some embodiments. Other examples of systems selectable by a USC within the GUI 195 are also possible or a like GUI for another selected vehicle are also possible.

Next, FIG. 26 shows a GUI 210 in accordance with the example embodiments. The GUI 210 can be output on the display 128. As an example, the GUI 210 can be output on the display in response to making a selection from the GUI 195, such as a selection of the system selection USC 198 that corresponds to the high voltage battery system. The GUI 210 includes a diagnostic selector USC 211, 212, 213, 214, 215, 216.

The diagnostic selector USC 211 is selectable to cause the processor 116 to transmit VDMs to the vehicle 4 to request DTCs from the vehicle 4. As an example, the VDMs transmitted to the vehicle 4 can include a request for any and all DTCs set within the vehicle 4. As another example, the VDMs transmitted to the vehicle 4 can include a request for any and all DTCs set by an ECU within the high voltage battery system and any related system ECU. As yet another example, the VDMs transmitted to the vehicle 4 can include a request for any and all DTCs set by an ECU within the high voltage battery system.

The diagnostic selector USC 212 is selectable to cause the processor 116 to transmit VDM(s) to the vehicle 4 to clear DTCs. The VDMs can be directed to all ECUs in the vehicle or to a subset of ECUs within the vehicle 4. As an example, a VDM sent to the vehicle 32 in response to selection of the diagnostic selector USC 211 can include a request to clear DTCs stored in the ECU 34 that controls and/or is part of a battery management system corresponding to the battery pack 92.

The diagnostic selector USC 213 is selectable to cause the processor 116 to transmit VDMs with PID(s) to the vehicle 4 to request PID parameter values. As an example, the PID parameter values can indicate voltage levels, current levels, temperatures, state-of-charge status or some other condition of a component of a battery system within the vehicle 4, 32, 71. The processor can output the PID parameter values on the display 128. As an example, the PID parameter values can be shown using alphanumerical characters. As another example, the PID parameter values can be represented graphically on the display 128.

The diagnostic selector USC 214 is selectable to cause the processor 116 to launch an application for performing a battery system test, and/or to launch one or more modules of a battery system test.

The diagnostic selector USC 215 is selectable to cause the processor 116 to output a GUI, such as the GUI 320 shown in FIG. 38, to provide one or more user-selectable controls selectable to launch execution of the GCT module 317 and/or to configure a test device for performing a test of the component test 141.

The diagnostic selector USC 216 is selectable to cause the processor 116 to launch an application for performing outputting test results, and/or to launch one or more modules for outputting test results. As an example, outputting the test results can include outputting the test results on the display 128. As another example, outputting the test results can include the processor 116 and/or the network transceiver 126 transmitting the test results to another computing system, such as the server 6.

Next, FIG. 27 shows a GUI 220 in accordance with the example embodiments. As an example, the GUI 220 can be output on the display 128 in response to making a selection from the GUI 210 shown in FIG. 26, such as a selection of the diagnostic selector USC 214.

The GUI 220 includes a USC 221, 222, 223. A selection of the USC 221 can cause the processor 116 to output guidance on the display 128 for guiding a user in performing a test of the battery system within a vehicle. In accordance with at least some other embodiments, the guidance can be output on the GUI 220 or a GUI (e.g., the GUI 230) displayed after a selection of the USC 222.

A selection of the USC 222 can be configured to launch an application and/or a module to start a battery system test. The processor 116 can output a GUI, such as the GUI 230 or the GUI 235 in response to the selection of the USC 222. A person having ordinary skill in the art will understand that the processor 116 can begin plotting a graph 239, 242, 245 in response to displaying the GUI 235 (shown in FIG. 29) and the VST 3 receiving corresponding parameter values.

A selection of the USC 223 can cause the processor to perform actions that include and/or lead to outputting test results of battery system tests. As an example, the processor 116 can output a GUI, such as the GUI 260, showing test results. As another example, the processor 116 can output a GUI, such as the GUI 270, showing a list of test results from which the user can select a USC to cause the test results to be displayed.

Next, FIG. 28 shows a GUI 230 in accordance with the example embodiments. The GUI 230 includes guidance 231 and a USC 232. The guidance 231 can provide textual and/or pictorial information that explain how to connect the VST to the vehicle, how to use the VST 3, and/or how to drive the vehicle 4, 32, 71 to test a battery system within the vehicle. The USC 232 can be configured to carry out the same functionality discussed with respect to the USC 232.

Next, FIG. 29 shows a GUI 235 in accordance with the example embodiments. The GUI 235 includes a test identifier 236 and a test mode identifier 237. The test identifier 236 indicates that data within the GUI 235 corresponds to a battery system test in progress, ready to be performed, or after performance. The GUI 235 (and other GUIs shown in the drawings) includes a scroll bar 248 selectable to cause the processor 116 to output a different portion of the GUI containing the scroll bar 248. The GUI 235 includes a data summary container 217, 218, 219, a graph container 226, 227, 228, and a cursor 240, 243, 246 within the graph container 226, 227, 228. The graph container 226, 227, 228 includes a graph 239, 242, 245, respectively.

The data summary container 217, 218, 219 indicates a textual name corresponding to a PID whose parameter values are graphed by the graph 239, 242, 245, respectively. In other words, the graph 239 represents a battery pack current, the graph 242 represents a minimum battery voltage of multiple battery pack components (e.g., battery pack modules) within the battery pack, and the graph 245 represents a maximum battery voltage of multiple battery pack components (e.g., battery pack modules) within the battery pack. The data summary container 217 also includes a current value 207 represented by the graph 239 at a point of the cursor 240, and a range 238 of current values along the graph 239 captured during performance of the battery system test. The data summary container 218 also includes a voltage value 208 represented by the graph 242 at a point of the cursor 243, and a range 241 of voltage values along the graph 242 captured during performance of the battery system test. The data summary container 219 also includes a voltage value 209 represented by the graph 245 at a point of the cursor 246, and a range 244 of voltage values along the graph 245 captured during performance of the battery system test.

In FIG. 29, the test mode identifier 237 indicates a regenerative braking mode. In at least some embodiments, the test mode identifier 237 indicates a mode of the identified test (i.e., battery system test) at a point of the cursor 240, 243, 246. In at least some embodiments, the cursor 240, 243, 246 can be moved, individually, to a different position within the graph container 226, 227, 228, respectively. In at least some embodiments, movement of the cursor 240, 243, 246 occurs uniformly left to right or right to left. As an example, the cursor 240, 243, 246 can be moved to a prior cursor position 233 and the processor can determine which test mode was active at a time when points along the graph 239, 242, 245 at the prior cursor position 233 was added to those graphs.

The GUI 235 includes a USC 160 selectable to cause the processor 116 to clear the ranges shown on a GUI (e.g., the range 238, 241, 244). As an example, clearing the ranges can include overwriting parameter values stored previously within the parameter values 147 or elsewhere. As another example, clearing the ranges in response a selection of the USC 160 can cause ranges displayed on a GUI (e.g., the range 238, 241, 244) to be cleared (e.g., show as dashes or blank spaces) until subsequent parameter values corresponding to the cleared ranges are received.

The GUI 235 includes a USC 247 selectable to cause the processor 116 to output test results of the battery system test. In some embodiments, the test results are output within the GUI 235 or a GUI that includes the test results and at least some of the content of the GUI 235. In at least some other embodiments, the test results are output within a GUI, such as the GUI 260 shown in FIG. 31 or the GUI 460 shown in FIG. 33.

A person having ordinary skill in the art will understand that the term “Batt Module” within the data summary container 218, 219 can indicate and/or be replaced with “Battery Module” “Batt Block,” or “Battery Block.”

Next, FIG. 30 shows a GUI 250 in accordance with the example embodiments. The GUI 250 includes the test identifier 236 and the test mode identifier 237. The test identifier 236 indicates that data within the GUI 250 corresponds to the battery system test in progress, ready to be performed, or after performance. The GUI 250 includes a data summary container 283, 284, 285, a graph container 280, 281, 282, and a cursor 253, 256, 259 within the graph container 280, 281, 282. The graph container 280, 281, 282 includes a graph 252, 255, 258, respectively.

The data summary container 283, 284, 285 indicates a textual name corresponding to a PID whose parameter values are graphed by the graph 252, 255, 258, respectively. In other words, the graph 252 represents a battery pack current, the graph 255 represents a minimum battery voltage of multiple battery pack components (e.g., battery pack modules) within the battery pack, and the graph 258 represents a maximum battery voltage of multiple battery pack components (e.g., battery pack modules) within the battery pack. The data summary container 283 also includes a current value 286 represented by the graph 252 at a point of the cursor 253, and a range 251 of current values along the graph 252 captured during performance of the battery system test. The data summary container 284 also includes a voltage value 287 represented by the graph 255 at a point of the cursor 256, and a range 254 of voltage values along the graph 255 captured during performance of the battery system test. The data summary container 285 also includes a voltage value 288 represented by the graph 258 at a point of the cursor 259, and a range 257 of voltage values along the graph 258 captured during performance of the battery system test.

In FIG. 30, the test mode identifier 237 indicates an electric vehicle (EV) mode. In at least some embodiments, the test mode identifier 237 indicates a mode of the identified test (i.e., battery system test) at a point of the cursor 253, 256, 259. In at least some embodiments, the cursor 253, 256, 259 can be moved, individually, to a different position within the graph container 280, 281, 282, respectively. In at least some embodiments, movement of the cursor 253, 256, 259 occurs uniformly left to right or right to left. As an example, the cursor 253, 256, 259 can be moved to a prior cursor position 233 and the processor can determine which test mode was active at a time when points along the graph 252, 255, 258 at the prior cursor position 233 was added to those graphs.

The GUI 250 includes a USC 279 selectable to cause the processor 116 to output test results of the battery system test. In some embodiments, the test results are output within the GUI 250 or a GUI that includes the test results and at least some of the content of the GUI 250. In at least some other embodiments, the test results are output within a GUI, such as the GUI 260 shown in FIG. 31 or the GUI 460 shown in FIG. 33. The GUI 250 includes the USC 160 discussed above.

A person having ordinary skill in the art will understand that the term “Batt Block” within the data summary container 284, 285 can indicate and/or be replaced with “Batt Module” “Battery Module,” or “Battery module.”

Next, FIG. 31 shows a GUI 260 in accordance with the example embodiments. The GUI 260 shows test results of a battery system test. A GUI showing test results, such as the GUI 260, can be displayed on the display 128 in response to selection of a USC while another GUI is displayed, such as the diagnostic selector USC 216 shown in FIG. 26, the USC 223 shown in FIG. 27, the USC 247 shown in FIG. 29, the USC 279 shown in FIG. 30, or a USC 273 shown in FIG. 32. The test results shown in the GUI can include test results determined by execution of the determine test condition/result module 305, the determine min/max battery voltage value module 309, and one or more other modules.

The GUI 260 includes an identifier 261 indicating what the test results pertain to (i.e., results of a battery system test). The GUI 260 includes an identifier 262 of the particular vehicle whose battery system was tested. As an example, the identifier 262 can include a VIN or some portion of a VIN corresponding the particular vehicle. The GUI 260 includes a temporal indicator 263 corresponding to when the battery system was tested. As an example, the temporal indicator 263 can include a date on which the test was performed. As another example, the temporal indicator 263 can include a time corresponding to when the test was performed, such as a start time and/or a completion time.

The GUI 260 includes test results 264 corresponding to measurements made while the vehicle operated within a regenerative braking mode, and test results 265 corresponding to measurements made while the vehicle operated within an electric vehicle mode.

The test results 264 includes battery pack current values and range data 289, battery pack component (BPC) minimum voltage and range data 290, battery pack component (BPC) maximum voltage and range data 291, delta values 292 indicating differences between corresponding minimum and maximum voltages, an average state of charge value 293 and a specification value 294. The test result 264 shows seven data values for each of the battery pack current values and range data 289, the battery pack component (BPC) minimum voltage and range data 290, the battery pack component (BPC) maximum voltage and range data 291, and the delta values 292. In accordance with the example embodiments, the test results 264 or other test results determined by performance of a described test may include values for a different quantity of data points.

The specification value can indicate a specified, average state-of-charge range for a particular type of battery within the tested vehicle. As an example, the specification value 294 for nickel-metal hydride (NiMH) batteries can be 40-65%. As another example, the specification value 294 for lithium ion batteries can be 20-80%. Other examples are possible.

The test results 265 includes battery pack current values and range data 295, battery pack component (BPC) minimum voltage and range data 296, battery pack component (BPC) maximum voltage and range data 297, delta values 298 indicating differences between corresponding minimum and maximum voltages, an average state of charge value 224 and a specification value 225. The test result 265 shows seven data values for each of the battery pack current values and range data 295, the battery pack component (BPC) minimum voltage and range data 296, the battery pack component (BPC) maximum voltage and range data 297, and the delta values 298.

The GUI 260 also includes a test result indicator 266. As shown in FIG. 31, the test result indicator 266 can indicate “Test Passed.” Based on different results, the test results indicator 266 can indicate “Test Failed.” Based on still other results, the test results indicator 266 can indicate ‘Test Inconclusive.” Such indication could be output for various reasons, such as the test was not completed or the battery system set a diagnostic trouble code during performance of the test.

A person having ordinary skill in the art will understand that the term “Batt Module” within the test results 264, 265 or elsewhere can indicate and/or be replaced with “Battery Module,” “Batt Block,” or “Battery Block.”

The GUI 260 includes a graph view USC 234 selectable to cause the processor 116 to output on the display 128 a graphed view of test results. As an example, a selection of the graph view USC 234 while the GUI 260 is displayed can cause the processor 116 to output a GUI 500 shown in FIG. 34 or the GUI 510 shown in FIG. 35.

Next, FIG. 32 shows a GUI 270 in accordance with the example embodiments. The GUI 270 includes a set 271 of test results sorted temporally (e.g., by date). The set 271 of test results includes a USC 272, 273, 274, 275, 276, 277. Those USCs and/or the GUI 270 include a vehicle identification data so that a user can locate test results for a particular vehicle. As an example, selection of the USC 273 can cause the processor 116 to output the GUI 260 shown in FIG. 31. The GUI 270 includes a USC 278 to select a date range to search for test results generated on a day within the selected date range. Selection of the USC 272, 274, 275, 276, 277 can cause the processor to display a GUI showing test results similar to how test results are output in the GUI 260 shown in FIG. 31, but for the vehicle indicated by the USC 272, 274, 275, 276, 277.

Next, FIG. 33 shows a GUI 460 in accordance with the example embodiments. The GUI 460 shows test results of a battery system test. A GUI showing test results, such as the GUI 460, can be displayed on the display 128 in response to selection of a USC while another GUI is displayed, such as the diagnostic selector USC 216 shown in FIG. 26, the USC 223 shown in FIG. 27, the USC 247 shown in FIG. 29, the USC 279 shown in FIG. 30, or a USC 273 shown in FIG. 32. The test results shown in the GUI can include test results determined by execution of the determine test condition/result module 305, the determine min/max battery voltage value module 309, and one or more other modules.

The GUI 460 includes an identifier 461 indicating what the test results pertain to (i.e., results of a battery system test). The GUI 460 includes an identifier 462 of the particular vehicle whose battery system was tested. As an example, the identifier 462 can include a VIN or some portion of a VIN corresponding the particular vehicle. The GUI 460 includes a temporal indicator 463 corresponding to when the battery system was tested. As an example, the temporal indicator 463 can include a date on which the test was performed. As another example, the temporal indicator 463 can include a time corresponding to when the test was performed, such as a start time and/or a completion time.

The GUI 460 includes test results 464 corresponding to measurements made while the vehicle operated within a regenerative braking mode, and test results 465 corresponding to measurements made while the vehicle operated within an electric vehicle mode.

The test results 464 includes battery pack current values and range data 466, battery pack component (BPC) minimum voltage and range data 467, battery pack component (BPC) maximum voltage and range data 468, delta values 469 indicating differences between corresponding minimum and maximum voltages, an average state of charge value 470 and a specification value 471. The test result 464 shows seven data values for each of the battery pack current values and range data 466, the battery pack component (BPC) minimum voltage and range data 467, the battery pack component (BPC) maximum voltage and range data 468, and the delta values 469. In accordance with the example embodiments, the test results 464 or other test results determined by performance of a described test may include values for a different quantity of data points.

The test results 465 includes battery pack current values and range data 472, battery pack component (BPC) minimum voltage and range data 473, battery pack component (BPC) maximum voltage and range data 474, delta values 475 indicating differences between corresponding minimum and maximum voltages, an average state of charge value 476 and a specification value 447. The test result 465 shows seven data values for each of the battery pack current values and range data 472, the battery pack component (BPC) minimum voltage and range data 473, the battery pack component (BPC) maximum voltage and range data 474, and the delta values 475.

The GUI 460 also includes a test result indicator 478. As shown in FIG. 33, the test result indicator 478 can indicate “Test Failed.” Based on different results, the test results indicator 478 can indicate different results as discussed with respect to the test result indicator 266.

The GUI 460 includes the graph view USC 234. A selection of the graph view USC 234 while the GUI 460 is displayed can cause the processor 116 to output a GUI 520 shown in FIG. 36 or the GUI 530 shown in FIG. 37.

Next, FIG. 34 shows a GUI 500 in accordance with the example embodiments. The GUI 500 shows test results from a battery system test performed while the vehicle identified by the vehicle identifier 196 was in the EV mode (as indicated by a test mode indicator 502). A notification 503 indicates a conclusion the processor 116 determines by performing the battery system test. The GUI 500 includes a container 501 showing a graph 505 of battery pack current measurements and a bar chart 506 of data values (DV) corresponding to battery pack component (BPC) minimum and maximum voltage measurements. A legend 504 is provided for identifying how the current and voltage measurements are represented in the container 501. The labels 507 represent voltage values for the bar chart 506. The labels 508 represent current values for the graph 505.

A GUI showing test results, such as the GUI 500, can be displayed on the display 128 in response to selection of a USC while another GUI is displayed, such as the diagnostic selector USC 216 shown in FIG. 26, the USC 223 shown in FIG. 27, the USC 247 shown in FIG. 29, the USC 279 shown in FIG. 30, the graph view USC 234 shown in FIG. 31, or a USC 273 shown in FIG. 32. The test results shown in the GUI 500 can include test results determined by execution of the determine test condition/result module 305, the determine min/max battery voltage value module 309, and one or more other modules.

The GUI 500 includes a USC 509 selectable to cause the processor 116 to switch to a GUI showing a table view of the test results, such as the GUI 260 shown in FIG. 31. The GUI 500 includes a USC 510 selectable to cause the processor 116 to switch to displaying a GUI showing test results while the vehicle identified by the vehicle identifier 196 was in the regenerative braking mode, such as a GUI 520 shown in FIG. 35.

Next, FIG. 35 shows the GUI 520 in accordance with the example embodiments. The GUI 520 shows test results from a battery system test performed while the vehicle identified by the vehicle identifier 196 was in the regenerative braking mode (as indicated by a test mode indicator 522). A notification 523 indicates a conclusion the processor 116 determines by performing the battery system test. The GUI 520 includes a container 521 showing a graph 525 of battery pack current measurements and a bar chart 526 of data values (DV) corresponding to battery pack component (BPC) minimum and maximum voltage measurements. A legend 524 is provided for identifying how the current and voltage measurements are represented in the container 521. The labels 527 represent voltage values for the bar chart 526. The labels 528 represent current values for the graph 525.

A GUI showing test results, such as the GUI 520, can be displayed on the display 128 in response to selection of a USC while another GUI is displayed, such as the diagnostic selector USC 216 shown in FIG. 26, the USC 223 shown in FIG. 27, the USC 247 shown in FIG. 29, the USC 279 shown in FIG. 30, the graph view USC 234 shown in FIG. 31, or a USC 273 shown in FIG. 32. The test results shown in the GUI 520 can include test results determined by execution of the determine test condition/result module 305, the determine min/max battery voltage value module 309, and one or more other modules.

The GUI 520 includes the USC 509 selectable to cause the processor 116 to switch to a GUI showing a table view of the test results, such as the GUI 260 shown in FIG. 31. The GUI 520 includes a USC 529 selectable to cause the processor 116 to switch to displaying a GUI showing test results while the vehicle identified by the vehicle identifier 196 was in the EV mode, such as the GUI 500 shown in FIG. 34.

Next, FIG. 36 shows a GUI 530 in accordance with the example embodiments. The GUI 530 shows test results from a battery system test performed while the vehicle identified by the vehicle identifier 196 was in the EV mode (as indicated by a test mode indicator 532). A notification 533 indicates a conclusion the processor 116 determines by performing the battery system test. The GUI 530 includes a container 531 showing a graph 535 of battery pack current measurements and a bar chart 536 of data values (DV) corresponding to battery pack component (BPC) minimum and maximum voltage measurements. A legend 534 is provided for identifying how the current and voltage measurements are represented in the container 531. The labels 537 represent voltage values for the bar chart 536. The labels 538 represent current values for the graph 535.

A GUI showing test results, such as the GUI 530, can be displayed on the display 128 in response to selection of a USC while another GUI is displayed, such as the diagnostic selector USC 216 shown in FIG. 26, the USC 223 shown in FIG. 27, the USC 247 shown in FIG. 29, the USC 279 shown in FIG. 30, the graph view USC 234 shown in FIG. 31, or a USC 273 shown in FIG. 32. The test results shown in the GUI 530 can include test results determined by execution of the determine test condition/result module 305, the determine min/max battery voltage value module 309, and one or more other modules.

The GUI 530 includes a USC 539 selectable to cause the processor 116 to switch to a GUI showing a table view of the test results, such as the GUI 460 shown in FIG. 33. The GUI 530 includes a USC 540 selectable to cause the processor 116 to switch to displaying a GUI showing test results while the vehicle identified by the vehicle identifier 196 was in the regenerative braking mode, such as a GUI 550 shown in FIG. 37.

Next, FIG. 37 shows the GUI 550 in accordance with the example embodiments. The GUI 550 shows test results from a battery system test performed while the vehicle identified by the vehicle identifier 196 was in the regenerative braking mode (as indicated by a test mode indicator 552). A notification 553 indicates a conclusion (e.g., test failed) the processor 116 determines by performing the battery system test. The GUI 550 includes a container 551 showing a graph 555 of battery pack current measurements and a bar chart 556 of data values (DV) corresponding to battery pack component (BPC) minimum and maximum voltage measurements.

A legend 554 is provided for identifying how the current and voltage measurements are represented in the container 551. The labels 557 represent voltage values for the bar chart 556. The labels 558 represent current values for the graph 555.

A GUI showing test results, such as the GUI 550, can be displayed on the display 128 in response to selection of a USC while another GUI is displayed, such as the diagnostic selector USC 216 shown in FIG. 26, the USC 223 shown in FIG. 27, the USC 247 shown in FIG. 29, the USC 279 shown in FIG. 30, the graph view USC 234 shown in FIG. 31, or a USC 273 shown in FIG. 32. The test results shown in the GUI 550 can include test results determined by execution of the determine test condition/result module 305, the determine min/max battery voltage value module 309, and one or more other modules.

The GUI 550 includes the USC 539 selectable to cause the processor 116 to switch to a GUI showing a table view of the test results, such as the GUI 460 shown in FIG. 33. The GUI 550 includes a USC 559 selectable to cause the processor 116 to switch to displaying a GUI showing test results while the vehicle identified by the vehicle identifier 196 was in the EV mode, such as the GUI 530 shown in FIG. 36.

Next, FIG. 38 shows a GUI 320 in accordance with the example embodiments. The GUI 320 can be output on the display 128. As an example, the GUI 320 can be output on the display in response to making a selection from the GUI 210, such as a selection of the system selection USC 215 that corresponds to guided component tests 215. The GUI 320 includes a GCT selector USC 321, 322, 323, 324, 325, 326 corresponding to six guided component tests indicated as GCT-1, GCT-2, GCT-3, GCT-4, GCT-5, and GCT-6, where “GCT” represents guided component test. Other example embodiments can include a different quantity of GCT selectors and/or different guided component tests corresponding to the GCT selectors.

The GCT selector USC 321, 322, 323, 324, 325, 326 corresponds to different guided component tests. One or more or all of the GCT selector USC 321, 322, 323, 324, 325, 326 can correspond to guided component tests for components of a battery system of an electric vehicle. As an example, the GCT selector USC 321 can correspond to a voltage test for a battery fan, the GCT selector 322 can correspond to a resistance test for a battery fan, the GCT selector 323 can correspond to a temperature test for a battery pack, the GCT 324 can correspond to a voltage test for a temperature sensor within the battery pack, the GCT selector USC 325 can correspond to a voltage test of a battery cell, and the GCT selector 326 can correspond to a current test of a currently in a circuit connected to a battery.

### Example Operation IV

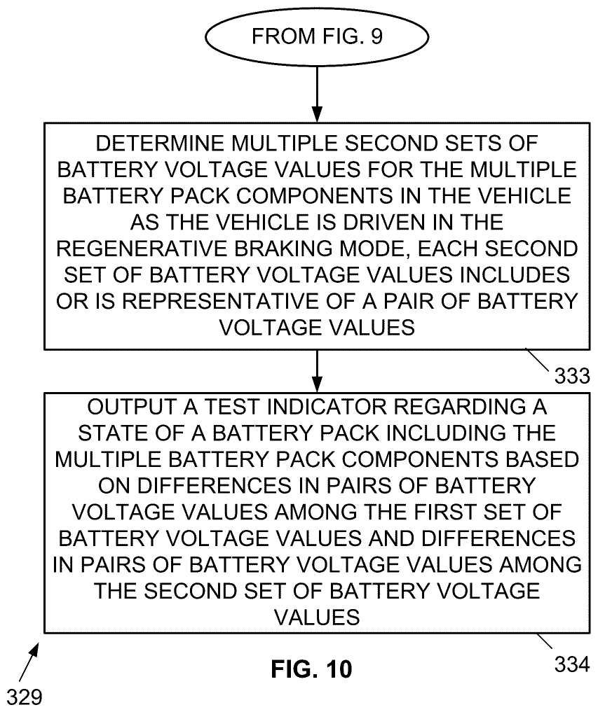

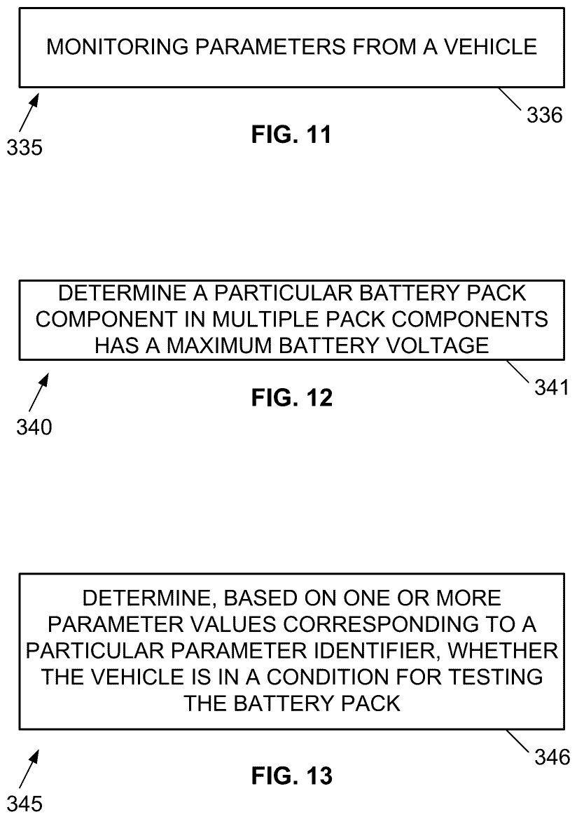

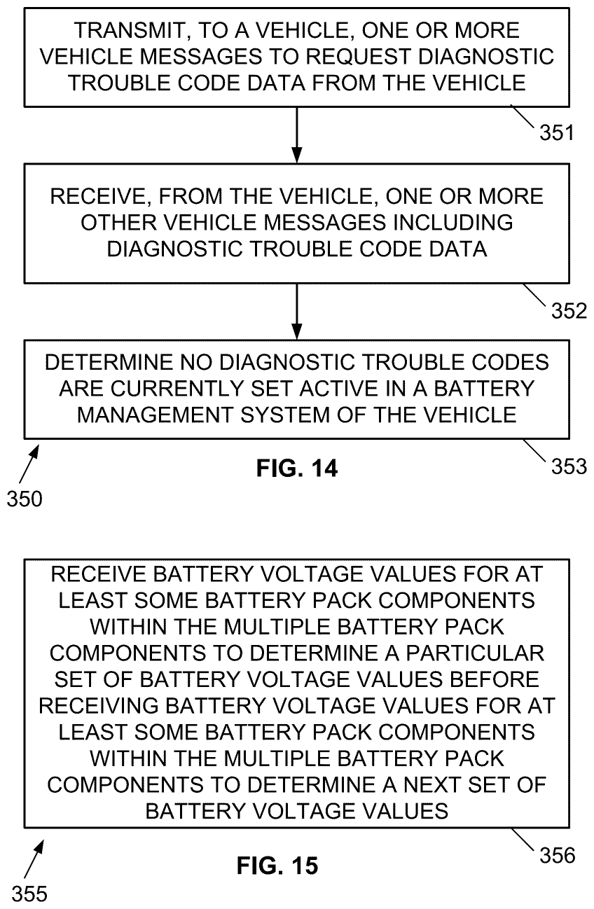

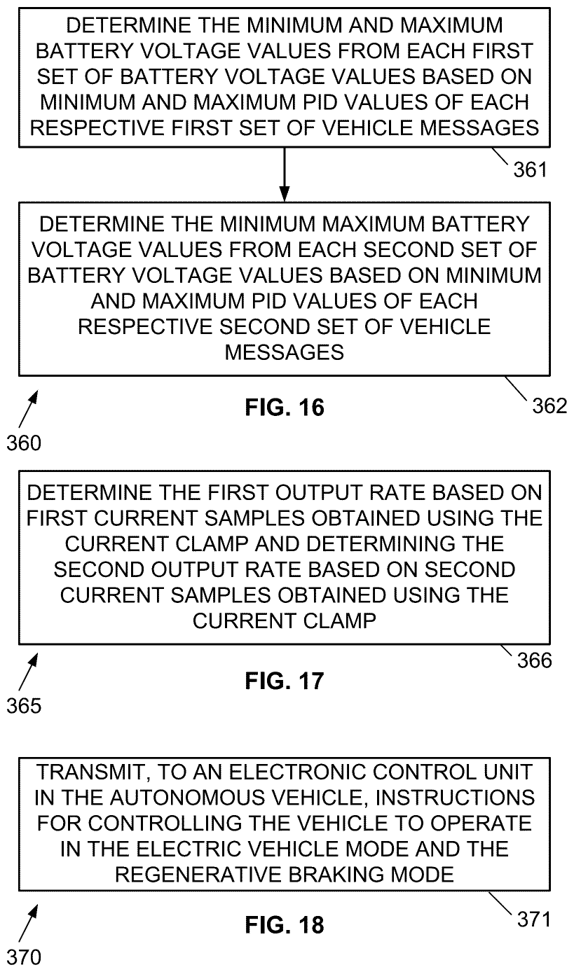

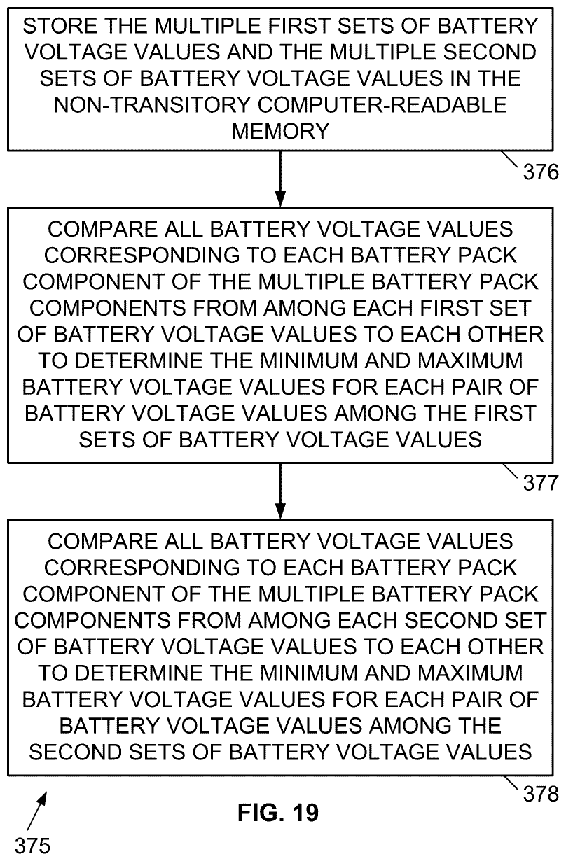

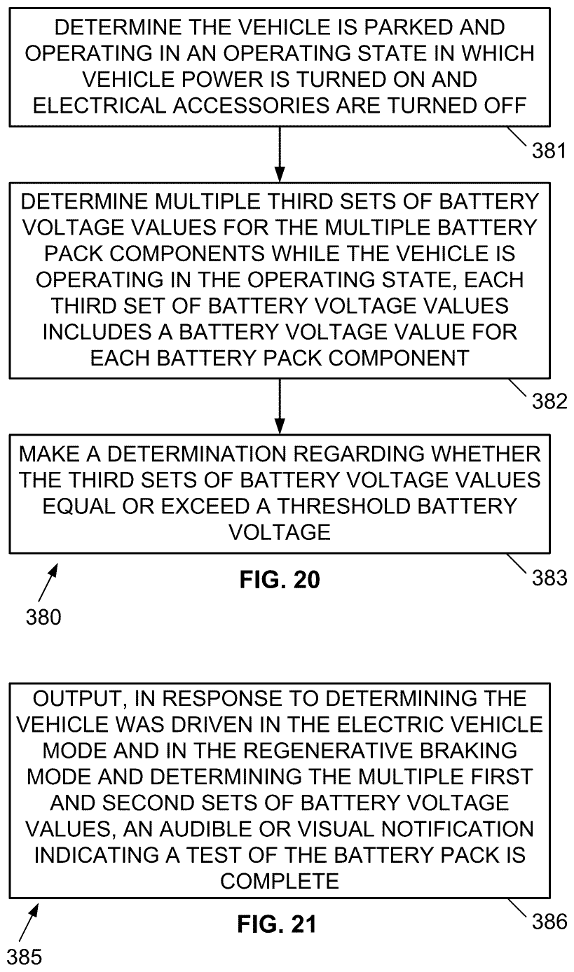

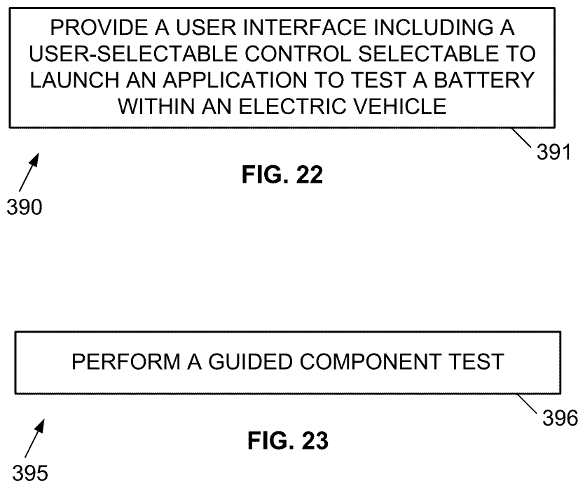

Next, FIG. 9 and FIG. 10 show a flow chart showing a function set 329 (e.g., a set of function(s)) of a method in accordance with the example embodiments. The functions of the function set 329 are shown in a block 330, 331, 332 shown in FIG. 9 and a block 333, 334 shown in FIG. 10, and are arranged as a flowchart. Two or more functions and/or portions of two or more functions of the function set 329 or of any other function set described in this description can be performed at the same time. The functions of the function set 329 can be performed by one or more computing systems, such as the VST 3, the server 6, and/or the computing system 670 shown in FIG. 43. A computing system configured to perform a function of the function set 329 can perform other function(s) besides those shown in FIG. 9 and FIG. 10. As an example, those other function(s) can include one or more functions of one or more of the functions sets shown in FIG. 11 to FIG. 22, any other function described in this description, and/or any function represented in a drawing of this disclosure.

Block 330 includes determining a vehicle is being driven in an electric vehicle mode with a first output rate continuously for at least a first threshold amount of time. The function(s) of block 330 can be performed by a processor (e.g., one or more hardware processors) configured by machine-readable instructions including a module that is the same as or similar to the determine vehicle driving mode module 300, in accordance with the example embodiments. The function(s) of block 330 can include one or more of the functions described with respect to the determine vehicle driving mode module 300.

Next, block 331 includes determining multiple first sets of battery voltage values for multiple battery pack components (e.g., battery pack modules, strings, or cells) in the vehicle as the vehicle is driven in the electric vehicle mode with the first output rate continuously for at least the first threshold amount of time. Each first set of battery voltage values includes or is representative of a pair of battery voltage values. The function(s) of block 331 can be performed by a processor (e.g., one or more hardware processors) configured by machine-readable instructions including a module that is the same as or similar to the determine battery voltage values module 301, in accordance with the example embodiments. The function(s) of block 331 can include one or more of the functions described with respect to the determine battery voltage values module 301. Each first set of battery voltage values can correspond to each other temporally and/or with respect to a common data point.

Next, block 332 includes determining the vehicle is being driven in a regenerative braking mode with a second output rate continuously for at least a second threshold amount of time. The function(s) of block 332 can be performed by a processor (e.g., one or more hardware processors) configured by machine-readable instructions including a module that is the same as or similar to the determine vehicle driving mode module 300, in accordance with the example embodiments. The function(s) of block 332 can include one or more of the functions described with respect to the determine vehicle driving mode module 300.

Next, block 333 includes determining multiple second sets of battery voltage values for the multiple battery pack components in the vehicle as the vehicle is driven in the regenerative braking mode, each second set of battery voltage values includes or is representative of a pair of battery voltage values. The function(s) of block 333 can be performed by a processor (e.g., one or more hardware processors) configured by machine-readable instructions including a module that is the same as or similar to the determine battery voltage values module 301, in accordance with the example embodiments. The function(s) of block 333 can include one or more of the functions described with respect to the determine battery voltage values module 301. Each second set of battery voltage values can correspond to each other temporally and/or with respect to a common data point.

Next, block 334 includes outputting a test indicator regarding a state of a battery pack including the multiple battery pack components based on differences in pairs of battery voltage values among the first set of battery voltage values and differences in pairs of battery voltage values among the second set of battery voltage values. The function(s) of block 334 can be performed by a processor (e.g., one or more hardware processors) configured by machine-readable instructions including a module that is the same as or similar to the output test indicator module 302, in accordance with the example embodiments. The function(s) of block 334 can include one or more of the functions described with respect to the output test indicator module 302.

Turning to FIG. 11, a function set 335 including function(s) within a block 336 is shown. Block 336 includes monitoring parameters from the vehicle. The function(s) of block 336 can be performed by a processor (e.g., one or more hardware processors) configured by machine-readable instructions including a module that is the same as or similar to the monitor parameters module 303, in accordance with the example embodiments. The function(s) of block 336 can include one or more of the functions described with respect to the monitor parameters module 303.

In accordance with at least some embodiments, the parameters include a first set of parameters indicative of a first electrical current and a system voltage within the vehicle, and a second set of parameters indicative of a second electrical current and the system voltage. Additionally, the first electrical current is different than the second electrical current. Moreover, determining the vehicle is being driven in the electric vehicle mode with the first output rate is based on the first set of parameters, and determining the vehicle is being driven in the regenerative braking mode with the second output rate is based on the second set of parameters.

Turning to FIG. 12, a function set 340 including function(s) within a block 341 is shown. Block 341 includes determining a particular battery pack component in the multiple battery pack components has a maximum battery voltage. The function(s) of block 341 can be performed by a processor (e.g., one or more hardware processors) configured by machine-readable instructions including a module that is the same as or similar to the determine particular battery pack component module 304, in accordance with the example embodiments. The function(s) of block 341 can include one or more of the functions described with respect to the determine particular battery pack component module 304.

Turning to FIG. 13, a function set 345 including function(s) within a block 346 is shown. Block 346 includes determining, based on one or more parameter values corresponding to a particular parameter identifier, whether the vehicle is in a condition for testing the battery pack. As an example, the one or more parameter values corresponding to the particular parameter identifier are representative of a battery state-of-charge, a battery temperature, or a DTC status. The function(s) of block 346 can be performed by a processor (e.g., one or more hardware processors) configured by machine-readable instructions including a module that is the same as or similar to the determine test condition/result module 305, in accordance with the example embodiments. The function(s) of block 346 can include one or more of the functions described with respect to the determine test condition/result module 305.

Next, FIG. 14 shows a function set 350 including function(s) within a block 351, 352, 353.

Block 351 includes transmitting, to the vehicle, one or more vehicle messages to request diagnostic trouble code data from the vehicle. The function(s) of block 351 can be performed by a processor (e.g., one or more hardware processors) configured by machine-readable instructions including a module that is the same as or similar to the transmit vehicle message module 306, in accordance with the example embodiments. The function(s) of block 351 can include one or more of the functions described with respect to the transmit vehicle message module 306.

Block 352 includes receiving, from the vehicle, one or more other vehicle messages including diagnostic trouble code data. The function(s) of block 352 can be performed by a processor (e.g., one or more hardware processors) configured by machine-readable instructions including a module that is the same as or similar to the receive vehicle message module 307, in accordance with the example embodiments. The function(s) of block 352 can include one or more of the functions described with respect to the receive vehicle message module 307.

Block 353 includes determining no diagnostic trouble codes are currently set active in a battery management system of the vehicle. The function(s) of block 353 can be performed by a processor (e.g., one or more hardware processors) configured by machine-readable instructions including a module that is the same as or similar to the determine DTC state module 308, in accordance with the example embodiments. The function(s) of block 353 can include one or more of the functions described with respect to the determine DTC state module 308.

Turning to FIG. 15, a function set 355 including function(s) within a block 356 is shown. Block 356 includes receiving battery voltage values for at least some battery pack components within the multiple battery pack components to determine a particular set of battery voltage values before receiving battery voltage values for at least some battery pack components within the battery pack components to determine a next set of battery voltage values. The function(s) of block 356 can be performed by a processor (e.g., one or more hardware processors) configured by machine-readable instructions including a module that is the same as or similar to the determine battery voltage values module 301, in accordance with the example embodiments. The function(s) of block 356 can include one or more of the functions described with respect to the determine battery voltage values module 301.

Next, FIG. 16 shows a function set 360 including function(s) within a block 361, 362.

Block 361 includes determining the minimum and maximum battery voltage values from each first set of battery voltage values based on minimum and maximum PID parameter values of each respective first set of vehicle messages. The function(s) of block 361 can be performed by a processor (e.g., one or more hardware processors) configured by machine-readable instructions including a module that is the same as or similar to the determine min/max battery voltage value module 309, in accordance with the example embodiments. The function(s) of block 361 can include one or more of the functions described with respect to the determine min/max battery voltage value module 309.

Block 362 includes receiving, from the vehicle, one or more other vehicle messages including diagnostic trouble code data. The function(s) of block 362 can be performed by a processor (e.g., one or more hardware processors) configured by machine-readable instructions including a module that is the same as or similar to the determine min/max battery voltage value module 309, in accordance with the example embodiments. The function(s) of block 362 can include one or more of the functions described with respect to the determine min/max battery voltage value module 309.

Turning to FIG. 17, a function set 365 including function(s) within a block 366 is shown. Block 366 includes determining the first output rate based on first current samples obtained using the current clamp meter and determining the second output rate based on second current samples obtained using the current clamp meter. The function(s) of block 366 can be performed by a processor (e.g., one or more hardware processors) configured by machine-readable instructions including a module that is the same as or similar to the determine output rate module 310, in accordance with the example embodiments. The function(s) of block 366 can include one or more of the functions described with respect to the determine output rate module 310.

Turning to FIG. 18, a function set 370 including function(s) within a block 371 is shown. Block 371 includes transmitting, to an electronic control unit in the autonomous vehicle, instructions for controlling the vehicle to operate in the electric vehicle mode and the regenerative braking mode. The function(s) of block 371 can be performed by a processor (e.g., one or more hardware processors) configured by machine-readable instructions including a module that is the same as or similar to the transmit instructions module 311, in accordance with the example embodiments. The function(s) of block 371 can include one or more of the functions described with respect to the transmit instructions module 311.

Next, FIG. 19 shows a function set 375 including function(s) within a block 376, 377, 378.

Block 376 includes storing the multiple first sets of battery voltage values and the multiple second sets of battery voltage values in the non-transitory computer-readable memory. The function(s) of block 376 can be performed by a processor (e.g., one or more hardware processors) configured by machine-readable instructions including a module that is the same as or similar to the store parameter values module 312, in accordance with the example embodiments. The function(s) of block 376 can include one or more of the functions described with respect to the store parameter values module 312.

Block 377 includes comparing all battery voltage values corresponding to each battery pack component of the multiple battery pack components from among each first set of battery voltage values to each other to determine the minimum and maximum battery voltage values for each pair of battery voltage values among the first sets of battery voltage values. The function(s) of block 377 can be performed by a processor (e.g., one or more hardware processors) configured by machine-readable instructions including a module that is the same as or similar to the compare battery voltage values module 313, in accordance with the example embodiments. The function(s) of block 377 can include one or more of the functions described with respect to the compare battery voltage values module 313.

Block 378 includes comparing all battery voltage values corresponding to each battery pack component of the multiple battery pack components from among each second set of battery voltage values to each other to determine the minimum and maximum battery voltage values for each pair of battery voltage values among the second sets of battery voltage values. The function(s) of block 378 can be performed by a processor (e.g., one or more hardware processors) configured by machine-readable instructions including a module that is the same as or similar to the compare battery voltage values module 313, in accordance with the example embodiments. The function(s) of block 378 can include one or more of the functions described with respect to the compare battery voltage values module 313.

Next, FIG. 20 shows a function set 380 including function(s) within a block 381, 382, 383.

Block 381 includes determining the vehicle is parked and operating in an operating state in which vehicle power is turned on and electrical accessories are turned off. The function(s) of block 381 can be performed by a processor (e.g., one or more hardware processors) configured by machine-readable instructions including a module that is the same as or similar to the determine vehicle operating state module 314, in accordance with the example embodiments. The function(s) of block 381 can include one or more of the functions described with respect to the determine vehicle operating state module 314.

Block 382 includes determining multiple third sets of battery voltage values for the multiple battery pack components while the vehicle is operating in the operating state. Each third set of battery voltage values includes a battery voltage value for each battery pack component of the multiple battery pack components. The function(s) of block 382 can be performed by a processor (e.g., one or more hardware processors) configured by machine-readable instructions including a module that is the same as or similar to the determine battery voltage values module 301, in accordance with the example embodiments. The function(s) of block 382 can include one or more of the functions described with respect to the determine battery voltage values module 301.

Block 383 includes determining the third sets of battery voltage values equal or exceed a threshold battery voltage or at least some battery voltages of the third sets of battery voltage do not equal or exceed the threshold battery voltage. The function(s) of block 383 can be performed by a processor (e.g., one or more hardware processors) configured by machine-readable instructions including a module that is the same as or similar to the determine threshold breach module 315, in accordance with the example embodiments. The function(s) of block 383 can include one or more of the functions described with respect to the determine threshold breach module 315.

Turning to FIG. 21, a function set 385 including function(s) within a block 386 is shown. Block 386 includes outputting, in response to determining the vehicle was driven in the electric vehicle mode and in the regenerative braking mode and determining the multiple first and second sets of battery voltage values, an audible or visual notification indicating a test of the battery pack is complete. The function(s) of block 386 can be performed by a processor (e.g., one or more hardware processors) configured by machine-readable instructions including a module that is the same as or similar to the determine output test indicator module 302, in accordance with the example embodiments. The function(s) of block 386 can include one or more of the functions described with respect to the determine output test indicator module 302.

Turning to FIG. 22, a function set 390 including function(s) within a block 391 is shown. Block 391 includes providing at the computing system a user interface including a user-selectable control selectable to launch an application to test a battery within an electric vehicle. The application is in an un-launched state when the user-selectable control is selectable. The function(s) of block 391 can be performed by a processor (e.g., one or more hardware processors) configured by machine-readable instructions including a module that is the same as or similar to the USC module 316, in accordance with the example embodiments. The function(s) of block 391 can include one or more of the functions described with respect to the USC module 316.

Turning to FIG. 23, a function set 395 including function(s) within a block 396 is shown. Block 396 includes performing a guided component test. The function(s) of block 396 can be performed by a processor (e.g., one or more hardware processors) configured by machine-readable instructions including a module that is the same as or similar to the GCT module 317, in accordance with the example embodiments. The function(s) of block 396 can include one or more of the functions described with respect to the GCT module 317.

### V. Example Vehicle

A vehicle is a mobile machine that can be used to transport a person, people, and/or cargo. A vehicle can be driven and/or otherwise guided along a path (e.g., a paved road or otherwise) on land, in water, in the air, and/or outer space. A vehicle can be wheeled, tracked, railed, and/or skied. A vehicle can include an automobile, a motorcycle (e.g., a two or three wheel motorcycle), an all-terrain vehicle (ATV) defined by ANSI/SVIA-1-2007, a snowmobile, a watercraft (e.g., a JET SKI® watercraft), a light-duty truck, a medium-duty truck, a heavy-duty truck, a semi-tractor, a drone, and/or a farm machine. A vehicle can include and/or use any appropriate voltage and/or current source, such as a battery, an alternator, a fuel cell, and the like, providing any appropriate current and/or voltage, such as about 12 volts, about 42 volts, 400 volts, 800 volts, or some other voltage level. A vehicle can include and/or use any system and/or engine to provide its mobility. Those systems and/or engines can include vehicle components that use fossil fuels, such as gasoline, diesel fuel, natural gas, propane, and the like, electricity, such as that generated by a battery, magneto, fuel cell, solar cell and the like, wind and hybrids and/or combinations thereof. A vehicle can include an electronic control unit (ECU), an OBDC, and a vehicle network that connects the OBDC to the ECU. A vehicle can be operable to operate as an autonomous vehicle.

A vehicle manufacturer can build various quantities of vehicles each calendar year (i.e., January 1^{st} to December 31^{st}). In some instances, a vehicle manufacturer defines a model year for a particular vehicle model to be built. The model year can start on a date other than January 1^{st} and/or can end on a date other than December 31^{st}. The model year can span portions of two calendar years. A vehicle manufacturer can build one vehicle model or multiple different vehicle models. Two or more different vehicle models built by a vehicle manufacturer during a particular calendar year can have the same of different defined model years. The vehicle manufacturer can build vehicles of a particular vehicle model with different vehicle options. For example, the particular vehicle model can include vehicles with six-cylinder engines and vehicles with eight-cylinder engines. The vehicle manufacturer or another entity can define vehicle identifying information for each vehicle built by the vehicle manufacturer. Particular vehicle identifying information identifies particular sets of vehicles (e.g., all vehicles of a particular vehicle model for a particular vehicle model year or all vehicles of a particular vehicle model for a particular vehicle model year with a particular set of one or more vehicle options).

As an example, the particular vehicle identifying information can comprise indicators of characteristics of the vehicle such as when the vehicle was built (e.g., a vehicle model year), who built the vehicle (e.g., a vehicle make (i.e., vehicle manufacturer)), marketing names associated with vehicle (e.g., a vehicle model name, or more simply “model”), and features of the vehicle (e.g., an engine type). In accordance with that example, the particular vehicle identifying information can be referred to by an abbreviation YMMEF, where each letter in the order shown represents a model year identifier, vehicle make identifier, vehicle model name identifier, engine type identifier, and fuel type identifier, respectively, or YMMF, where each letter in the order shown represents a model year identifier, vehicle make identifier, vehicle model name identifier, and fuel type identifier, respectively, or YMME, where each letter in the order shown represents a model year identifier, vehicle make identifier, vehicle model name identifier, and engine type identifier, respectively, or an abbreviation YMM, where each letter in the order shown represents a model year identifier, vehicle make identifier, and vehicle model name identifier, respectively. As yet another example, any of the aforementioned forms of vehicle identifiers can include information regarding a market such that the vehicle identifiers take the form of YMMM, YMMFM, YMMEM, or YMMEFM, where the last “M” represents a market. The market for example, could be the United States market, the United Kingdom market, the German market, the Canadian market, the Brazilian marked, the Australian market, or the market of some other country or region. Other aspects of a vehicle, such as an engine displacement of internal combustion engines, or sub-models designators, can also be represented with the vehicle identifying information.

An example YMME is 2021/Toyota/Camry/4Cyl, in which “2021” represents the model year the vehicle was built, “Toyota” represents the name of the vehicle manufacturer Toyota Motor Corporation, Aichi Japan, “Camry” represents a vehicle model built by that manufacturer, and “4Cyl” represents a an engine type (i.e., a four cylinder internal combustion engine) within the vehicle. Another example YMME is 2016/Freightliner/Cascadia/Cummins ISX15 EPA, in which “2016” represents the model year the vehicle was built, “Freightliner” represents the name of the vehicle manufacturer Daimler Trucks North America, Cleveland, North Carolina, “Cascadia” represents a vehicle model built by that manufacturer, and “Cummins ISX15 EPA” represents an engine manufacturer and model within the vehicle. An example YMM is 2016/Freightliner/Cascadia. An example YM is 2016/Freightliner. A person skilled in the art will understand that other features in addition to or as an alternative to “engine type” can be used to identify a vehicle. These other features can be identified in various manners, such as a regular production option (RPO) code, such as the RPO codes defined by the General Motors Company LLC, Detroit Michigan.

In some cases, different types of vehicles (e.g., vehicles with different YMM, YMMM, YMME, YMMEM, YMMF, YMMFM, YMMEF, or YMMEFM combinations) are part of a vehicle leveraging group. As an example, a vehicle leveraging group may be defined for three different YMM combinations based on different years (e.g., 2022 MM, 2021 MM, and 2020 MM), wherein the make and model name does not change. The leveraging group may be useful because any vehicle within the leveraging group may have a common set of vehicle data messages available to communicate with an off-board computing system. Accordingly, any vehicle within the leveraging group can perform the same functional tests and reset procedures, and be configured to respond to a common set of vehicle data messages.

Some vehicles, such as automobiles, are associated with a unique VIN. Some VINs include seventeen alpha-numeric characters. For at least some seventeen character VINs, the last six characters represent a unique serial number associated with a particular type of vehicle represented by the first eleven alpha-numeric characters of those VINs. The first eleven alpha-numeric characters typically represent at least a YMME or a YMM. In some instances, a vehicle includes a one dimensional or multi-dimensional bar code indicative of a VIN associated with that vehicle.

A vehicle network (e.g., the vehicle network 13 shown in FIG. 2, the vehicle network 85 shown in FIG. 3, or the vehicle network 44 shown in FIG. 4) can include one or more conductors (e.g., copper wire conductors) and/or can be wireless. As an example, a vehicle network can include one or two conductors for carrying vehicle data messages in accordance with a vehicle data message (VDM) protocol, such as a bi-directional VDM protocol. A bi-directional VDM protocol can include a SAE® J1850 (PWM or VPW) VDM protocol, an SAER J1939 VDM protocol based on the SAE® J1939_201808 serial control and communications heavy duty vehicle network-top level document, and/or any other core J1939 standard, an ISO® 15764-4 controller area network (CAN) VDM protocol, an ISO® 9141-2 K-Line VDM protocol, an ISO® 14230-4 KWP2000 K-Line VDM protocol, an ISO® 17458 (e.g., parts 1-5) FlexRay VDM protocol, an ISO® 17987 local interconnect network (LIN) VDM protocol, a CAN 2.0 VDM protocol, standardized in part using an ISO® 11898-1:2015 road vehicle-CAN-Part I: data link layer and physical signaling protocol, a CAN FD VDM protocol (e.g., CAN with flexible data rate VDM protocol), a MOST® Cooperation VDM protocol (such as the MOST Specification Rev. 3.0 E2, or the MOST® Dynamic Specification, Rev. 3.0.2), an Ethernet VDM protocol (e.g., an Ethernet 802.3 protocol using a BROADR-REACH® physical layer transceiver specification for Automotive Applications by Broadcom Inc., San Jose, California), or some other VDM protocol defined for performing communications with or within the vehicle 4, 32, 71. The aforementioned protocols can include definition for at least physical and data link layers of the seven layer Open Systems Interconnection (OSI) model. Each and every VDM discussed in this description is arranged according to a VDM protocol.

In at least some embodiments, a VDM protocol works in conjunction a Unified Diagnostic Services (UDS) protocol, such as the ISO® 14229-1:2020 standard for Road vehicles-UDS-Part 1: application layer, the ISO® 14229-2 standard for Road vehicles-unified diagnostic services, session layer services, or ISO® 14229-3:2022 standard for Road Vehicles-UDS on CAN embodiment (UDSonCAN). A VDM sent on a CAN vehicle bus according the UDS protocol can include a CAN message identifier, a protocol control information filed, a service identifier (SID), and data parameter value requests. Table B shows example SIDs sent to a ECU from a VST and example SIDs sent in response to the VST from the ECU.

TABLE B

| Request SID | Service | Response SID |
|---|---|---|
| $10 | Diagnostic session control | $50 |
| $11 | ECU reset | $51 |
| $14 | Clear DTC | $54 |
| $19 | Read DTC | $59 |
| $22 | Read data by identifier | $62 |
| $23 | Read memory by address | $63 |
| $24 | Read scaling data by identifier | $64 |
| $27 | Security access | $67 |
| $28 | Communication control | $68 |
| $29 | Authentication | $69 |
| $2A | Read data by identifier periodically | $6A |
| $2C | Dynamically define data identifier | $6C |
| $2E | Write data by identifier | $6E |
| $2F | Input Output Control by identifier | $6F |
| $31 | Routine control | $71 |
| $34 | Request download | $74 |
| $35 | Request upload | $75 |
| $36 | Transfer data | $76 |
| $37 | Request transfer exit | $77 |
| $38 | Request file transfer | $78 |
| $3D | Write memory by address | $7D |
| $3E | Tester present | $7E |
| $83 | Access timing parameters | $C3 |
| $84 | Secured data transmission | $C4 |
| $85 | Control DTC settings | $C5 |
| $86 | Response on event | $C6 |
| $87 | Link control | $C7 |

As an example, the processor 116 can transmit a VDM with a SID $2A to request an ECU to transmit VDMs with PID parameter data periodically. Moreover, the processor 116 can include a data rate, such as slow, medium, or fast to set a transmission rate for the ECU, or a data rate of stop to end the periodic transmission of PID parameter data from the ECU for the requested PID.

As another example, the processor 116 can transmit a VDM with a SID $2F to request the ECU to perform a functional test or a reset procedure. In other words, the VST 3 and/or the processor 116 can gain control over an analog or digital input or output of the ECU by sending a VDM with the SID $2F.

As yet another example, the processor 116 can transmit a VDM with a SID $22 to request a PID parameter value from an ECU, a SID $14 to clear DTCs, or a SID $19 to read DTCs.

In at least some embodiments, a VDM protocol can be unidirectional instead of bidirectional. For example, a SENT VDM protocol (e.g., a single-edge nibble transmission VDM protocol) is a unidirectional VDM protocol. The SENT VDM protocol has been standardized as the SAE J2716 VDM protocol. A sensor in a vehicle can include a transmitter operable to communicate using the SENT VDM protocol (e.g., a SENT VDM transmitter). A vehicle communication bus can operatively connect the SENT VDM transmitter and an ECU within the vehicle. The transceiver 118 (e.g., the vehicle communications transceiver 127) can include a SENT VDM receiver connectable to the vehicle communication bus operatively connected to the SENT VDM transmitter. The SENT VDM receiver can receive SENT VDM protocol messages representing sensor values output by the sensor with the SENT VDM transmitter.

An OBDC, such as the OBDC 11, 37, 84 can include an on-board diagnostic (OBD) connector, such as an OBD II connector. An OBD II connector can include slots for retaining up to sixteen connector terminals, but can include a different number of slots or no slots at all. As an example, an OBDC can include an OBD II connector that meets the SAE J1962 specification such as a connector 16M, part number 12110252, available from Aptiv LLC of Dublin, Ireland. An OBDC can include conductor terminals that connect to a conductor in a vehicle. For instance, an OBDC can include connector terminals that connect to conductors that respectively connect to positive and negative terminals of a battery or battery pack. An OBDC can include one or more conductor terminals that connect to a conductor of a vehicle communication bus such that the OBDC is operatively connected to one or more ECUs. A computing system, such as the VST 3 can operatively connect to an OBDC in order to receive a VDM from the vehicle including that OBDC. A VDM can carry VDM data. The VDM data can include a PID and parameter values associated with the PID. The VDM data can include a DTC. An operative connection between the OBDC and the VST 3 can occur via the arrangement 8, 9, 10 shown in FIG. 2 or via some other arrangement. A PID can be associated with one or more thresholds. A threshold corresponding to a PID can be dependent upon an operating condition of the vehicle 4, 32, 71. A VDM can be transmitted over a physical communication link, such as a copper wire or an optical cable, or using radio signals over an air interface. In many embodiments, the PID and parameter value are transmitted as binary data. A processor can parse a received VDM to recover a binary representation of a PID and parameter value. The processor can translate the binary representation of a PID and parameter value into a textual a PID and parameter value displayable on a display device.

In at least some vehicles, the OBDC includes an OBDC required in vehicles with internal combustion engines in certain countries. Some purely electric vehicles include the same type of OBDC required in vehicles with internal combustion engines. Some other purely electric vehicles includes an OBDC different than the type of OBDC required in vehicles with internal combustion engines. Some vehicles include the type of OBDC required in vehicles with internal combustion engines and one or more other OBDCs.

An ECU can control various aspects of vehicle operation and/or components within a vehicle system. For example, an ECU can include a powertrain (PT) system ECU, an engine control module (ECM) ECU, a supplemental inflatable restraint (SIR) system (e.g., an air bag system) ECU, an entertainment system ECU, a battery management system ECU, or some other ECU. An ECU can receive an electrical or optical input from an ECU-connected input device (e.g., a sensor input), control an ECU-connected output device (e.g., a solenoid) via an electrical or optical signal output by the ECU, generate a vehicle data message (VDM) (such as a VDM based on a received input or a controlled output), and set a DTC to a state (such as active or history). An ECU can perform a functional test in response to receiving a VDM requesting performance of the functional test. The functional test can be used to test an ECU-connected output device. In at least some embodiments, the ECU is operable to perform the functional test and/or provide the DTC in accordance with an industry standard, such as the SAE J1979_201202 and/or ISO 15031-5 standards for E/E diagnostic test modes.

### VI. Example Computing System Configuration

Next, FIG. 39 shows a vehicle message flow 400 in accordance with the example embodiments. The vehicle message flow 400 can occur over a vehicle network, such as the vehicle network 13, 44, 85. The vehicle message flow 400 includes a group of vehicle messages 401, 402, 403. Each group of vehicle messages 401, 402, 403 includes request messages and response messages. The request messages in an example vehicle message flow can be transmitted via execution of the transmit vehicle message module 306, and can include a PID. The response messages in an example vehicle message flow can be received via execution of the receive vehicle message module 307, and can include a PID and PID parameter value. In some vehicles, the PID in a response message is a sum of (i) a hexadecimal PID contained in a corresponding request vehicle message plus hexadecimal 40.

The group of vehicle messages 401 are transmitted on the vehicle network during a time period starting at time 1 and ending at time 2. The group of vehicle messages 402 are transmitted on the vehicle network during a time period starting at time 3 and ending at time 4. The group of vehicle messages 403 are transmitted on the vehicle network during a time period starting at time 5 and ending at time 6.

The group of vehicle messages 401 includes a vehicle message 406 to request a state-of-charge of a battery pack, a sub-group of vehicle messages 404, and a vehicle message 407 having a response to a request for the battery voltage value of a battery pack component (BPC) 14. The sub-group of vehicle messages 404 includes request and responses for battery pack current, battery temperatures, battery pack component (BPC) voltages, and a sub-group of vehicle messages 405. The sub-group of vehicle messages 405 includes request and response vehicle messages regarding battery pack minimum and maximum voltage values. The group of vehicle messages 401 includes a vehicle message 398 to request a battery pack current value and a vehicle message 399 comprising a response with the battery pack current. The vehicle messages including a request within the group of vehicle messages 401 can occur in an order different than shown in FIG. 39. The vehicle messages including a response would continue to follow a vehicle message having a corresponding request. As an example, the minimum and maximum voltage values for the sub-group of vehicle messages 405 can correspond to battery pack modules, battery blocks, strings, or cells within the battery pack.

The group of vehicle messages 402, 403 includes the vehicle message 406, an indication of other vehicle messages 408, and the vehicle message 407. The indication of other vehicle messages 408 represents the sub-group of vehicle messages 404. The group of vehicle messages 402, 403 repeat the group of vehicle messages. In that regard, the request vehicle message in those groups of vehicle messages can be identical, although the response vehicle messages amongst the groups of vehicle messages can vary based on the parameter values corresponding to like PID. The PID parameter values within each group of vehicle messages 401, 402, 403 can relate to each other temporally (e.g., occurring to the time intervals time 1 to time 2, time 3 to time 4, or time 5 to time 6) and/or to a common data point.

Next, FIG. 40 shows a vehicle message flow 410 in accordance with the example embodiments. The vehicle message flow 410 can occur over a vehicle network, such as the vehicle network 13, 44, 85. The vehicle message flow 410 includes a group of vehicle messages 411, 412, 413. Each group of vehicle messages 411, 412, 413 includes request messages and response messages.

The group of vehicle messages 411 are transmitted on the vehicle network during a time period starting at time 10 and ending at time 11. The group of vehicle messages 412 are transmitted on the vehicle network during a time period starting at time 12 and ending at time 13. The group of vehicle messages 413 are transmitted on the vehicle network during a time period starting at time 14 and ending at time 15.

The group of vehicle messages 411 includes the vehicle message 406 to request a state-of-charge of a battery pack, a sub-group of vehicle messages 414, and the vehicle message 407 having a response to a request for the battery voltage value of a battery pack component (BPC) 14. The sub-group of vehicle messages 414 includes request and responses for battery pack current, battery temperatures, battery pack component (BPC) voltages. The sub-group of vehicle messages 414 is identical to the sub-group of vehicle messages 404 shown in FIG. 39 except that the sub-group of vehicle messages does not include the sub-group of vehicle messages 405. The group of vehicle messages 411 includes the vehicle message 398, 399.

The group of vehicle messages 412, 413 includes the vehicle message 406, an indication of other vehicle messages 415, and the vehicle message 407. The indication of other vehicle messages 415 represents the sub-group of vehicle messages 414. The group of vehicle messages 412, 413 repeat the group of vehicle messages. In that regard, the request vehicle message in those groups of vehicle messages can be identical, although the response vehicle messages amongst the groups of vehicle messages can vary based on the parameter values corresponding to like PID. The PID parameter values within each group of vehicle messages 411, 412, 413 can relate to each other temporally (e.g., occurring to the time intervals time 10 to time 11, time 12 to time 13, or time 14 to time 15) and/or to a common data point.

A person having ordinary skill in the art will understand that other vehicle messages, such as non-diagnostic vehicle messages transmitted by one ECU in the vehicle directed to one or more other ECUs in the vehicle can be transmitted during time periods 1 to 2, 3 to 4, and/or 5 to 6 within the vehicle message flow 400, or during time periods 10 to 11, 12 to 13, and/or 14 to 15 within the vehicle message flow 410. As an example, a group of vehicle messages comprising parameter values indicative of battery module voltages, can include some vehicle messages that repeat within the group of vehicle messages, such as the vehicle message 398, 399. In accordance with that example, the computing system receiving the vehicle message 399 multiple times within a group of vehicle messages indicating BPC voltages can determine the battery pack current multiple times to ensure the vehicle remained in the electric vehicle mode or the regenerative braking mode while receiving the group of vehicle messages indicating BPC voltages.

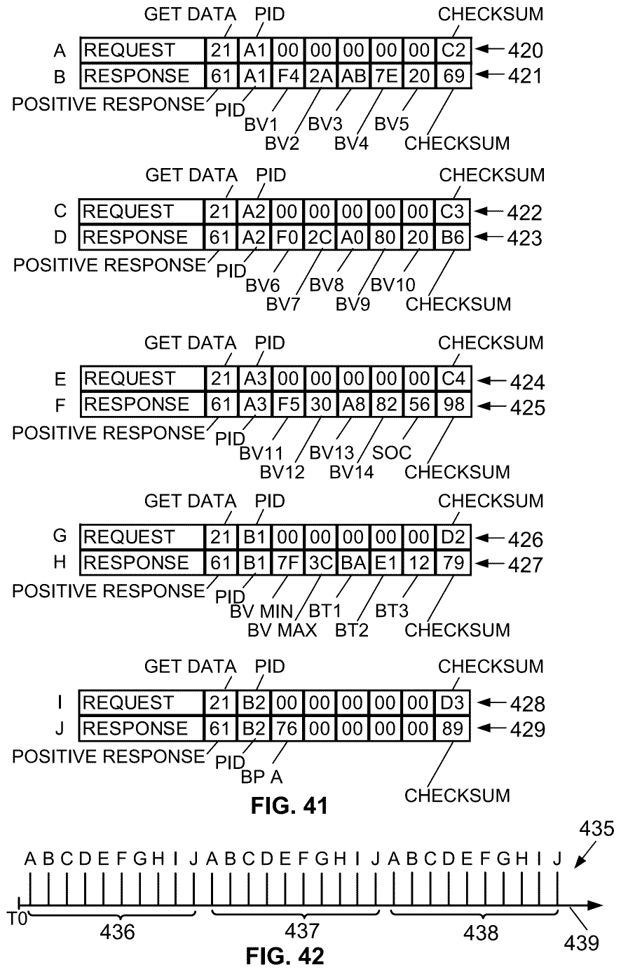

Next, FIG. 41 shows a vehicle message flow including a vehicle message 420, 421, 422, 423, 424, 425, 426, 427, 428, 429 in accordance with the example embodiments. Each of those messages includes a checksum. The vehicle message 420, 422, 424, 426, 428 is a vehicle message with a PID A1, A2, A3, B1, B2, respectively, to request PID parameter values. The vehicle message 420, 422, 424, 426, 428 includes a get data byte “21” indicating the message is a request message. The vehicle message 421, 423, 425, 427, 429 is a vehicle response message to the vehicle message 420, 422, 424, 426, 428, respectively. The vehicle message 420, 422, 424, 426, 428 includes a get data byte “61” indicating the message is a response message as well as the PID A1, A2, A3, B1, B2, respectively. FIG. 41 shows a reference A, B, C, D, E, F, G, H, I, J for the vehicle message 420, 421, 422, 423, 424, 425, 426, 427, 428, 429, respectively. Those references are also shown in FIG. 42.

The vehicle message 421 includes five data bytes that represent: a battery voltage for battery pack component 1 (i.e., BV1), a battery voltage for battery pack component 2 (i.e., BV2), a battery voltage for battery pack component 3 (i.e., BV3), a battery voltage for battery pack component 4 (i.e., BV4), and a battery voltage for battery pack component 5 (i.e., BV5). These data bytes in different instances of the vehicle message 421 are variable based on what the vehicle senses.

The vehicle message 423 includes five data bytes that represent: a battery voltage for battery pack component 6 (i.e., BV6), a battery voltage for battery pack component 7 (i.e., BV7), a battery voltage for battery pack component 8 (i.e., BV8), a battery voltage for battery pack component 9 (i.e., BV9), and a battery voltage for battery pack component 10 (i.e., BV10). These data bytes in different instances of the vehicle message 423 are variable based on what the vehicle senses.

The vehicle message 425 includes five data bytes that represent: a battery voltage for battery pack component 11 (i.e., BV11), a battery voltage for battery pack component 12 (i.e., BV12), a battery voltage for battery pack component 13 (i.e., BV13), a battery voltage for battery pack component 14 (i.e., BV14), and a battery state-of-charge value (i.e., SOC). These data bytes in different instances of the vehicle message 425 are variable based on what the vehicle senses.

The vehicle message 427 includes five data bytes that represent: a battery voltage minimum value (BV MIN), a battery voltage maximum value (BV MAX), a first battery temperature (BT1), a second battery temperature (BT2), and a third battery temperature (BT3). These data bytes in different instances of the vehicle message 427 are variable based on what the vehicle senses.

The vehicle message 429 includes five data bytes that represent: a battery pack current (BV A), and four spare data bytes. The first data byte in different instances of the vehicle message 429 is variable based on what the vehicle senses.

Next, FIG. 42 shows a vehicle message flow 435 including repeating sequences of vehicle messages A, B, C, D, E, F, G, H, I, J, that occur after a time TO as shown on a time line 439. Those sequences are represented as data point 436, 437, 438. Due to the nature of transmitting vehicle messages serially, a latency period exists in between sending each vehicle message in a given sequence. Accordingly, each sequence of vehicle messages for a data point include battery voltage values for fourteen battery pack components, a battery voltage maximum value, and a battery voltage maximum value, and in some circumstances due to the latency period, a battery voltage value of one or more of the modules may be less than the battery voltage maximum value or more than the battery voltage maximum value for a given data point. The determine min/max battery voltage value module 309 can be configured to use the battery voltage maximum value and the battery voltage maximum value to determine the minimum and maximum voltage values of battery pack components within a battery pack for a given data point. Alternatively, the determine min/max battery voltage value module 309 can be configured to compare BV1, BV2, BV3, BV4, BV5, BV6, BV7, BV8, BV9, BV10, BV11, BV12, BV13, BV14 with each other to determine which of those values is the least or greatest in order to determine the minimum and maximum voltage values of battery pack components within a battery pack for a given data point.

### VII. Example Computing System Configuration

Next, FIG. 43 is a block diagram of a computing system 670 in accordance with the example embodiments. In a basic configuration 671, the computing system 670 can include a processor 672 and a system memory 674. A memory bus 679 can be used for communicating between the processor 672 and the system memory 674. Depending on the desired configuration, the processor 672 can be of any type including but not limited to a microprocessor (μP), a microcontroller (μC), a digital signal processor (DSP), or any combination thereof. A memory controller 673 can also be used with the processor 672, or in some embodiments, the memory controller 673 can be an internal part of the processor 672.

Depending on the desired configuration, the system memory 674 can be of any type including but not limited to volatile memory (such as RAM), non-volatile memory (such as ROM, flash memory, etc.) or any combination thereof. The system memory 674 can include one or more applications 675, program data 677, and parameter values 694. The system memory 674 can include data contained within the memory 57, 117. The application 675 can include an algorithm 676 that is arranged to perform the functions described as being performed by the VST 3 or the server 6. The program data 677 can include system data 678 that could be directed to any number of types of data, such as the computer-readable data stored in the memory 57, 117. In some example embodiments, the applications 675 can be arranged to operate with the program data 677 on an operating system executable by the processor 672.

The computing system 670 can have additional features or functionality, and additional interfaces to facilitate communications between the basic configuration 671 and any devices and interfaces. For example, storage devices 680 can be provided including removable storage devices 681, non-removable storage devices 682, or a combination thereof. Examples of removable storage and non-removable storage devices include magnetic disk devices such as flexible disk drives and hard-disk drives (HDD), optical disk drives such as compact disc (CD) drives or digital versatile disk (DVD) drives, solid state drives (SSD), and tape drives to name a few. Computer storage media can include volatile and nonvolatile, non-transitory, removable and non-removable media implemented in any method or technology for storage of information, such as computer-readable program instructions, data structures, program modules, or other data such as the data stored in a computer-readable memory, such at the memory 57, 117.

The system memory 674 and the storage devices 680 are examples of computer-readable memory, such as the memory 57, 117. The system memory 674 and the storage devices 680 can include, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by the computing system 670.

The computing system 670 can include or be implemented as a portion of a small-form factor portable (e.g., mobile) electronic device such as a smartphone (e.g., an IPHONE® smartphone from Apple Inc. of Cupertino, California, or a GALAXY S® smartphone from Samsung Electronics Co., Ltd. of Maetan-Dong, Yeongtong-Gu Suwon-Si, Gyeonggi-Do, Republic of Korea), a tablet device (e.g., an IPAD® tablet device from Apple Inc., or a SAMSUNG GALAXY TAB tablet device from Samsung Electronics Co., Ltd.), or a wearable computing device (e.g., a wireless web-watch device or a personal headset device). The application 675, or the program data 677 can include an application downloaded to the communication interfaces 687 from the APP STORE® online retail store, from the GOOGLE PLAY® online retail store, or another source of the applications. A component of the VST 3, such as the display 128 and/or the transceiver 118, can be embodied in the small-form factor electronic device.

The computing system 670 can include or be implemented as part of a personal computing system (including both laptop computer and non-laptop computer configurations), or a server. The computing system 670 can be configured as an embedded system in which the processor 672 includes an embedded processor and the system memory 674 includes an embedded memory.

The computing system 670 includes output interface 683 comprising a graphics processing unit 684, which can be configured to communicate to various external devices such as a display device 686 or a speaker via an A/V port 685 or a communication interface 687. The communication interface 687 can include a network controller 688, which can be arranged to facilitate communications with the computing system 690 over a network communication via a communication port 689. The communication connection is one example of a communication media. Communication media can be embodied by computer-readable program instructions, data structures, program modules, GUIs, or other data in a modulated data signal, such as a carrier wave or other transport mechanism, and includes any information delivery media. A modulated data signal can be a signal that has one or more of its characteristics set or changed in such a manner as to encode information in the signal. By way of example, and not limitation, communication media can include wired media such as a wired network or direct-wired connection, and wireless media such as acoustic, radio frequency (RF), infrared (IR) and other wireless media.

Additionally or alternatively, the communication interface 687 can include a transceiver 667 operatively coupled to the network controller 688. The example transceivers discussed elsewhere in this description are applicable to the transceiver 667. The transceiver 667 is configured to communicate with computing system 668. As an example, the computing system 668 can include a meter, such as an electrical measurement meter configured to communicate with the transceiver 667 via a wireless communication protocol. For instance, the computing system 668 can include a digital clamp meter configured to communicate measurement values to a remote device via wireless communication, such as DCM 1500S digital clamp meter available from Megger Group Limited of Dover, England, United Kingdom. The transceiver 118 of the VST 3 can communicate with the computing system 668.

The computing system 670 includes input interfaces 691 comprising an input port 692. The input port 692 can connect to the input device 693. As an example, the input port 692 can include a Universal Serial Bus (USB) port, an Ethernet port (e.g., an RJ-45 port), a serial port (e.g., an RS-232 port), or a parallel port (e.g., an RS-232 port). As another example, the input device 693 can include a wiring harness connectable to an OBDC.

The display device 686 can include one or more display devices. The input device 693 can include one or more input devices. Each of the computing system 668, 690 can include one or more other computing systems. The A/V port 685 can include one or more A/V ports. The input port 692 can include one or more input ports. The communication port 689 can include one or more communication ports.

The computing system 670 includes a power supply 669. The power supply 669 is configured to provide electrical power to other components of the computing system 670 that operate electrically. The power supply examples described elsewhere in this description are applicable to the power supply 669.

In FIG. 44, a schematic illustrating a conceptual partial view of a computer program product 700 is shown. The computer program product 700 includes a computer program for executing a computer process on a computing system, arranged according to at least some embodiments presented herein. That computer program can be encoded on a non-transitory computer-readable storage medium in a machine-readable format, or on another non-transitory medium or article of manufacture.

In at least some embodiments, the computer program product 700 is provided using a signal bearing medium 695. The signal bearing medium 695 can include one or more programming instructions 696 that, when executed by a processor can provide functionality or portions of the functionality described above with respect to FIG. 1 to FIG. 43. In some examples, the signal bearing medium 695 can encompass a computer-readable memory 697, such as, but not limited to, a hard disk drive, a Compact Disc (CD), a Digital Video Disk (DVD), a digital tape, or any other memory described herein. In some embodiments, the signal bearing medium 695 can encompass a computer recordable medium 698, such as, but not limited to, memory, read/write (R/W) CDs, R/W DVDs, etc. In some embodiments, the signal bearing medium 695 can encompass a communications medium 699, such as, but not limited to, a digital and/or an analog communication medium (e.g., a fiber optic cable, a waveguide, a wired communications link, a wireless communication link, etc.). Thus, for example, the signal bearing medium 695 can be conveyed by a wireless form of the communications medium 699 (e.g., a wireless communications medium conforming to the IEEE 802.11 standard or another transmission protocol).

The one or more programming instructions 696 can be, for example, computer executable and/or logic implemented instructions. In some examples, a computing system such as the computer program product 700 of FIG. 44 can be configured to provide various operations, functions, or actions in response to the programming instructions 696 conveyed to the computing system 670 by one or more of the following: the computer-readable memory 697, the computer recordable medium 698, or the communications medium 699.

The VST 3 can include any or all of the components of the computing system 670. Additionally or alternatively, the processor 116 can be configured like the processor 672. The memory 117 can be configured as part of or all of the system memory 674 and/or the storage devices 680. The transceiver 118 can be configured as part of or all of the communication interface 687.

In at least some embodiments, the VST 3, the server 6 and/or the computing system 670 includes a power source. The power source can include a connection to an external power source and circuitry to allow current to flow to other elements connected to the power source. As an example, the external power source can include a wall outlet at which a connection to an alternating current can be made. As another example, the external power source can include an energy storage device (e.g., a battery) or an electric generator.

Additionally or alternatively, a power source can include a connection to an internal power source and power transfer circuitry to allow current to flow to other elements connected to the power source. As an example, the internal power source can include an energy storage device, such as a battery. Furthermore, any power source (e.g., a power supply) described herein can include various circuit protectors and signal conditioners. The power sources described herein can provide a way to transfer electrical currents to other elements that operate electrically.

### VIII. Example Test Data

In this section, example test data captured during test drives of two different vehicles is shown in Tables C1, C2, C3, D1, D2, D3, E1, E2, F1, F2. The test data in Tables C1, C2, C3, D1, D2, D3 was captured during a test drive of a 2015 TOYOTA® Auris, a hybrid vehicle. The test data in Tables E1, E2, F1, F2 was captured during a test drive of a 2016 TOYOTA® PRIUS®, another hybrid vehicle. The parameter values 147 shown in FIG. 5 and/or the parameter values 70 shown in FIG. 7 can include the data shown in one or more of Tables C1, C2, C3, D1, D2, D3, E1, E2, F1, F2.

Tables C1, C2, C3 show example data captured while testing a battery system of a 2015 TOYOTA® Auris in accordance with the example embodiments. The data in Tables C1, C2, C3 was captured while the vehicle was driven in a regenerative braking mode. The data in Table C2 and Table C3 corresponds to the data in Table C1 (i.e., the data points 1 to 56 in Tables C₁ to C₃ are the same data points).

The first row of Table C1 and Table D1 include the following abbreviations: SOC (i.e., state of charge), BP (i.e., Battery Pack), TB (i.e., Temperature of Battery), BPM (i.e., Battery Pack Module), A (i.e., Amperes),° C. (i.e., degrees Celsius), and VDC (i.e., volts direct current).

TABLE C1

| Data | SOC | BP Current | TB1 | TB2 | TB3 | BPM Min | BPM Max |
|---|---|---|---|---|---|---|---|
| point | (%) | (A) | (° C.) | (° C.) | (° C.) | (VDC) | (VDC) |
| 1 | 50.6 | −47.65 | 4.6 | 5.1 | 4.7 | 16.32 | 16.46 |
| 2 | 50.6 | −75.79 | 4.6 | 5.1 | 4.7 | 17.2 | 17.32 |
| 3 | 50.6 | −75.79 | 4.6 | 5.1 | 4.7 | 17.2 | 17.32 |
| 4 | 50.6 | −75.79 | 4.6 | 5.1 | 4.7 | 17.2 | 17.32 |
| 5 | 51 | −77.08 | 4.6 | 5.1 | 4.7 | 17.5 | 17.68 |
| 6 | 51 | −77.08 | 4.6 | 5.1 | 4.7 | 17.5 | 17.68 |
| 7 | 51 | −77.08 | 4.6 | 5.1 | 4.7 | 17.5 | 17.68 |
| 8 | 51 | −80.88 | 4.6 | 5.1 | 4.7 | 17.42 | 17.71 |
| 9 | 51 | −80.88 | 4.6 | 5.1 | 4.7 | 17.42 | 17.71 |
| 10 | 51.4 | −80.88 | 4.6 | 5.1 | 4.7 | 17.68 | 17.88 |
| 11 | 51.4 | −77.03 | 4.6 | 5.1 | 4.7 | 17.68 | 17.88 |
| 12 | 51.4 | −77.03 | 4.6 | 5.1 | 4.7 | 17.68 | 17.88 |
| 13 | 51.4 | −75.94 | 4.6 | 5.1 | 4.7 | 17.81 | 17.93 |
| 14 | 51.4 | −75.94 | 4.6 | 5.1 | 4.7 | 17.81 | 17.93 |
| 15 | 51.4 | −75.94 | 4.6 | 5.1 | 4.7 | 17.81 | 17.93 |
| 16 | 51.4 | −78.69 | 4.6 | 5.1 | 4.7 | 17.78 | 17.95 |
| 17 | 51.8 | −78.96 | 4.6 | 5.1 | 4.7 | 17.78 | 17.95 |
| 18 | 51.8 | −78.69 | 4.6 | 5.1 | 4.7 | 17.78 | 17.95 |
| 19 | 51.8 | −67.4 | 4.6 | 5.2 | 4.7 | 17.73 | 17.9 |
| 20 | 51.8 | −67.4 | 4.6 | 5.2 | 4.7 | 17.73 | 17.9 |
| 21 | 51.8 | −67.4 | 4.6 | 5.2 | 4.7 | 17.73 | 17.9 |
| 22 | 51.8 | −61.6 | 4.6 | 5.2 | 4.7 | 17.68 | 17.83 |
| 23 | 51.8 | −61.6 | 4.6 | 5.2 | 4.7 | 17.68 | 17.83 |
| 24 | 51.8 | −61.6 | 4.6 | 5.2 | 4.7 | 17.56 | 17.78 |
| 25 | 52.2 | −53.91 | 4.6 | 5.1 | 4.7 | 17.56 | 17.78 |
| 26 | 52.2 | −53.91 | 4.6 | 5.1 | 4.7 | 17.56 | 17.78 |
| 27 | 52.2 | −53.41 | 4.6 | 5.1 | 4.7 | 17.54 | 17.64 |
| 28 | 52.2 | −53.41 | 4.6 | 5.2 | 4.7 | 17.54 | 17.64 |
| 29 | 52.2 | −53.41 | 4.6 | 5.2 | 4.7 | 17.54 | 17.64 |
| 30 | 52.2 | −45.86 | 4.6 | 5.2 | 4.7 | 17.44 | 17.59 |
| 31 | 52.2 | −45.86 | 4.6 | 5.2 | 4.7 | 17.44 | 17.59 |
| 32 | 52.2 | −45.86 | 4.6 | 5.2 | 4.7 | 17.44 | 17.59 |
| 33 | 52.5 | −43.72 | 4.6 | 5.2 | 4.7 | 17.39 | 17.51 |
| 34 | 52.5 | −43.72 | 4.6 | 5.2 | 4.7 | 17.39 | 17.51 |
| 35 | 52.5 | −43.72 | 4.6 | 5.2 | 4.7 | 17.39 | 17.51 |
| 36 | 52.5 | −36.48 | 4.6 | 5.2 | 4.7 | 17.37 | 17.47 |
| 37 | 52.5 | −36.48 | 4.6 | 5.2 | 4.7 | 17.37 | 17.47 |
| 38 | 52.5 | −36.48 | 4.6 | 5.2 | 4.7 | 17.37 | 17.47 |
| 39 | 52.5 | −32.8 | 4.6 | 5.2 | 4.7 | 17.22 | 17.37 |
| 40 | 52.5 | −32.8 | 4.6 | 5.2 | 4.7 | 17.22 | 17.37 |
| 41 | 52.5 | −28.9 | 4.6 | 5.2 | 4.7 | 17.2 | 17.32 |
| 42 | 52.5 | −28.9 | 4.6 | 5.2 | 4.7 | 17.2 | 17.32 |
| 43 | 52.5 | −28.9 | 4.6 | 5.2 | 4.7 | 17.2 | 17.32 |
| 44 | 52.5 | −26.86 | 4.6 | 5.2 | 4.7 | 17.17 | 17.32 |
| 45 | 52.9 | −26.86 | 4.6 | 5.2 | 4.7 | 17.17 | 17.32 |
| 46 | 52.9 | −26.86 | 4.6 | 5.2 | 4.7 | 17.17 | 17.32 |
| 47 | 52.9 | −25.99 | 4.6 | 5.2 | 4.7 | 17.12 | 17.2 |
| 48 | 52.9 | −25.99 | 4.6 | 5.2 | 4.7 | 17.12 | 17.2 |
| 49 | 52.9 | −25.99 | 4.6 | 5.2 | 4.7 | 17.12 | 17.2 |
| 50 | 52.9 | −21.14 | 4.6 | 5.2 | 4.7 | 17.03 | 17.17 |
| 51 | 52.9 | −21.14 | 4.6 | 5.2 | 4.7 | 17.03 | 17.17 |
| 52 | 52.9 | −21.14 | 4.7 | 5.2 | 4.7 | 17.03 | 17.17 |
| 53 | 52.9 | −20.13 | 4.7 | 5.2 | 4.7 | 17.02 | 17.07 |
| 54 | 52.9 | −20.13 | 4.7 | 5.2 | 4.7 | 17.02 | 17.07 |
| 55 | 52.9 | −6.14 | 4.7 | 5.2 | 4.7 | 16.93 | 17.03 |
| 56 | 52.9 | −6.14 | 4.7 | 5.2 | 4.7 | 16.93 | 17.03 |

Table C2 is shown next. The first row of Table C2, C3, D2, D3 include the following abbreviations: BPM (i.e., Battery Pack Module) and V (i.e., volts). The voltages in Table C2, C3, D2, D3 are DC voltages. The letters VO followed by a number in the first row of Table C2, C3, D2, D3 are BPM numbers (e.g., VO1 is for BPM 1). As an example, each battery pack module can include five battery cells with nominal voltage of 3.5 volts. As another example, each battery pack module can include twelve battery cells with nominal voltage of 1.2 volts. Other examples are possible. The battery pack module for which this data is based can be referred to as a “battery block,” or by some other term(s).

TABLE C2

| Data | BPM | BPM | BPM | BPM | BPM | BPM | BPM |
|---|---|---|---|---|---|---|---|
| point | VO1 (V) | VO2 (V) | VO3 (V) | VO4 (V) | VO5 (V) | VO6 (V) | VO7 (V) |
| 1 | 16.19 | 16.24 | 16.22 | 16.22 | 16.37 | 16.34 | 16.49 |
| 2 | 17.39 | 17.37 | 17.39 | 17.37 | 17.34 | 17.32 | 17.29 |
| 3 | 17.39 | 17.37 | 17.39 | 17.37 | 17.34 | 17.32 | 17.29 |
| 4 | 17.59 | 17.56 | 17.64 | 17.66 | 17.64 | 17.61 | 17.64 |
| 5 | 17.59 | 17.56 | 17.64 | 17.66 | 17.64 | 17.61 | 17.64 |
| 6 | 17.59 | 17.56 | 17.64 | 17.66 | 17.64 | 17.61 | 17.64 |
| 7 | 17.64 | 17.61 | 17.81 | 17.81 | 17.71 | 17.71 | 17.61 |
| 8 | 17.64 | 17.61 | 17.81 | 17.81 | 17.71 | 17.71 | 17.61 |
| 9 | 17.64 | 17.61 | 17.81 | 17.81 | 17.71 | 17.71 | 17.61 |
| 10 | 17.78 | 17.76 | 17.86 | 17.88 | 17.88 | 17.86 | 17.78 |
| 11 | 17.78 | 17.76 | 17.86 | 17.88 | 17.88 | 17.86 | 17.78 |
| 12 | 17.78 | 17.76 | 17.86 | 17.88 | 17.88 | 17.86 | 17.78 |
| 13 | 17.83 | 17.83 | 17.93 | 17.93 | 17.83 | 17.83 | 17.93 |
| 14 | 17.83 | 17.83 | 17.93 | 17.93 | 17.83 | 17.83 | 17.93 |
| 15 | 17.83 | 17.83 | 17.93 | 17.93 | 17.83 | 17.83 | 17.93 |
| 16 | 18.08 | 18.05 | 17.93 | 17.95 | 17.83 | 17.81 | 17.93 |
| 17 | 18.08 | 18.05 | 17.93 | 17.95 | 17.83 | 17.81 | 17.93 |
| 18 | 17.81 | 17.78 | 17.88 | 17.9 | 17.73 | 17.73 | 17.73 |
| 19 | 17.81 | 17.78 | 17.88 | 17.9 | 17.73 | 17.73 | 17.73 |
| 20 | 17.81 | 17.78 | 17.88 | 17.9 | 17.73 | 17.73 | 17.73 |
| 21 | 17.78 | 17.76 | 17.73 | 17.73 | 17.71 | 17.68 | 17.64 |
| 22 | 17.78 | 17.76 | 17.73 | 17.73 | 17.71 | 17.68 | 17.64 |
| 23 | 17.78 | 17.76 | 17.73 | 17.73 | 17.71 | 17.68 | 17.64 |
| 24 | 17.68 | 17.66 | 17.68 | 17.71 | 17.68 | 17.66 | 17.54 |
| 25 | 17.68 | 17.66 | 17.68 | 17.71 | 17.68 | 17.66 | 17.54 |
| 26 | 17.68 | 17.66 | 17.68 | 17.71 | 17.68 | 17.66 | 17.54 |
| 27 | 17.54 | 17.51 | 17.59 | 17.59 | 17.56 | 17.56 | 17.59 |
| 28 | 17.54 | 17.51 | 17.59 | 17.59 | 17.56 | 17.56 | 17.59 |
| 29 | 17.54 | 17.51 | 17.59 | 17.59 | 17.56 | 17.56 | 17.59 |
| 30 | 17.54 | 17.54 | 17.51 | 17.51 | 17.49 | 17.49 | 17.44 |
| 31 | 17.54 | 17.54 | 17.51 | 17.51 | 17.49 | 17.49 | 17.44 |
| 32 | 17.49 | 17.47 | 17.39 | 17.42 | 17.39 | 17.37 | 17.39 |
| 33 | 17.49 | 17.47 | 17.39 | 17.42 | 17.39 | 17.37 | 17.39 |
| 34 | 17.49 | 17.47 | 17.39 | 17.42 | 17.39 | 17.37 | 17.39 |
| 35 | 17.32 | 17.32 | 17.34 | 17.34 | 17.42 | 17.39 | 17.37 |
| 36 | 17.32 | 17.32 | 17.34 | 17.34 | 17.42 | 17.39 | 17.37 |
| 37 | 17.32 | 17.32 | 17.34 | 17.34 | 17.42 | 17.39 | 17.37 |
| 38 | 17.34 | 17.32 | 17.25 | 17.27 | 17.34 | 17.32 | 17.34 |
| 39 | 17.34 | 17.32 | 17.25 | 17.27 | 17.34 | 17.32 | 17.34 |
| 40 | 17.34 | 17.32 | 17.25 | 17.27 | 17.34 | 17.32 | 17.34 |
| 41 | 17.32 | 17.32 | 17.29 | 17.32 | 17.29 | 17.27 | 17.27 |
| 42 | 17.32 | 17.32 | 17.29 | 17.32 | 17.29 | 17.27 | 17.27 |
| 43 | 17.32 | 17.32 | 17.29 | 17.32 | 17.29 | 17.27 | 17.27 |
| 44 | 17.12 | 17.15 | 17.2 | 17.2 | 17.25 | 17.22 | 17.25 |
| 45 | 17.12 | 17.15 | 17.2 | 17.2 | 17.25 | 17.22 | 17.25 |
| 46 | 17.12 | 17.12 | 17.12 | 17.15 | 17.22 | 17.22 | 17.15 |
| 47 | 17.12 | 17.12 | 17.12 | 17.15 | 17.22 | 17.22 | 17.15 |
| 48 | 17.12 | 17.12 | 17.12 | 17.15 | 17.22 | 17.22 | 17.15 |
| 49 | 17.07 | 17.07 | 17.15 | 17.17 | 17.1 | 17.12 | 17.1 |
| 50 | 17.07 | 17.07 | 17.15 | 17.17 | 17.1 | 17.12 | 17.1 |
| 51 | 17.07 | 17.07 | 17.15 | 17.17 | 17.1 | 17.12 | 17.1 |
| 52 | 17.03 | 17.03 | 17.05 | 17.07 | 17.03 | 17.03 | 17.05 |
| 53 | 17.03 | 17.03 | 17.05 | 17.07 | 17.03 | 17.03 | 17.05 |
| 54 | 17.03 | 17.03 | 17.05 | 17.07 | 17.03 | 17.03 | 17.05 |
| 55 | 16.98 | 16.98 | 16.98 | 17.03 | 16.95 | 16.93 | 17 |
| 56 | 16.98 | 16.98 | 16.98 | 17.03 | 16.95 | 16.93 | 17 |

Table C3 is shown next.

TABLE C3

| Data | BPM | BPM | BPM | BPM | BPM | BPM | BPM |
|---|---|---|---|---|---|---|---|
| point | VO8 (V) | VO9 (V) | VO10 (V) | VO11 (V) | VO12 (V) | VO13 (V) | VO14 (V) |
| 1 | 16.46 | 16.34 | 16.31 | 16.46 | 16.44 | 16.44 | 16.44 |
| 2 | 17.32 | 17.29 | 17.3 | 17.29 | 17.29 | 17.29 | 17.27 |
| 3 | 17.32 | 17.29 | 17.3 | 17.29 | 17.29 | 17.29 | 17.27 |
| 4 | 17.61 | 17.54 | 17.48 | 17.56 | 17.56 | 17.59 | 17.56 |
| 5 | 17.61 | 17.54 | 17.48 | 17.56 | 17.56 | 17.59 | 17.56 |
| 6 | 17.61 | 17.54 | 17.48 | 17.56 | 17.56 | 17.59 | 17.56 |
| 7 | 17.66 | 17.68 | 17.66 | 17.68 | 17.71 | 17.73 | 17.73 |
| 8 | 17.66 | 17.68 | 17.66 | 17.68 | 17.71 | 17.73 | 17.73 |
| 9 | 17.66 | 17.68 | 17.66 | 17.68 | 17.71 | 17.73 | 17.73 |
| 10 | 17.78 | 17.76 | 17.71 | 17.78 | 17.81 | 17.61 | 17.66 |
| 11 | 17.78 | 17.76 | 17.71 | 17.78 | 17.81 | 17.61 | 17.66 |
| 12 | 17.78 | 17.76 | 17.71 | 17.78 | 17.81 | 17.61 | 17.66 |
| 13 | 17.9 | 17.9 | 17.87 | 17.81 | 17.83 | 17.86 | 17.88 |
| 14 | 17.9 | 17.9 | 17.87 | 17.81 | 17.83 | 17.86 | 17.88 |
| 15 | 17.9 | 17.9 | 17.87 | 17.81 | 17.83 | 17.86 | 17.88 |
| 16 | 17.95 | 17.88 | 17.86 | 17.93 | 17.93 | 18.08 | 18.05 |
| 17 | 17.95 | 17.88 | 17.86 | 17.93 | 17.93 | 18.08 | 18.05 |
| 18 | 17.76 | 17.81 | 17.79 | 17.78 | 17.81 | 17.76 | 17.81 |
| 19 | 17.76 | 17.81 | 17.79 | 17.78 | 17.81 | 17.76 | 17.81 |
| 20 | 17.76 | 17.81 | 17.79 | 17.78 | 17.81 | 17.76 | 17.81 |
| 21 | 17.68 | 17.73 | 17.68 | 17.83 | 17.83 | 17.66 | 17.66 |
| 22 | 17.68 | 17.73 | 17.68 | 17.83 | 17.83 | 17.66 | 17.66 |
| 23 | 17.68 | 17.73 | 17.68 | 17.83 | 17.83 | 17.66 | 17.66 |
| 24 | 17.56 | 17.68 | 17.68 | 17.68 | 17.68 | 17.64 | 17.66 |
| 25 | 17.56 | 17.68 | 17.68 | 17.68 | 17.68 | 17.64 | 17.66 |
| 26 | 17.56 | 17.68 | 17.68 | 17.68 | 17.68 | 17.64 | 17.66 |
| 27 | 17.64 | 17.56 | 17.54 | 17.59 | 17.56 | 17.51 | 17.51 |
| 28 | 17.64 | 17.56 | 17.54 | 17.59 | 17.56 | 17.51 | 17.51 |
| 29 | 17.64 | 17.56 | 17.54 | 17.59 | 17.56 | 17.51 | 17.51 |
| 30 | 17.47 | 17.54 | 17.49 | 17.54 | 17.51 | 17.51 | 17.51 |
| 31 | 17.47 | 17.54 | 17.49 | 17.54 | 17.51 | 17.51 | 17.51 |
| 32 | 17.42 | 17.39 | 17.38 | 17.44 | 17.44 | 17.39 | 17.39 |
| 33 | 17.42 | 17.39 | 17.38 | 17.44 | 17.44 | 17.39 | 17.39 |
| 34 | 17.42 | 17.39 | 17.38 | 17.44 | 17.44 | 17.39 | 17.39 |
| 35 | 17.37 | 17.47 | 17.44 | 17.34 | 17.37 | 17.42 | 17.39 |
| 36 | 17.37 | 17.47 | 17.44 | 17.34 | 17.37 | 17.42 | 17.39 |
| 37 | 17.37 | 17.47 | 17.44 | 17.34 | 17.37 | 17.42 | 17.39 |
| 38 | 17.37 | 17.32 | 17.34 | 17.34 | 17.37 | 17.37 | 17.37 |
| 39 | 17.37 | 17.32 | 17.34 | 17.34 | 17.37 | 17.37 | 17.37 |
| 40 | 17.37 | 17.32 | 17.34 | 17.34 | 17.37 | 17.37 | 17.37 |
| 41 | 17.27 | 17.29 | 17.29 | 17.29 | 17.32 | 17.22 | 17.22 |
| 42 | 17.27 | 17.29 | 17.29 | 17.29 | 17.32 | 17.22 | 17.22 |
| 43 | 17.27 | 17.29 | 17.29 | 17.29 | 17.32 | 17.22 | 17.22 |
| 44 | 17.27 | 17.22 | 17.25 | 17.27 | 17.27 | 17.17 | 17.15 |
| 45 | 17.27 | 17.22 | 17.25 | 17.27 | 17.27 | 17.17 | 17.15 |
| 46 | 17.17 | 17.1 | 17.07 | 17.15 | 17.17 | 17.15 | 17.15 |
| 47 | 17.17 | 17.1 | 17.07 | 17.15 | 17.17 | 17.15 | 17.15 |
| 48 | 17.17 | 17.1 | 17.07 | 17.15 | 17.17 | 17.15 | 17.15 |
| 49 | 17.12 | 17.1 | 17.1 | 17.15 | 17.17 | 17.07 | 17.07 |
| 50 | 17.12 | 17.1 | 17.1 | 17.15 | 17.17 | 17.07 | 17.07 |
| 51 | 17.12 | 17.1 | 17.1 | 17.15 | 17.17 | 17.07 | 17.07 |
| 52 | 17.1 | 17.03 | 17.02 | 17.05 | 17.05 | 17.03 | 17.03 |
| 53 | 17.1 | 17.03 | 17.02 | 17.05 | 17.05 | 17.03 | 17.03 |
| 54 | 17.1 | 17.03 | 17.02 | 17.05 | 17.05 | 17.03 | 17.03 |
| 55 | 17.03 | 16.98 | 16.99 | 17 | 17.03 | 16.98 | 16.98 |
| 56 | 17.03 | 16.98 | 16.99 | 17 | 17.03 | 16.98 | 16.98 |

Next, Tables D1, D2, D3 show example data captured while testing a battery system of an electric hybrid vehicle in accordance with the example embodiments. The data in Tables D1, D2, D3 was captured while the vehicle was driven in an electric vehicle (EV) mode. The data in Table D2 and Table D3 corresponds to the data in Table D1 (i.e., the data points 1 to 56 in Tables D1 to D3 are the same data points). The electric hybrid vehicle tested during the capture of the data in Tables D1 to D3 is the same electric hybrid vehicle tested during the capture of the data in Tables C1 to C3.

TABLE D1

| Data | SOC | BP Current | TB1 | TB2 | TB3 | BPM Min | BPM Max |
|---|---|---|---|---|---|---|---|
| point | (%) | (A) | (° C.) | (° C.) | (° C.) | (VDC) | (VDC) |
| 1 | 52.9 | 27 | 4.2 | 4.7 | 4.3 | 14.83 | 14.9 |
| 2 | 52.9 | 28.15 | 4.2 | 4.7 | 4.3 | 14.8 | 14.88 |
| 3 | 52.9 | 28.15 | 4.2 | 4.7 | 4.3 | 14.8 | 14.88 |
| 4 | 52.9 | 28.15 | 4.2 | 4.7 | 4.3 | 14.7 | 14.77 |
| 5 | 52.5 | 31.53 | 4.2 | 4.7 | 4.3 | 14.7 | 14.77 |
| 6 | 52.5 | 31.53 | 4.2 | 4.7 | 4.3 | 14.7 | 14.77 |
| 7 | 52.5 | 34.58 | 4.2 | 4.7 | 4.3 | 14.63 | 14.7 |
| 8 | 52.5 | 34.58 | 4.2 | 4.7 | 4.3 | 14.63 | 14.7 |
| 9 | 52.5 | 34.58 | 4.2 | 4.7 | 4.3 | 14.63 | 14.7 |
| 10 | 52.5 | 34.77 | 4.2 | 4.7 | 4.3 | 14.56 | 14.64 |
| 11 | 52.5 | 34.77 | 4.2 | 4.7 | 4.3 | 14.56 | 14.64 |
| 12 | 52.5 | 34.77 | 4.2 | 4.7 | 4.3 | 14.56 | 14.64 |
| 13 | 52.5 | 37.61 | 4.2 | 4.7 | 4.3 | 14.48 | 14.61 |
| 14 | 52.5 | 37.61 | 4.2 | 4.7 | 4.3 | 14.48 | 14.61 |
| 15 | 52.5 | 37.61 | 4.2 | 4.7 | 4.3 | 14.48 | 14.61 |
| 16 | 52.5 | 38.02 | 4.2 | 4.7 | 4.3 | 14.44 | 14.51 |
| 17 | 52.5 | 38.02 | 4.2 | 4.7 | 4.3 | 14.44 | 14.51 |
| 18 | 52.5 | 38.02 | 4.2 | 4.7 | 4.3 | 14.36 | 14.49 |
| 19 | 52.2 | 39.73 | 4.2 | 4.7 | 4.3 | 14.36 | 14.49 |
| 20 | 52.2 | 39.73 | 4.2 | 4.7 | 4.3 | 14.36 | 14.49 |
| 21 | 52.2 | 40.71 | 4.2 | 4.7 | 4.3 | 14.27 | 14.39 |
| 22 | 52.2 | 40.71 | 4.2 | 4.7 | 4.3 | 14.27 | 14.39 |
| 23 | 52.2 | 40.71 | 4.2 | 4.7 | 4.3 | 14.27 | 14.39 |
| 24 | 52.2 | 41.74 | 4.2 | 4.7 | 4.3 | 14.24 | 14.36 |
| 25 | 52.2 | 41.74 | 4.2 | 4.7 | 4.3 | 14.24 | 14.36 |
| 26 | 52.2 | 41.74 | 4.2 | 4.7 | 4.3 | 14.24 | 14.36 |
| 27 | 51.8 | 44.84 | 4.2 | 4.7 | 4.3 | 14.09 | 14.26 |
| 28 | 51.8 | 44.84 | 4.2 | 4.7 | 4.3 | 14.09 | 14.26 |
| 29 | 51.8 | 44.84 | 4.2 | 4.7 | 4.3 | 14.09 | 14.26 |
| 30 | 51.8 | 46.25 | 4.2 | 4.7 | 4.3 | 14.07 | 14.24 |
| 31 | 51.8 | 46.25 | 4.2 | 4.7 | 4.3 | 14.07 | 14.24 |
| 32 | 51.8 | 46.25 | 4.2 | 4.7 | 4.3 | 14.07 | 14.24 |
| 33 | 51.8 | 46.67 | 4.2 | 4.7 | 4.3 | 13.99 | 14.12 |
| 34 | 51.8 | 46.67 | 4.2 | 4.7 | 4.3 | 13.99 | 14.12 |
| 35 | 51.8 | 46.67 | 4.2 | 4.7 | 4.3 | 13.95 | 14.04 |
| 36 | 51.8 | 48.85 | 4.2 | 4.7 | 4.3 | 13.95 | 14.04 |
| 37 | 51.8 | 48.85 | 4.2 | 4.7 | 4.3 | 13.95 | 14.04 |
| 38 | 51.8 | 49.32 | 4.2 | 4.7 | 4.3 | 13.87 | 14.07 |
| 39 | 51.4 | 49.32 | 4.2 | 4.7 | 4.3 | 13.87 | 14.07 |
| 40 | 51.4 | 49.32 | 4.2 | 4.7 | 4.3 | 13.87 | 14.07 |
| 41 | 51.4 | 48.7 | 4.2 | 4.7 | 4.3 | 13.85 | 13.97 |
| 42 | 51.4 | 48.7 | 4.2 | 4.7 | 4.3 | 13.85 | 13.97 |
| 43 | 51.4 | 48.7 | 4.2 | 4.7 | 4.3 | 13.85 | 13.97 |
| 44 | 51.4 | 49.24 | 4.2 | 4.8 | 4.3 | 13.78 | 13.92 |
| 45 | 51.4 | 49.24 | 4.2 | 4.8 | 4.3 | 13.78 | 13.92 |
| 46 | 51.4 | 49.24 | 4.2 | 4.7 | 4.3 | 13.78 | 13.92 |
| 47 | 51 | 50.52 | 4.2 | 4.7 | 4.3 | 13.75 | 13.88 |
| 48 | 51 | 50.52 | 4.2 | 4.7 | 4.3 | 13.75 | 13.88 |
| 49 | 51 | 50.52 | 4.2 | 4.8 | 4.3 | 13.75 | 13.88 |
| 50 | 51 | 51.57 | 4.2 | 4.8 | 4.3 | 13.7 | 13.85 |
| 51 | 51 | 51.57 | 4.2 | 4.7 | 4.3 | 13.7 | 13.85 |
| 52 | 51 | 51.57 | 4.2 | 4.7 | 4.3 | 13.63 | 13.78 |
| 53 | 51 | 51.48 | 4.2 | 4.7 | 4.3 | 13.63 | 13.78 |
| 54 | 51 | 51.48 | 4.2 | 4.8 | 4.3 | 13.65 | 13.78 |
| 55 | 51 | 51.33 | 4.2 | 4.8 | 4.3 | 13.65 | 13.78 |
| 56 | 50.6 | 51.33 | 4.2 | 4.7 | 4.3 | 13.65 | 13.78 |

Table D2 is shown next.

TABLE D2

| Data | BPM | BPM | BPM | BPM | BPM | BPM | BPM |
|---|---|---|---|---|---|---|---|
| point | VO1 (V) | VO2 (V) | VO3 (V) | VO4 (V) | VO5 (V) | VO6 (V) | VO7 (V) |
| 1 | 14.85 | 14.8 | 14.85 | 14.88 | 14.8 | 14.8 | 14.85 |
| 2 | 14.85 | 14.8 | 14.85 | 14.88 | 14.8 | 14.8 | 14.85 |
| 3 | 14.85 | 14.8 | 14.85 | 14.88 | 14.8 | 14.8 | 14.85 |
| 4 | 14.7 | 14.7 | 14.7 | 14.7 | 14.75 | 14.73 | 14.75 |
| 5 | 14.7 | 14.7 | 14.7 | 14.7 | 14.75 | 14.73 | 14.75 |
| 6 | 14.7 | 14.7 | 14.7 | 14.7 | 14.75 | 14.73 | 14.75 |
| 7 | 14.63 | 14.61 | 14.68 | 14.7 | 14.66 | 14.66 | 14.66 |
| 8 | 14.63 | 14.61 | 14.68 | 14.7 | 14.66 | 14.66 | 14.66 |
| 9 | 14.63 | 14.61 | 14.68 | 14.7 | 14.66 | 14.66 | 14.66 |
| 10 | 14.56 | 14.56 | 14.58 | 14.61 | 14.61 | 14.58 | 14.58 |
| 11 | 14.56 | 14.56 | 14.58 | 14.61 | 14.61 | 14.58 | 14.58 |
| 12 | 14.51 | 14.51 | 14.53 | 14.56 | 14.51 | 14.48 | 14.51 |
| 13 | 14.51 | 14.51 | 14.53 | 14.56 | 14.51 | 14.48 | 14.51 |
| 14 | 14.51 | 14.51 | 14.53 | 14.56 | 14.51 | 14.48 | 14.51 |
| 15 | 14.41 | 14.41 | 14.44 | 14.46 | 14.46 | 14.46 | 14.48 |
| 16 | 14.41 | 14.41 | 14.44 | 14.46 | 14.46 | 14.46 | 14.48 |
| 17 | 14.41 | 14.41 | 14.44 | 14.46 | 14.46 | 14.46 | 14.48 |
| 18 | 14.41 | 14.41 | 14.39 | 14.41 | 14.41 | 14.39 | 14.41 |
| 19 | 14.41 | 14.41 | 14.39 | 14.41 | 14.41 | 14.39 | 14.41 |
| 20 | 14.41 | 14.41 | 14.39 | 14.41 | 14.41 | 14.39 | 14.41 |
| 21 | 14.31 | 14.31 | 14.31 | 14.36 | 14.31 | 14.31 | 14.34 |
| 22 | 14.31 | 14.31 | 14.31 | 14.36 | 14.31 | 14.31 | 14.34 |
| 23 | 14.31 | 14.31 | 14.31 | 14.36 | 14.31 | 14.31 | 14.34 |
| 24 | 14.22 | 14.22 | 14.29 | 14.31 | 14.26 | 14.26 | 14.24 |
| 25 | 14.22 | 14.22 | 14.29 | 14.31 | 14.26 | 14.26 | 14.24 |
| 26 | 14.22 | 14.22 | 14.29 | 14.31 | 14.26 | 14.26 | 14.24 |
| 27 | 14.12 | 14.12 | 14.19 | 14.22 | 14.17 | 14.17 | 14.19 |
| 28 | 14.12 | 14.12 | 14.19 | 14.22 | 14.17 | 14.17 | 14.19 |
| 29 | 14.09 | 14.07 | 14.14 | 14.17 | 14.17 | 14.12 | 14.14 |
| 30 | 14.09 | 14.07 | 14.14 | 14.17 | 14.17 | 14.12 | 14.14 |
| 31 | 14.09 | 14.07 | 14.14 | 14.17 | 14.17 | 14.12 | 14.14 |
| 32 | 14.07 | 14.04 | 14 | 14.02 | 14.07 | 14.07 | 14.04 |
| 33 | 14.07 | 14.04 | 14 | 14.02 | 14.07 | 14.07 | 14.04 |
| 34 | 14.07 | 14.04 | 14 | 14.02 | 14.07 | 14.07 | 14.04 |
| 35 | 14.02 | 14 | 14 | 14.02 | 14.02 | 13.97 | 14 |
| 36 | 14.02 | 14 | 14 | 14.02 | 14.02 | 13.97 | 14 |
| 37 | 14.02 | 14 | 14 | 14.02 | 14.02 | 13.97 | 14 |
| 38 | 13.92 | 13.92 | 14 | 14.02 | 13.87 | 13.87 | 13.95 |
| 39 | 13.92 | 13.92 | 14 | 14.02 | 13.87 | 13.87 | 13.95 |
| 40 | 13.92 | 13.92 | 14 | 14.02 | 13.87 | 13.87 | 13.95 |
| 41 | 13.85 | 13.82 | 13.95 | 13.95 | 13.97 | 13.97 | 13.85 |
| 42 | 13.85 | 13.82 | 13.95 | 13.95 | 13.97 | 13.97 | 13.85 |
| 43 | 13.87 | 13.87 | 13.8 | 13.8 | 13.87 | 13.87 | 13.78 |
| 44 | 13.87 | 13.87 | 13.8 | 13.8 | 13.87 | 13.87 | 13.78 |
| 45 | 13.87 | 13.87 | 13.8 | 13.8 | 13.87 | 13.87 | 13.78 |
| 46 | 13.85 | 13.82 | 13.75 | 13.78 | 13.78 | 13.78 | 13.7 |
| 47 | 13.85 | 13.82 | 13.75 | 13.78 | 13.78 | 13.78 | 13.7 |
| 48 | 13.85 | 13.82 | 13.75 | 13.78 | 13.78 | 13.78 | 13.7 |
| 49 | 13.78 | 13.73 | 13.65 | 13.65 | 13.7 | 13.68 | 13.75 |
| 50 | 13.78 | 13.73 | 13.65 | 13.65 | 13.7 | 13.68 | 13.75 |
| 51 | 13.78 | 13.73 | 13.65 | 13.65 | 13.7 | 13.68 | 13.75 |
| 52 | 13.73 | 13.7 | 13.7 | 13.7 | 13.78 | 13.73 | 13.78 |
| 53 | 13.73 | 13.7 | 13.7 | 13.7 | 13.78 | 13.73 | 13.78 |
| 54 | 13.73 | 13.7 | 13.7 | 13.7 | 13.78 | 13.73 | 13.78 |
| 55 | 13.68 | 13.68 | 13.78 | 13.78 | 13.68 | 13.68 | 13.73 |
| 56 | 13.68 | 13.68 | 13.78 | 13.78 | 13.68 | 13.68 | 13.73 |

Table D3 is shown next.

TABLE D3

| Data | BPM | BPM | BPM | BPM | BPM | BPM | BPM |
|---|---|---|---|---|---|---|---|
| point | VO8 (V) | VO9 (V) | VO10 (V) | VO11 (V) | VO12 (V) | VO13 (V) | VO14 (V) |
| 1 | 14.85 | 14.8 | 14.82 | 14.83 | 14.85 | 14.85 | 14.83 |
| 2 | 14.85 | 14.8 | 14.82 | 14.83 | 14.85 | 14.85 | 14.83 |
| 3 | 14.85 | 14.8 | 14.82 | 14.83 | 14.85 | 14.7 | 14.7 |
| 4 | 14.75 | 14.7 | 14.69 | 14.7 | 14.7 | 14.7 | 14.7 |
| 5 | 14.75 | 14.7 | 14.69 | 14.7 | 14.7 | 14.7 | 14.7 |
| 6 | 14.75 | 14.7 | 14.69 | 14.7 | 14.7 | 14.61 | 14.61 |
| 7 | 14.66 | 14.63 | 14.64 | 14.63 | 14.66 | 14.61 | 14.61 |
| 8 | 14.66 | 14.63 | 14.64 | 14.63 | 14.66 | 14.61 | 14.61 |
| 9 | 14.66 | 14.63 | 14.64 | 14.63 | 14.66 | 14.61 | 14.61 |
| 10 | 14.61 | 14.63 | 14.64 | 14.58 | 14.58 | 14.61 | 14.61 |
| 11 | 14.61 | 14.63 | 14.64 | 14.58 | 14.58 | 14.51 | 14.51 |
| 12 | 14.53 | 14.56 | 14.54 | 14.51 | 14.53 | 14.51 | 14.51 |
| 13 | 14.53 | 14.56 | 14.54 | 14.51 | 14.53 | 14.51 | 14.51 |
| 14 | 14.53 | 14.56 | 14.54 | 14.51 | 14.53 | 14.41 | 14.41 |
| 15 | 14.51 | 14.46 | 14.47 | 14.44 | 14.44 | 14.41 | 14.41 |
| 16 | 14.51 | 14.46 | 14.47 | 14.44 | 14.44 | 14.41 | 14.41 |
| 17 | 14.51 | 14.46 | 14.47 | 14.44 | 14.44 | 14.36 | 14.36 |
| 18 | 14.44 | 14.39 | 14.38 | 14.41 | 14.44 | 14.36 | 14.36 |
| 19 | 14.44 | 14.39 | 14.38 | 14.41 | 14.44 | 14.36 | 14.36 |
| 20 | 14.44 | 14.39 | 14.38 | 14.41 | 14.44 | 14.31 | 14.31 |
| 21 | 14.36 | 14.26 | 14.27 | 14.39 | 14.39 | 14.31 | 14.31 |
| 22 | 14.36 | 14.26 | 14.27 | 14.39 | 14.39 | 14.31 | 14.31 |
| 23 | 14.36 | 14.26 | 14.27 | 14.39 | 14.39 | 14.22 | 14.22 |
| 24 | 14.26 | 14.29 | 14.29 | 14.24 | 14.26 | 14.22 | 14.22 |
| 25 | 14.26 | 14.29 | 14.29 | 14.24 | 14.26 | 14.22 | 14.22 |
| 26 | 14.26 | 14.29 | 14.29 | 14.24 | 14.26 | 14.12 | 14.14 |
| 27 | 14.22 | 14.12 | 14.14 | 14.14 | 14.19 | 14.12 | 14.14 |
| 28 | 14.22 | 14.12 | 14.14 | 14.14 | 14.19 | 14.09 | 14.12 |
| 29 | 14.17 | 14.09 | 14.08 | 14.14 | 14.14 | 14.09 | 14.12 |
| 30 | 14.17 | 14.09 | 14.08 | 14.14 | 14.14 | 14.09 | 14.12 |
| 31 | 14.17 | 14.09 | 14.08 | 14.14 | 14.14 | 14.04 | 14.04 |
| 32 | 14.04 | 14.04 | 14.03 | 14.09 | 14.09 | 14.04 | 14.04 |
| 33 | 14.04 | 14.04 | 14.03 | 14.09 | 14.09 | 14.04 | 14.04 |
| 34 | 14.04 | 14.04 | 14.03 | 14.09 | 14.09 | 14 | 14.02 |
| 35 | 14 | 13.92 | 13.94 | 14.04 | 14.04 | 14 | 14.02 |
| 36 | 14 | 13.92 | 13.94 | 14.04 | 14.04 | 14 | 14.02 |
| 37 | 14 | 13.92 | 13.94 | 14.04 | 14.04 | 13.85 | 13.87 |
| 38 | 13.97 | 13.97 | 13.97 | 13.95 | 13.97 | 13.85 | 13.87 |
| 39 | 13.97 | 13.97 | 13.97 | 13.95 | 13.97 | 13.85 | 13.87 |
| 40 | 13.97 | 13.97 | 13.97 | 13.95 | 13.97 | 13.85 | 13.87 |
| 41 | 13.87 | 13.85 | 13.86 | 13.9 | 13.9 | 13.85 | 13.87 |
| 42 | 13.87 | 13.85 | 13.86 | 13.9 | 13.9 | 13.85 | 13.85 |
| 43 | 13.82 | 13.75 | 13.78 | 13.85 | 13.85 | 13.85 | 13.85 |
| 44 | 13.82 | 13.75 | 13.78 | 13.85 | 13.85 | 13.85 | 13.85 |
| 45 | 13.82 | 13.75 | 13.78 | 13.85 | 13.85 | 13.8 | 13.8 |
| 46 | 13.7 | 13.75 | 13.78 | 13.85 | 13.85 | 13.8 | 13.8 |
| 47 | 13.7 | 13.75 | 13.78 | 13.85 | 13.85 | 13.8 | 13.8 |
| 48 | 13.7 | 13.75 | 13.78 | 13.85 | 13.85 | 13.7 | 13.73 |
| 49 | 13.75 | 13.75 | 13.8 | 13.8 | 13.82 | 13.7 | 13.73 |
| 50 | 13.75 | 13.75 | 13.8 | 13.8 | 13.82 | 13.7 | 13.73 |
| 51 | 13.75 | 13.75 | 13.8 | 13.8 | 13.82 | 13.65 | 13.68 |
| 52 | 13.78 | 13.75 | 13.75 | 13.63 | 13.63 | 13.65 | 13.68 |
| 53 | 13.78 | 13.75 | 13.75 | 13.63 | 13.63 | 13.65 | 13.68 |
| 54 | 13.78 | 13.75 | 13.75 | 13.63 | 13.63 | 13.65 | 13.68 |
| 55 | 13.75 | 13.75 | 13.76 | 13.65 | 13.65 | 13.65 | 13.68 |
| 56 | 13.75 | 13.75 | 13.76 | 13.65 | 13.65 | 13.65 | 13.68 |

Table E1, E2 show example data captured while testing a battery system of a 2016 TOYOTA® PRIUS®, in accordance with the example embodiments. The data in Table E1 and Table E2 was captured while the vehicle was driven in a regenerative braking mode. The data in Table E2 corresponds to the data in Table D1 (i.e., the data points 1 to 31 in Tables E1 to E2 are the same data points).

The first row of Table E1 and Table F1 include the following abbreviations: A (i.e., Amperes), V (i.e., Voltage), and SOC (i.e., state of charge). The voltages in Table E1 and Table F1 are DC voltages.

TABLE E1

| Data | Hybrid Battery | Hybrid Battery | Hybrid Battery |
|---|---|---|---|
| point | Current (A) | Voltage (V) | SOC (%) |
| 1 | −11.77 | 228 | 47.84 |
| 2 | −11.77 | 228 | 47.84 |
| 3 | −38.67 | 234 | 47.84 |
| 4 | −38.67 | 234 | 47.84 |
| 5 | −24.33 | 236 | 47.84 |
| 6 | −24.33 | 236 | 47.84 |
| 7 | −24.33 | 236 | 47.84 |
| 8 | −24.33 | 236 | 47.84 |
| 9 | −24.33 | 236 | 47.84 |
| 10 | −117.08 | 261 | 48.24 |
| 11 | −117.08 | 261 | 48.24 |
| 12 | −120.22 | 261 | 48.63 |
| 13 | −120.22 | 261 | 48.63 |
| 14 | −103.6 | 259 | 49.02 |
| 15 | −103.6 | 259 | 49.02 |
| 16 | −103.6 | 259 | 49.02 |
| 17 | −103.6 | 259 | 49.02 |
| 18 | −103.6 | 259 | 49.02 |
| 19 | −82.58 | 256 | 49.41 |
| 20 | −82.58 | 256 | 49.41 |
| 21 | −78.84 | 255 | 49.41 |
| 22 | −78.84 | 255 | 49.41 |
| 23 | −76.9 | 255 | 49.41 |
| 24 | −76.9 | 255 | 49.41 |
| 25 | −76.9 | 255 | 49.41 |
| 26 | −76.9 | 255 | 49.41 |
| 27 | −76.9 | 255 | 49.41 |
| 28 | −64.44 | 252 | 50.2 |
| 29 | −64.44 | 252 | 50.2 |
| 30 | −53.2 | 250 | 50.2 |
| 31 | −53.2 | 250 | 50.2 |

Table E2 is shown next. The battery pack module (BPM) in Table E2 can be referred to as a “battery block,” or by other term(s).

TABLE E2

| | Hybrid Battery pack module # Voltage (V) | | | | | | | | |
|---|---|---|---|---|---|---|---|---|---|
| Data | BPM | BPM | BPM | BPM | BPM | BPM | BPM | BPM | BPM |
| point | 1 | 2 | 3 | 4 | 5 | 6 | 7 | 8 | 9 |
| 1 | 16.37 | 16.32 | 32.59 | 32.63 | 32.59 | 32.59 | 32.54 | 16.34 | 16.37 |
| 2 | 16.37 | 16.32 | 32.59 | 32.63 | 32.59 | 32.59 | 32.54 | 16.34 | 16.37 |
| 3 | 16.76 | 16.71 | 33.22 | 33.42 | 33.22 | 33.37 | 33.12 | 16.68 | 16.71 |
| 4 | 16.76 | 16.71 | 33.22 | 33.42 | 33.22 | 33.37 | 33.12 | 16.68 | 16.71 |
| 5 | 17.32 | 17.25 | 33.91 | 34.49 | 33.91 | 34.64 | 33.81 | 17.27 | 17.27 |
| 6 | 17.32 | 17.25 | 33.91 | 34.49 | 33.91 | 34.64 | 33.81 | 17.27 | 17.27 |
| 7 | 17.32 | 17.25 | 33.91 | 34.49 | 33.91 | 34.64 | 33.81 | 17.27 | 17.27 |
| 8 | 17.32 | 17.25 | 33.91 | 34.49 | 33.91 | 34.64 | 33.81 | 17.27 | 17.27 |
| 9 | 17.32 | 17.25 | 33.91 | 34.49 | 33.91 | 34.64 | 33.81 | 17.27 | 17.27 |
| 10 | 18.66 | 18.59 | 37.08 | 37.08 | 36.98 | 37.13 | 36.98 | 18.61 | 18.66 |
| 11 | 18.66 | 18.59 | 37.08 | 37.08 | 37.18 | 37.42 | 37.28 | 18.74 | 18.66 |
| 12 | 18.88 | 18.76 | 37.28 | 37.42 | 37.18 | 37.42 | 37.28 | 18.74 | 18.81 |
| 13 | 18.88 | 18.76 | 37.28 | 37.42 | 36.98 | 39.94 | 36.98 | 18.56 | 18.81 |
| 14 | 18.66 | 18.54 | 37.08 | 37.08 | 36.98 | 39.94 | 36.98 | 18.56 | 18.61 |
| 15 | 18.66 | 18.54 | 37.08 | 37.08 | 36.98 | 39.94 | 36.98 | 18.56 | 18.61 |
| 16 | 18.66 | 18.54 | 37.08 | 37.08 | 36.98 | 39.94 | 36.98 | 18.56 | 18.61 |
| 17 | 18.66 | 18.54 | 37.08 | 37.08 | 36.98 | 39.94 | 36.98 | 18.56 | 18.61 |
| 18 | 18.66 | 18.54 | 37.08 | 37.08 | 36.5 | 36.54 | 36.54 | 18.32 | 18.61 |
| 19 | 18.42 | 18.3 | 36.54 | 36.59 | 36.5 | 36.54 | 36.54 | 18.32 | 18.37 |
| 20 | 18.42 | 18.3 | 36.54 | 36.59 | 36.4 | 36.45 | 36.45 | 18.27 | 18.37 |
| 21 | 18.37 | 18.27 | 36.45 | 36.5 | 36.4 | 36.45 | 36.45 | 18.27 | 18.32 |
| 22 | 18.37 | 18.27 | 36.45 | 36.5 | 36.35 | 36.45 | 36.35 | 18.27 | 18.32 |
| 23 | 18.34 | 18.25 | 36.45 | 36.5 | 36.35 | 36.45 | 36.35 | 18.27 | 18.32 |
| 24 | 18.34 | 18.25 | 36.45 | 36.5 | 36.35 | 36.45 | 36.35 | 18.27 | 18.32 |
| 25 | 18.34 | 18.25 | 36.45 | 36.5 | 36.35 | 36.45 | 36.35 | 18.27 | 18.32 |
| 26 | 18.34 | 18.25 | 36.45 | 36.5 | 36.35 | 36.45 | 36.35 | 18.27 | 18.32 |
| 27 | 18.34 | 18.25 | 36.45 | 36.5 | 35.96 | 36.06 | 36.01 | 18.08 | 18.32 |
| 28 | 18.12 | 18.05 | 36.06 | 36.11 | 35.96 | 36.06 | 36.01 | 18.08 | 18.1 |
| 29 | 18.12 | 18.05 | 36.06 | 36.11 | 35.57 | 35.67 | 35.57 | 17.88 | 18.1 |
| 30 | 17.93 | 17.86 | 35.62 | 35.76 | 35.57 | 35.67 | 35.57 | 17.88 | 17.9 |
| 31 | 17.93 | 17.86 | 35.62 | 35.76 | 35.57 | 35.67 | 35.57 | 17.88 | 17.9 |

Table E1 shows example data captured while testing a battery system of a 2016 TOYOTA® PRIUS®, in accordance with the example embodiments. The data in Table F1 and Table F2 was captured while the vehicle was driven in an electric vehicle (EV) mode. The data in Table F2 corresponds to the data in Table F1 (i.e., the data points 1 to 31 in Table F1 and Table F2 are the same data points). The electric hybrid vehicle tested during the capture of the data in Table F1 and Table F2 is the same electric hybrid vehicle tested during the capture of the data in Table E1 and Table E2.

TABLE F1

| Data | Hybrid Battery | Hybrid Battery | Hybrid Battery |
|---|---|---|---|
| point | Current (A) | Voltage (V) | SOC (%) |
| 1 | 1.4 | 226 | 50.59 |
| 2 | 1.4 | 226 | 50.59 |
| 3 | 4.4 | 225 | 50.59 |
| 4 | 4.4 | 225 | 50.59 |
| 5 | 4.4 | 225 | 50.59 |
| 6 | 4.4 | 225 | 50.59 |
| 7 | 4.4 | 225 | 50.59 |
| 8 | 13.2 | 223 | 50.59 |
| 9 | 13.2 | 223 | 50.59 |
| 10 | 18 | 221 | 50.2 |
| 11 | 18 | 221 | 50.2 |
| 12 | 24.4 | 220 | 50.2 |
| 13 | 24.4 | 220 | 50.2 |
| 14 | 24.4 | 220 | 50.2 |
| 15 | 24.4 | 220 | 50.2 |
| 16 | 24.4 | 220 | 50.2 |
| 17 | 28.8 | 216 | 50.2 |
| 18 | 28.8 | 216 | 50.2 |
| 19 | 33.2 | 215 | 50.2 |
| 20 | 33.2 | 215 | 50.2 |
| 21 | 40.5 | 213 | 50.2 |
| 22 | 40.5 | 213 | 50.2 |
| 23 | 40.5 | 213 | 50.2 |
| 24 | 40.5 | 213 | 50.2 |
| 25 | 40.5 | 213 | 50.2 |
| 26 | 40.5 | 209 | 50.2 |
| 27 | 46.9 | 208 | 49.8 |
| 28 | 48.3 | 208 | 49.8 |
| 29 | 48.3 | 207 | 49.8 |
| 30 | 49.3 | 207 | 49.8 |
| 31 | 49.3 | 207 | 49.8 |

Table F2 is shown next. The battery pack module (BPM) in Table F2 can be referred to as a “battery block,” or by other term(s).

TABLE F2

| | Hybrid Battery pack module # Voltage (V) | | | | | | | | |
|---|---|---|---|---|---|---|---|---|---|
| Data | BPM | BPM | BPM | BPM | BPM | BPM | BPM | BPM | BPM |
| point | 1 | 2 | 3 | 4 | 5 | 6 | 7 | 8 | 9 |
| 1 | 16.1 | 16.07 | 32.15 | 32.24 | 32 | 32.19 | 32.1 | 16.12 | 16.1 |
| 2 | 16.1 | 16.07 | 32.15 | 32.24 | 32 | 32.19 | 32.1 | 16.12 | 16.1 |
| 3 | 16.1 | 16.07 | 32.15 | 32.24 | 32.1 | 32.15 | 32.1 | 16.05 | 16.07 |
| 4 | 16.1 | 16.07 | 32.15 | 32.19 | 32.1 | 32.15 | 32.1 | 16.05 | 16.07 |
| 5 | 16.1 | 16.07 | 32.15 | 32.19 | 32.1 | 32.15 | 32.1 | 16.05 | 16.07 |
| 6 | 16.1 | 16.07 | 32.15 | 32.19 | 32.1 | 32.15 | 32.1 | 16.05 | 16.07 |
| 7 | 16.1 | 16.07 | 32.15 | 32.19 | 32.1 | 32.15 | 32.1 | 16.05 | 16.07 |
| 8 | 15.85 | 15.83 | 31.76 | 31.76 | 31.71 | 31.71 | 31.71 | 15.9 | 15.85 |
| 9 | 15.85 | 15.83 | 31.76 | 31.76 | 31.71 | 31.71 | 31.71 | 15.9 | 15.85 |
| 10 | 15.75 | 15.73 | 31.46 | 31.51 | 31.46 | 31.56 | 31.51 | 15.78 | 15.73 |
| 11 | 15.75 | 15.73 | 31.46 | 31.51 | 31.46 | 31.56 | 31.51 | 15.78 | 15.73 |
| 12 | 15.63 | 15.63 | 31.22 | 31.41 | 31.22 | 31.41 | 31.22 | 15.63 | 15.61 |
| 13 | 15.63 | 15.63 | 31.22 | 31.41 | 31.22 | 31.41 | 31.22 | 15.63 | 15.61 |
| 14 | 15.63 | 15.63 | 31.22 | 31.41 | 31.22 | 31.41 | 31.22 | 15.63 | 15.61 |
| 15 | 15.63 | 15.63 | 31.22 | 31.41 | 31.22 | 31.41 | 31.22 | 15.63 | 15.61 |
| 16 | 15.63 | 15.63 | 31.22 | 31.41 | 31.22 | 31.41 | 31.22 | 15.63 | 15.61 |
| 17 | 15.44 | 15.41 | 30.88 | 30.92 | 30.83 | 30.88 | 30.83 | 15.44 | 15.39 |
| 18 | 15.44 | 15.41 | 30.88 | 30.92 | 30.83 | 30.88 | 30.83 | 15.44 | 15.39 |
| 19 | 15.34 | 15.34 | 30.63 | 30.73 | 30.63 | 30.73 | 30.63 | 15.29 | 15.24 |
| 20 | 15.34 | 15.34 | 30.63 | 30.73 | 30.63 | 30.73 | 30.63 | 15.29 | 15.24 |
| 21 | 15.19 | 15.19 | 30.24 | 30.44 | 30.29 | 30.39 | 30.29 | 15.19 | 15.14 |
| 22 | 15.19 | 15.19 | 30.24 | 30.44 | 30.29 | 30.39 | 30.29 | 15.19 | 15.14 |
| 23 | 15.19 | 15.19 | 30.24 | 30.44 | 30.29 | 30.39 | 30.29 | 15.19 | 15.14 |
| 24 | 15.19 | 15.19 | 30.24 | 30.44 | 30.29 | 30.39 | 30.29 | 15.19 | 15.14 |
| 25 | 15.19 | 15.19 | 30.24 | 30.44 | 30.29 | 30.39 | 30.29 | 15.19 | 15.14 |
| 26 | 15.19 | 15.19 | 30.24 | 30.44 | 30.29 | 30.39 | 30.29 | 15.19 | 15.14 |
| 27 | 14.92 | 14.9 | 29.85 | 29.9 | 29.85 | 29.9 | 29.85 | 14.95 | 14.88 |
| 28 | 14.88 | 14.88 | 29.7 | 29.8 | 29.75 | 29.8 | 29.75 | 14.9 | 14.83 |
| 29 | 14.88 | 14.88 | 29.7 | 29.8 | 29.75 | 29.8 | 29.75 | 14.9 | 14.83 |
| 30 | 14.8 | 14.83 | 29.65 | 29.7 | 29.65 | 29.7 | 29.65 | 14.85 | 14.78 |
| 31 | 14.8 | 14.83 | 29.65 | 29.7 | 29.65 | 29.7 | 29.65 | 14.85 | 14.78 |

### IX. Conclusion

It should be understood that the arrangements described herein and/or shown in the drawings are for purposes of example only and are not intended to be limiting. As such, those skilled in the art will appreciate that other arrangements and elements (e.g., machines, interfaces, functions, orders, and/or groupings of functions) can be used instead, and some elements can be omitted altogether. Furthermore, various functions described and/or shown in the drawings as being performed by one or more elements can be carried out by a processor executing computer-readable program instructions or by a combination of hardware, firmware, and/or software. For purposes of this description, execution of CRPI contained in a computer-readable memory to perform some function can include executing all of the program instructions of those CRPI or only a portion of those CRPI.

While various aspects and embodiments are described herein, other aspects and embodiments will be apparent to those skilled in the art. The various aspects and embodiments disclosed herein are for purposes of illustration and are not intended to be limiting, with the true scope being indicated by the claims, along with the full scope of equivalents to which such claims are entitled. It is also to be understood that the terminology used herein for the purpose of describing embodiments only, and is not intended to be limiting.

In this description, the articles “a,” “an,” and “the” are used to introduce elements and/or functions of the example embodiments. The intent of using those articles is that there is one or more of the introduced elements and/or functions.

In this description, the intent of using the term “and/or” within a list of at least two elements or functions and the intent of using the terms “at least one of,” “at least one of the following,” “one or more of,” “one or more from among,” and “one or more of the following” immediately preceding a list of at least two components or functions is to cover each embodiment including a listed component or function independently and each embodiment including a combination of the listed components or functions. For example, an embodiment described as including A, B, and/or C, or at least one of A, B, and C, or at least one of: A, B, and C, or at least one of A, B, or C, or at least one of: A, B, or C, or one or more of A, B, and C, or one or more of: A, B, and C, or one or more of A, B, or C, or one or more of: A, B, or C is intended to cover each of the following possible embodiments: (i) an embodiment including A, but not B and not C, (ii) an embodiment including B, but not A and not C, (iii) an embodiment including C, but not A and not B, (iv) an embodiment including A and B, but not C, (v) an embodiment including A and C, but not B, (v) an embodiment including B and C, but not A, and/or (vi) an embodiment including A, B, and C. For the embodiments including component or function A, the embodiments can include one A or multiple A. For the embodiments including component or function B, the embodiments can include one B or multiple B. For the embodiments including component or function C, the embodiments can include one C or multiple C. In accordance with the aforementioned example and at least some of the example embodiments, “A” can represent a component, “B” can represent a system, and “C” can represent a symptom.

The use of ordinal numbers such as “first,” “second,” “third” and so on is to distinguish respective elements rather than to denote an order of those elements unless the context of using those terms explicitly indicates otherwise. The use of the symbol “$” as prefix to a number indicates the number is a hexadecimal number.

Embodiments of the present disclosure can thus relate to one of the enumerated example embodiments (EEEs) listed below.

EEE A1 is a computing system comprising: a processor; and a non-transitory computer-readable memory storing executable instructions, wherein execution of the executable instructions by the processor causes the computing system to perform functions comprising: determining a vehicle is being driven in an electric vehicle mode with a first output rate continuously for at least a first threshold amount of time; determining multiple first sets of battery voltage values for multiple battery pack components in the vehicle as the vehicle is driven in the electric vehicle mode with the first output rate continuously for at least the first threshold amount of time, each first set of battery voltage values includes or is representative of a pair of battery voltage values; determining the vehicle is being driven in a regenerative braking mode with a second output rate continuously for at least a second threshold amount of time; determining multiple second sets of battery voltage values for the multiple battery pack components in the vehicle as the vehicle is driven in the regenerative braking mode, each second set of battery voltage values includes or is representative of a pair of battery voltage values; and outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Each pair of battery voltage values among the second set of battery voltage values includes or is representative of minimum and maximum battery voltage values from each second set of battery voltage values.

EEE A2 is the computing system of EEE A1, wherein: the functions further comprise monitoring parameters from the vehicle. The parameters include a first set of parameters indicative of a first electrical current and a system voltage within the vehicle, and a second set of parameters indicative of a second electrical current and the system voltage. The first electrical current is different than the second electrical current. Determining the vehicle is being driven in the electric vehicle mode with the first output rate is based on the first set of parameters. Determining the vehicle is being driven in the regenerative braking mode with the second output rate is based on the second set of parameters.

EEE A3 is the computing system of any one of EEE A1 to A2, wherein: the functions further comprise determining a particular battery pack component in the multiple battery pack components has a maximum battery voltage, and the first threshold amount of time equals an amount of time it takes for a battery voltage of the particular battery pack component to decay by a threshold percentage of the maximum battery voltage while the vehicle is being driven in the electric vehicle mode with the first output rate.

EEE A4 is the computing system of any one of EEE A1 to A3, wherein: the first threshold amount of time is a first fixed amount of time stored in the non-transitory computer-readable memory, and the second threshold amount of time is a second fixed amount of time stored in the non-transitory computer-readable memory.

EEE A5 is the computing system of any one of EEE A1 to A4, wherein: the functions further comprise determining, based on one or more parameter values corresponding to a particular parameter identifier, whether the vehicle is in a condition for testing the battery pack; and the one or more parameter values corresponding to the particular parameter identifier are representative of a battery state-of-charge or a battery temperature.

EEE A6 is the computing system of any one of EEE A1 to A5, wherein the functions further comprise: transmitting, to the vehicle, one or more vehicle messages to request diagnostic trouble code data from the vehicle; receiving, from the vehicle, one or more other vehicle messages including diagnostic trouble code data; and determining no diagnostic trouble codes are currently set active in a battery management system of the vehicle.

EEE A7 is the computing system of any one of EEE A1 to A6, wherein: the first output rate includes multiple output rates within a range of positive current rates, and the second output rate includes multiple output rates within a range of negative current rates.

EEE A8 is the computing system of any one of EEE A1 to A7, wherein determining the vehicle is being driven in the electric vehicle mode with the first output rate continuously for at least the first threshold amount of time and determining the multiple first sets of battery voltage values occurs before determining the vehicle is being driven in the regenerative braking mode with the second output rate continuously for at least the second threshold amount of time and determining the multiple second sets of battery voltage values.

EEE A9 is the computing system of any one of EEE A1 to A7, wherein determining the vehicle is being driven in the electric vehicle mode with the first output rate continuously for at least the first threshold amount of time and determining the multiple first sets of battery voltage values occurs after determining the vehicle is being driven in the regenerative braking mode with the second output rate continuously for at least the second threshold amount of time and determining the multiple second sets of battery voltage values.

EEE A10 is the computing system of any one of EEE A1 to A9, wherein the first output rate is specified as: a given percentage of a specified peak output current of electrical motor(s) in the vehicle, or a range of currents including the specified peak output current of electrical motor(s) in the vehicle.

EEE A11 is the computing system of any one of EEE A1 to A10, wherein: the first output rate includes a first range of output rates, the first sets of battery voltage values are determined sequentially, each first set of battery voltage values is associated with an output rate within the first range of output rates, and the functions further comprise receiving battery voltage values for at least some battery pack components within the multiple battery pack components to determine a particular first set of battery voltage values before receiving battery voltage values for at least some battery pack components within the multiple battery pack components to determine a next first set of battery voltage values.

EEE A12 is the computing system of any one of EEE A1 to A11, wherein: the second output rate includes a second range of output rates, the second sets of battery voltage values are determined sequentially, each second set of battery voltage values is associated with an output rate within the second range of output rates, and the functions further comprise receiving battery voltage values for at least some battery pack components within the multiple battery pack components to determine a particular second set of battery voltage values before receiving battery voltage values for at least some battery pack components within the multiple battery pack components to determine a next second set of battery voltage values.

EEE A13 is the computing system of any one of EEE A1 to A12, wherein the test indicator is based on whether the differences in pairs of battery voltage values among the first set of battery voltage values and whether differences in pairs of battery voltage values among the second set of battery voltage values exceed a threshold voltage value.

EEE A14 is the computing system of any one of EEE A1 to A13, wherein: the minimum and maximum battery voltage values of each pair of battery voltage values within the first sets of battery voltage values correspond to each other temporally, and the minimum and maximum battery voltage values of each pair of battery voltage values within the second sets of battery voltage values correspond to each other temporally.

EEE A15 is the computing system of any one of EEE A1 to A13, wherein: the minimum and maximum battery voltage values of each pair of battery voltage values within the first sets of battery voltage values are determined from a respective first set of vehicle messages received from the vehicle, and the minimum and maximum battery voltage values of each pair of battery voltage values within the second sets of battery voltage values are determined from a respective second set of vehicle messages received from the vehicle.

EEE A16 is the computing system of EEE A15, wherein: each respective first set of vehicle messages includes parameter-identifier (PID) parameter values corresponding to first, second, third, and fourth PIDs, each respective second set of vehicle messages includes PID parameter values corresponding to the first, second, third, and fourth PIDs, the first PID corresponds to a maximum battery voltage of a battery pack component within the multiple battery pack components having the maximum battery voltage at a respective time, the second PID corresponds to a battery identifier of the battery pack component within the multiple battery pack components having the maximum battery voltage at a respective time, the third PID corresponds to a minimum battery voltage of a battery pack component within the multiple battery pack components having the minimum battery voltage at the respective time, and the fourth PID corresponds to a battery identifier of the battery pack component within the multiple battery pack components having the minimum battery voltage at the respective time.

EEE A17 is the computing system of EEE A15, wherein: each respective first set of vehicle messages includes parameter-identifier (PID) parameter values corresponding to a battery voltage of each battery pack component within the multiple battery pack components at a respective time as the vehicle is being driven in the electric vehicle mode with the first output rate, each respective second set of vehicle messages includes PID parameter values corresponding to a battery voltage of each battery pack component within the multiple battery pack components at a respective time as the vehicle is driven in the regenerative braking mode with the second output rate. The functions further comprise: determining the minimum and maximum battery voltage values from each first set of battery voltage values based on minimum and maximum PID parameter values of each respective first set of vehicle messages, and determining the minimum maximum battery voltage values from each second set of battery voltage values based on minimum and maximum PID parameter values of each respective second set of vehicle messages.

EEE A18 is the computing system of any one of EEE A1 to A17, wherein: the multiple first sets of battery voltage values for the multiple battery pack components and the multiple second sets of battery voltage values for the multiple battery pack components include groups of battery voltage values, each group of battery voltages includes a respective battery voltage value for one or more battery pack components in the vehicle battery pack, and each respective battery voltage value in each group of battery voltage values correspond to each other temporally.

EEE A19 is the computing system of any one of EEE A1 to A18, wherein: the minimum and maximum battery voltage values for each pair of battery voltage values among the first set of battery voltage values are voltage values corresponding to different battery pack components of the battery pack, and the minimum and maximum battery voltage values for each pair of battery voltage values among the second set of battery voltage values are voltage values corresponding to different battery pack components of the battery pack.

EEE A20 is the computing system of EEE A19, wherein the functions further comprise: storing the multiple first sets of battery voltage values and the multiple second sets of battery voltage values in the non-transitory computer-readable memory; comparing all battery voltage values corresponding to each battery pack component of the multiple battery pack components from among each first set of battery voltage values to each other to determine the minimum and maximum battery voltage values for each pair of battery voltage values among the first sets of battery voltage values; and comparing all battery voltage values corresponding to each battery pack component of the multiple battery pack components from among each second set of battery voltage values to each other to determine the minimum and maximum battery voltage values for each pair of battery voltage values among the second sets of battery voltage values.

EEE A21 is the computing system of any one of EEE A1 to A20, wherein the test indicator regarding the state of a battery pack includes a recommendation to rebalance two or more battery pack components in the battery pack or replacement of one or more battery pack components in the battery pack.

EEE A22 is the computing system of EEE A21, wherein the recommendation of the replacement of one or more battery pack components in the battery pack is based on differences in pairs of battery voltage values decreasing while the vehicle is driven in the electric vehicle mode with a first output rate by more than a voltage comparison threshold.

EEE A23 is the computing system of EEE A22, further comprises: a current clamp meter, wherein the functions further comprise determining the first output rate based on first current samples obtained using the current clamp meter and determining the second output rate based on second current samples obtained using the current clamp meter.

EEE A24 is the computing system of any one of EEE A1 to A23, wherein: the functions further comprise: determining the vehicle is parked and operating in an operating state in which vehicle power is turned on and electrical accessories are turned off; determining multiple third sets of battery voltage values for the multiple battery pack components while the vehicle is operating in the operating state, each third set of battery voltage values includes a battery voltage value for each battery pack component of the multiple battery pack components; and determining the third sets of battery voltage values equal or exceed a threshold battery voltage or at least some battery voltages of the third sets of battery voltage do not equal or exceed the threshold battery voltage, the computing system is configured to determine the vehicle is being driven in the electric vehicle mode with the first output rate continuously for at least the first threshold amount of time or the regenerative braking mode with the second output rate continuously for at least the second threshold amount of time in response to determining the third sets of battery voltage values equal or exceed the threshold battery voltage, and the executable instructions include instructions executable by the processor to output a notification indicating the battery pack failed a battery test in response to determining at least some battery voltages of the third sets of battery voltage do not equal or exceed the threshold battery voltage.

EEE A25 is the computing system of any one of EEE A1 to A24, wherein: determining the vehicle is being driven in the electric vehicle mode with the first output rate continuously for at least the first threshold amount of time includes determining a first set of parameters received from the vehicle indicate electrical current within a circuit of the vehicle equals or exceeds a first electrical current threshold, determining the vehicle is being driven in the regenerative braking mode with the second output rate continuously for at least the second threshold amount of time includes determining a second set of parameters received from the vehicle indicate electrical current within the circuit of the vehicle equals or exceeds a second electrical current threshold, the first set of parameters includes first and second parameters corresponding to a particular parameter identifier, the second set of parameters includes third and fourth parameters corresponding to the particular parameter identifier, an amount of time between when the computing system receives the first and second parameters equals or exceeds the first threshold amount of time, and an amount of time between when the computing system receives the third and fourth parameters equals or exceeds the second threshold amount of time.

EEE A26 is the computing system of EEE A25, wherein: one or more other parameters of the first set of parameters correspond to the particular parameter identifier and are received by the computing system between receiving the first and second parameters, and the one or more other parameters of the first set of parameters indicate electrical current within the circuit of the vehicle equals or exceeds the first electrical current threshold, and/or one or more other parameters of the second set of parameters correspond to the particular parameter identifier and are received by the computing system between receiving the third and fourth parameters, and the one or more other parameters of the second set of parameters indicate electrical current within the circuit of the vehicle equals or exceeds the second electrical current threshold.

EEE A27 is the computing system of EEE A25, wherein: determining the multiple first sets of battery voltage values includes determining battery voltage values from vehicle messages received at the computing system between the computing system receiving a first vehicle message including the first parameter and a second vehicle message including the second parameter, and determining the multiple second sets of battery voltage values includes determining battery voltage values from vehicle messages received at the computing system between the computing system receiving a third vehicle message including the third parameter and a fourth vehicle message including the fourth parameter.

EEE A28 is the computing system of any one of EEE A1 to A27, wherein the functions further comprise: outputting, in response to determining the vehicle was driven in the electric vehicle mode and in the regenerative braking mode and determining the multiple first and second sets of battery voltage values, an audible or visual notification indicating a test of the battery pack is complete.

EEE A29 is the computing system of any one of EEE A1 to A28, wherein: the vehicle is an autonomous vehicle, and the functions further comprise transmitting, to an electronic control unit in the autonomous vehicle, instructions for controlling the vehicle to operate in the electric vehicle mode and the regenerative braking mode.

EEE A30 is the computing system of any one of EEE A1 to A29, wherein: the vehicle includes a hybrid vehicle, and determining the vehicle is being driven in the electric vehicle mode with the first output rate continuously for at least the first threshold amount of time occurs after determining a button in the hybrid vehicle to select electric vehicle mode has been selected.

EEE A31 is the computing system of any one of EEE A1 to A30, wherein the functions further comprise: providing at the computing system a user interface including a user-selectable control selectable to launch an application to test a battery within an electric vehicle, and the application is in an un-launched state when the user-selectable control is selectable.

EEE A32 is the computing system of EEE A31, wherein providing the user-selectable control includes providing the user-selectable control on a graphical user interface.

EEE A33 is the computing system of EEE A31, wherein providing the user-selectable control includes configuring a hardware button at the computing system to be selectable to launch the application.

EEE A34 is the computing system of any one of EEE A3 wherein the particular battery pack component comprises a battery pack module, a battery block, a battery string, or a battery cell.

EEE A35 is the computing system of any one of EEE A11, A12, A18-A22, or A24 wherein the battery pack components comprise a battery pack module, a battery block, a battery string, or a battery cell.

EEE A36 is the computing system of any one of EEE A16 or A17 wherein the battery pack component comprises a battery pack module, a battery block, a battery string, or a battery cell.

EEE A37 is the computing system of any one of EEE A1 to A36, wherein the processor includes multiple processors.

EEE A38 is the computing system of any one of EEE A1 to A37, further comprising: a user interface configured to output the test indicator.

EEE A39 is the computing system of EEE A38, wherein the user interface includes a display, a loudspeaker, or the display and the loudspeaker.

EEE A40 is the computing system of any one of EEE A1 to A39, wherein the functions further comprise: selecting, from a user interface, a guided component test for performing a measurement of a vehicle component; configuring a test device for performing the measurement; performing the measurement via the configured test device; and outputting on a display an indication of the measurement.

EEE B1 is a method comprising: determining a vehicle is being driven in an electric vehicle mode with a first output rate continuously for at least a first threshold amount of time; determining multiple first sets of battery voltage values for multiple battery pack components in the vehicle as the vehicle is driven in the electric vehicle mode with the first output rate continuously for at least the first threshold amount of time, each first set of battery voltage values includes or is representative of a pair of battery voltage values; determining the vehicle is being driven in a regenerative braking mode with a second output rate continuously for at least a second threshold amount of time; determining multiple second sets of battery voltage values for the multiple battery pack components in the vehicle as the vehicle is driven in the regenerative braking mode, each second set of battery voltage values includes or is representative of a pair of battery voltage values; and outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Each pair of battery voltage values among the second set of battery voltage values includes or is representative of minimum and maximum battery voltage values from each second set of battery voltage values.

EEE B2 is the method of EEE B1, further comprising monitoring parameters from the vehicle. The parameters include a first set of parameters indicative of a first electrical current and a system voltage within the vehicle, and a second set of parameters indicative of a second electrical current and the system voltage. The first electrical current is different than the second electrical current. Determining the vehicle is being driven in the electric vehicle mode with the first output rate is based on the first set of parameters. Determining the vehicle is being driven in the regenerative braking mode with the second output rate is based on the second set of parameters.

EEE B3 is the method of any one of EEE B1 to B2, further comprising determining a particular battery pack component in the multiple battery pack components has a maximum battery voltage. The first threshold amount of time equals an amount of time it takes for a battery voltage of the particular battery pack component to decay by a threshold percentage of the maximum battery voltage while the vehicle is being driven in the electric vehicle mode with the first output rate.

EEE B4 is the method of any one of EEE B1 to B3, wherein the first threshold amount of time is a first fixed amount of time stored in the non-transitory computer-readable memory, and the second threshold amount of time is a second fixed amount of time stored in the non-transitory computer-readable memory.

EEE B5 is the method of any one of EEE B1 to B4, further comprising determining, based on one or more parameter values corresponding to a particular parameter identifier, whether the vehicle is in a condition for testing the battery pack. The one or more parameter values corresponding to the particular parameter identifier are representative of a battery state-of-charge or a battery temperature.

EEE B6 is the method of any one of EEE B1 to B5, further comprising transmitting, to the vehicle, one or more vehicle messages to request diagnostic trouble code data from the vehicle; receiving, from the vehicle, one or more other vehicle messages including diagnostic trouble code data; and determining no diagnostic trouble codes are currently set active in a battery management system of the vehicle.

EEE B7 is the method of any one of EEE B1 to B6, wherein the first output rate includes multiple output rates within a range of positive current rates, and the second output rate includes multiple output rates within a range of negative current rates.

EEE B8 is the method of any one of EEE B1 to B7, wherein determining the vehicle is being driven in the electric vehicle mode with the first output rate continuously for at least the first threshold amount of time and determining the multiple first sets of battery voltage values occurs before determining the vehicle is being driven in the regenerative braking mode with the second output rate continuously for at least the second threshold amount of time and determining the multiple second sets of battery voltage values.

EEE B9 is the method of any one of EEE B1 to B7, wherein determining the vehicle is being driven in the electric vehicle mode with the first output rate continuously for at least the first threshold amount of time and determining the multiple first sets of battery voltage values occurs after determining the vehicle is being driven in the regenerative braking mode with the second output rate continuously for at least the second threshold amount of time and determining the multiple second sets of battery voltage values.

EEE B10 is the method of any one of EEE B1 to B9, wherein the first output rate is specified as: a given percentage of a specified peak output current of electrical motor(s) in the vehicle, or a range of currents including the specified peak output current of electrical motor(s) in the vehicle.

EEE B11 is the method of any one of EEE B1 to B10, wherein: the first output rate includes a first range of output rates, the first sets of battery voltage values are determined sequentially, each first set of battery voltage values is associated with an output rate within the first range of output rates, and the method further comprises receiving battery voltage values for at least some battery pack components within the multiple battery pack components to determine a particular first set of battery voltage values before receiving battery voltage values for at least some battery pack components within the multiple battery pack components to determine a next first set of battery voltage values.

EEE B12 is the method of any one of EEE B1 to B11, wherein the second output rate includes a second range of output rates, the second sets of battery voltage values are determined sequentially, each second set of battery voltage values is associated with an output rate within the second range of output rates. The method comprises receiving battery voltage values for at least some battery pack components within the multiple battery pack components to determine a particular second set of battery voltage values before receiving battery voltage values for at least some battery pack components within the multiple battery pack components to determine a next second set of battery voltage values.

EEE B13 is the method of any one of EEE B1 to B12, wherein the test indicator is based on whether the differences in pairs of battery voltage values among the first set of battery voltage values and whether differences in pairs of battery voltage values among the second set of battery voltage values exceed a threshold voltage value.

EEE B14 is the method of any one of EEE B1 to B13, wherein the minimum and maximum battery voltage values of each pair of battery voltage values within the first sets of battery voltage values correspond to each other temporally, and the minimum and maximum battery voltage values of each pair of battery voltage values within the second sets of battery voltage values correspond to each other temporally.

EEE B15 is the method of any one of EEE B1 to B13, wherein the minimum and maximum battery voltage values of each pair of battery voltage values within the first sets of battery voltage values are determined from a respective first set of vehicle messages received from the vehicle, and the minimum and maximum battery voltage values of each pair of battery voltage values within the second sets of battery voltage values are determined from a respective second set of vehicle messages received from the vehicle.

EEE B16 is the method of EEE B15, wherein each respective first set of vehicle messages includes parameter-identifier (PID) parameter values corresponding to first, second, third, and fourth PIDs, each respective second set of vehicle messages includes PID parameter values corresponding to the first, second, third, and fourth PIDs, the first PID corresponds to a maximum battery voltage of a battery pack component within the multiple battery pack components having the maximum battery voltage at a respective time, the second PID corresponds to a battery identifier of the battery pack component within the multiple battery pack components having the maximum battery voltage at a respective time, the third PID corresponds to a minimum battery voltage of a battery pack component within the multiple battery pack components having the minimum battery voltage at the respective time, and the fourth PID corresponds to a battery identifier of the battery pack component within the multiple battery pack components having the minimum battery voltage at the respective time.

EEE B17 is the method of EEE B15, wherein each respective first set of vehicle messages includes parameter-identifier (PID) parameter values corresponding to a battery voltage of each battery pack component within the multiple battery pack components at a respective time as the vehicle is being driven in the electric vehicle mode with the first output rate, each respective second set of vehicle messages includes PID parameter values corresponding to a battery voltage of each battery pack component within the multiple battery pack components at a respective time as the vehicle is driven in the regenerative braking mode with the second output rate. The method further comprises determining the minimum and maximum battery voltage values from each first set of battery voltage values based on minimum and maximum PID parameter values of each respective first set of vehicle messages, and determining the minimum maximum battery voltage values from each second set of battery voltage values based on minimum and maximum PID parameter values of each respective second set of vehicle messages.

EEE B18 is the method of any one of EEE B1 to B17, wherein the multiple first sets of battery voltage values for the multiple battery pack components and the multiple second sets of battery voltage values for the multiple battery pack components include groups of battery voltage values, each group of battery voltages includes a respective battery voltage value for one or more battery pack components in the vehicle battery pack, and each respective battery voltage value in each group of battery voltage values correspond to each other temporally.

EEE B19 is the method of any one of EEE B1 to B18, wherein the minimum and maximum battery voltage values for each pair of battery voltage values among the first set of battery voltage values are voltage values corresponding to different battery pack components of the battery pack, and the minimum and maximum battery voltage values for each pair of battery voltage values among the second set of battery voltage values are voltage values corresponding to different battery pack components of the battery pack.

EEE B20 is the method of EEE B19, further comprising storing the multiple first sets of battery voltage values and the multiple second sets of battery voltage values in the non-transitory computer-readable memory; comparing all battery voltage values corresponding to each battery pack component of the multiple battery pack components from among each first set of battery voltage values to each other to determine the minimum and maximum battery voltage values for each pair of battery voltage values among the first sets of battery voltage values; and comparing all battery voltage values corresponding to each battery pack component of the multiple battery pack components from among each second set of battery voltage values to each other to determine the minimum and maximum battery voltage values for each pair of battery voltage values among the second sets of battery voltage values.

EEE B21 is the method of any one of EEE B1 to B20, wherein the test indicator regarding the state of a battery pack includes a recommendation to rebalance two or more battery pack components in the battery pack or replacement of one or more battery pack components in the battery pack.

EEE B22 is the method of EEE B21, wherein the recommendation of the replacement of one or more battery pack components in the battery pack is based on differences in pairs of battery voltage values decreasing while the vehicle is driven in the electric vehicle mode with a first output rate by more than a voltage comparison threshold.

EEE B23 is the method of EEE B22, further comprising determining the first output rate based on first current samples obtained using a current clamp meter and determining the second output rate based on second current samples obtained using the current clamp meter.

EEE B24 is the method of any one of EEE B1 to B23, further comprising determining the vehicle is parked and operating in an operating state in which vehicle power is turned on and electrical accessories are turned off; determining multiple third sets of battery voltage values for the multiple battery pack components while the vehicle is operating in the operating state, each third set of battery voltage values includes a battery voltage value for each battery pack component of the multiple battery pack components; and determining the third sets of battery voltage values equal or exceed a threshold battery voltage or at least some battery voltages of the third sets of battery voltage do not equal or exceed the threshold battery voltage, the computing system is configured to determine the vehicle is being driven in the electric vehicle mode with the first output rate continuously for at least the first threshold amount of time or the regenerative braking mode with the second output rate continuously for at least the second threshold amount of time in response to determining the third sets of battery voltage values equal or exceed the threshold battery voltage, and the executable instructions include instructions executable by the processor to output a notification indicating the battery pack failed a battery test in response to determining at least some battery voltages of the third sets of battery voltage do not equal or exceed the threshold battery voltage.

EEE B25 is the method of any one of EEE B1 to B24, wherein: determining the vehicle is being driven in the electric vehicle mode with the first output rate continuously for at least the first threshold amount of time includes determining a first set of parameters received from the vehicle indicate electrical current within a circuit of the vehicle equals or exceeds a first electrical current threshold, determining the vehicle is being driven in the regenerative braking mode with the second output rate continuously for at least the second threshold amount of time includes determining a second set of parameters received from the vehicle indicate electrical current within the circuit of the vehicle equals or exceeds a second electrical current threshold, the first set of parameters includes first and second parameters corresponding to a particular parameter identifier, the second set of parameters includes third and fourth parameters corresponding to the particular parameter identifier, an amount of time between when the computing system receives the first and second parameters equals or exceeds the first threshold amount of time, and an amount of time between when the computing system receives the third and fourth parameters equals or exceeds the second threshold amount of time.

EEE B26 is the method of EEE B25, wherein one or more other parameters of the first set of parameters correspond to the particular parameter identifier and are received by the computing system between receiving the first and second parameters, and the one or more other parameters of the first set of parameters indicate electrical current within the circuit of the vehicle equals or exceeds the first electrical current threshold, and/or one or more other parameters of the second set of parameters correspond to the particular parameter identifier and are received by the computing system between receiving the third and fourth parameters, and the one or more other parameters of the second set of parameters indicate electrical current within the circuit of the vehicle equals or exceeds the second electrical current threshold.

EEE B27 is the method of EEE B25, wherein determining the multiple first sets of battery voltage values includes determining battery voltage values from vehicle messages received at the computing system between the computing system receiving a first vehicle message including the first parameter and a second vehicle message including the second parameter, and determining the multiple second sets of battery voltage values includes determining battery voltage values from vehicle messages received at the computing system between the computing system receiving a third vehicle message including the third parameter and a fourth vehicle message including the fourth parameter.

EEE B28 is the method of any one of EEE B1 to B27, further comprising outputting, in response to determining the vehicle was driven in the electric vehicle mode and in the regenerative braking mode and determining the multiple first and second sets of battery voltage values, an audible or visual notification indicating a test of the battery pack is complete.

EEE B29 is the method of any one of EEE B1 to B28, wherein the vehicle is an autonomous vehicle, and the method further comprises transmitting, to an electronic control unit in the autonomous vehicle, instructions for controlling the vehicle to operate in the electric vehicle mode and the regenerative braking mode.

EEE B30 is the method of any one of EEE B1 to B29, wherein the vehicle includes a hybrid vehicle, and determining the vehicle is being driven in the electric vehicle mode with the first output rate continuously for at least the first threshold amount of time occurs after determining a button in the hybrid vehicle to select electric vehicle mode has been selected.

EEE B31 is the method of any one of EEE B1 to B30, further comprising providing a user interface including a user-selectable control selectable to launch an application to test a battery within an electric vehicle, and the application is in an un-launched state when the user-selectable control is selectable.

EEE B32 is the method of EEE B31, wherein providing the user-selectable control includes providing the user-selectable control on a graphical user interface.

EEE B33 is the method of EEE B31, wherein providing the user-selectable control includes configuring a hardware button at a computing system to be selectable to launch the application.

EEE B34 is the method of any one of EEE B3 wherein the particular battery pack component comprises a battery pack module, a battery block, a battery string, or a battery cell.

EEE B35 is the method of any one of EEE B11, B12, B18-B22, or B24 wherein the battery pack components comprise a battery pack module, a battery block, a battery string, or a battery cell.

EEE B36 is the method of any one of EEE B16 or B17 wherein the battery pack component comprises a battery pack module, a battery block, a battery string, or a battery cell.

EEE B37 is the method of any one of EEE B1 to B36, wherein a processor of a computing system includes multiple processors.

EEE B38 is the method of any one of EEE B1 to B37, wherein a user interface of a computing system is configured to output the test indicator.

EEE B39 is the method of EEE B38, wherein the user interface includes a display, a loudspeaker, or the display and the loudspeaker.

EEE B40 is the method of any one of EEE B1 to B39, further comprising selecting, from a user interface, a guided component test for performing a measurement of a vehicle component; configuring a test device for performing the measurement; performing the measurement via the configured test device; and outputting on a display an indication of the measurement.

EEE C1 is a non-transitory computer-readable memory having stored therein instructions executable by a processor to cause a computing system to perform functions, the functions comprising: determining a vehicle is being driven in an electric vehicle mode with a first output rate continuously for at least a first threshold amount of time; determining multiple first sets of battery voltage values for multiple battery pack components in the vehicle as the vehicle is driven in the electric vehicle mode with the first output rate continuously for at least the first threshold amount of time, each first set of battery voltage values includes or is representative of a pair of battery voltage values; determining the vehicle is being driven in a regenerative braking mode with a second output rate continuously for at least a second threshold amount of time; determining multiple second sets of battery voltage values for the multiple battery pack components in the vehicle as the vehicle is driven in the regenerative braking mode, each second set of battery voltage values includes or is representative of a pair of battery voltage values; and outputting a test indicator regarding a state of a battery pack including the multiple battery pack components based on differences in pairs of battery voltage values among the first set of battery voltage values and differences in pairs of battery voltage values among the second set of battery voltage values. Each pair of battery voltage values among the first set of battery voltage values includes or is representative of minimum and maximum battery voltage values from each first set of battery voltage values. Each pair of battery voltage values among the second set of battery voltage values includes or is representative of minimum and maximum battery voltage values from each second set of battery voltage values.

EEE C2 is a non-transitory computer-readable memory having stored therein instructions executable by a processor to cause a computing system to the method in any one of EEE B1 to B40.

We claim:

1. A computing system comprising:
a processor; and
a non-transitory computer-readable memory storing executable instructions, wherein execution of the executable instructions by the processor causes the computing system to perform functions comprising:
determining a vehicle is being driven in an electric vehicle mode with a first output rate continuously for at least a first threshold amount of time;
determining multiple first sets of battery voltage values for multiple battery pack components in the vehicle as the vehicle is driven in the electric vehicle mode with the first output rate continuously for at least the first threshold amount of time, each first set of battery voltage values includes or is representative of a pair of battery voltage values;
determining the vehicle is being driven in a regenerative braking mode with a second output rate continuously for at least a second threshold amount of time;
determining multiple second sets of battery voltage values for the multiple battery pack components in the vehicle as the vehicle is driven in the regenerative braking mode, each second set of battery voltage values includes or is representative of a pair of battery voltage values; and
outputting a test indicator regarding a state of a battery pack including the multiple battery pack components based on differences in pairs of battery voltage values among the first set of battery voltage values and differences in pairs of battery voltage values among the second set of battery voltage values, wherein:
each pair of battery voltage values among the first set of battery voltage values includes or is representative of minimum and maximum battery voltage values from each first set of battery voltage values, and
each pair of battery voltage values among the second set of battery voltage values includes or is representative of minimum and maximum battery voltage values from each second set of battery voltage values.

2. The computing system of claim 1, wherein:
the functions further comprise monitoring parameters from the vehicle,
the parameters include a first set of parameters indicative of a first electrical current and a system voltage within the vehicle, and a second set of parameters indicative of a second electrical current and the system voltage,
the first electrical current is different than the second electrical current,
determining the vehicle is being driven in the electric vehicle mode with the first output rate is based on the first set of parameters, and
determining the vehicle is being driven in the regenerative braking mode with the second output rate is based on the second set of parameters.

3. The computing system of claim 1, wherein:
the functions further comprise determining a particular battery pack component in the multiple battery pack components has a maximum battery voltage, and
the first threshold amount of time equals an amount of time it takes for a battery voltage of the particular battery pack component to decay by a threshold percentage of the maximum battery voltage while the vehicle is being driven in the electric vehicle mode with the first output rate.

4. The computing system of claim 1, wherein:
the first threshold amount of time is a first fixed amount of time stored in the non-transitory computer-readable memory, and
the second threshold amount of time is a second fixed amount of time stored in the non-transitory computer-readable memory.

5. The computing system of claim 1, wherein:
the functions further comprise determining, based on one or more parameter values corresponding to a particular parameter identifier, whether the vehicle is in a condition for testing the battery pack; and
the one or more parameter values corresponding to the particular parameter identifier are representative of a battery state-of-charge or a battery temperature.

6. The computing system of claim 1,
wherein the functions further comprise:
transmitting, to the vehicle, one or more vehicle messages to request diagnostic trouble code data from the vehicle;
receiving, from the vehicle, one or more other vehicle messages including diagnostic trouble code data; and
determining no diagnostic trouble codes are currently set active in a battery management system of the vehicle.

7. The computing system of claim 1, wherein:
the first output rate includes multiple output rates within a range of positive current rates, and
the second output rate includes multiple output rates within a range of negative current rates.

8. The computing system of claim 1, wherein determining the vehicle is being driven in the electric vehicle mode with the first output rate continuously for at least the first threshold amount of time and determining the multiple first sets of battery voltage values occurs before determining the vehicle is being driven in the regenerative braking mode with the second output rate continuously for at least the second threshold amount of time and determining the multiple second sets of battery voltage values.

9. The computing system of claim 1, wherein determining the vehicle is being driven in the electric vehicle mode with the first output rate continuously for at least the first threshold amount of time and determining the multiple first sets of battery voltage values occurs after determining the vehicle is being driven in the regenerative braking mode with the second output rate continuously for at least the second threshold amount of time and determining the multiple second sets of battery voltage values.

10. The computing system of claim 1, wherein the first output rate is specified as:
a given percentage of a specified peak output current of electrical motor(s) in the vehicle, or
a range of currents including the specified peak output current of electrical motor(s) in the vehicle.

11. The computing system of claim 1, wherein:
the first output rate includes a first range of output rates,
the first sets of battery voltage values are determined sequentially,
each first set of battery voltage values is associated with an output rate within the first range of output rates, and
the functions further comprise receiving battery voltage values for at least some battery pack components within the multiple battery pack components to determine a particular first set of battery voltage values before receiving battery voltage values for at least some battery pack components within the multiple battery pack components to determine a next first set of battery voltage values.

12. The computing system of claim 1, wherein:
the second output rate includes a second range of output rates,
the second sets of battery voltage values are determined sequentially,
each second set of battery voltage values is associated with an output rate within the second range of output rates, and
the functions further comprise receiving battery voltage values for at least some battery pack components within the multiple battery pack components to determine a particular second set of battery voltage values before receiving battery voltage values for at least some battery pack components within the multiple battery pack components to determine a next second set of battery voltage values.

13. The computing system of claim 1, wherein the test indicator is based on whether the differences in pairs of battery voltage values among the first set of battery voltage values and whether differences in pairs of battery voltage values among the second set of battery voltage values exceed a threshold voltage value.

14. The computing system of claim 1, wherein:
the minimum and maximum battery voltage values of each pair of battery voltage values within the first sets of battery voltage values correspond to each other temporally, and
the minimum and maximum battery voltage values of each pair of battery voltage values within the second sets of battery voltage values correspond to each other temporally.

15. The computing system of claim 1, wherein:
the minimum and maximum battery voltage values of each pair of battery voltage values within the first sets of battery voltage values are determined from a respective first set of vehicle messages received from the vehicle, and
the minimum and maximum battery voltage values of each pair of battery voltage values within the second sets of battery voltage values are determined from a respective second set of vehicle messages received from the vehicle.

16. The computing system of claim 15, wherein:
each respective first set of vehicle messages includes parameter-identifier (PID) parameter values corresponding to first, second, third, and fourth PIDs,
each respective second set of vehicle messages includes PID parameter values corresponding to the first, second, third, and fourth PIDs,
the first PID corresponds to a maximum battery voltage of a battery pack component within the multiple battery pack components having the maximum battery voltage at a respective time,
the second PID corresponds to a battery identifier of the battery pack component within the multiple battery pack components having the maximum battery voltage at a respective time,
the third PID corresponds to a minimum battery voltage of a battery pack component within the multiple battery pack components having the minimum battery voltage at the respective time, and
the fourth PID corresponds to a battery identifier of the battery pack component within the multiple battery pack components having the minimum battery voltage at the respective time.

17. The computing system of claim 15, wherein:
each respective first set of vehicle messages includes parameter-identifier (PID) parameter values corresponding to a battery voltage of each battery pack component within the multiple battery pack components at a respective time as the vehicle is being driven in the electric vehicle mode with the first output rate,
each respective second set of vehicle messages includes PID parameter values corresponding to a battery voltage of each battery pack component within the multiple battery pack components at a respective time as the vehicle is driven in the regenerative braking mode with the second output rate, and
the functions further comprise:
determining the minimum and maximum battery voltage values from each first set of battery voltage values based on minimum and maximum PID parameter values of each respective first set of vehicle messages, and
determining the minimum maximum battery voltage values from each second set of battery voltage values based on minimum and maximum PID parameter values of each respective second set of vehicle messages.

18. The computing system of claim 1, wherein:
the multiple first sets of battery voltage values for the multiple battery pack components and the multiple second sets of battery voltage values for the multiple battery pack components include groups of battery voltage values,
each group of battery voltages includes a respective battery voltage value for one or more battery pack components in the vehicle battery pack, and
each respective battery voltage value in each group of battery voltage values correspond to each other temporally.

19. The computing system of claim 1, wherein:
the minimum and maximum battery voltage values for each pair of battery voltage values among the first set of battery voltage values are voltage values corresponding to different battery pack components of the battery pack, and
the minimum and maximum battery voltage values for each pair of battery voltage values among the second set of battery voltage values are voltage values corresponding to different battery pack components of the battery pack.

20. The computing system of claim 19, wherein the functions further comprise:
storing the multiple first sets of battery voltage values and the multiple second sets of battery voltage values in the non-transitory computer-readable memory;
comparing all battery voltage values corresponding to each battery pack component of the multiple battery pack components from among each first set of battery voltage values to each other to determine the minimum and maximum battery voltage values for each pair of battery voltage values among the first sets of battery voltage values; and
comparing all battery voltage values corresponding to each battery pack component of the multiple battery pack components from among each second set of battery voltage values to each other to determine the minimum and maximum battery voltage values for each pair of battery voltage values among the second sets of battery voltage values.

21. The computing system of claim 1, wherein the test indicator regarding the state of a battery pack includes a recommendation to rebalance two or more pack components in the battery pack or replacement of one or more battery pack components in the battery pack.

22. The computing system of claim 21, wherein the recommendation of the replacement of one or more battery pack components in the battery pack is based on differences in pairs of battery voltage values decreasing while the vehicle is driven in the electric vehicle mode with a first output rate by more than a voltage comparison threshold.

23. The computing system of claim 22, further comprises:
a current clamp meter, wherein the functions further comprise determining the first output rate based on first current samples obtained using the current clamp meter and determining the second output rate based on second current samples obtained using the current clamp meter.

24. The computing system of claim 1, wherein:
the functions further comprise:
determining the vehicle is parked and operating in an operating state in which vehicle power is turned on and electrical accessories are turned off;
determining multiple third sets of battery voltage values for the multiple battery pack components while the vehicle is operating in the operating state, each third set of battery voltage values includes a battery voltage value for each battery pack component of the multiple battery pack components; and
determining the third sets of battery voltage values equal or exceed a threshold battery voltage or at least some battery voltages of the third sets of battery voltage do not equal or exceed the threshold battery voltage,
the computing system is configured to determine the vehicle is being driven in the electric vehicle mode with the first output rate continuously for at least the first threshold amount of time or the regenerative braking mode with the second output rate continuously for at least the second threshold amount of time in response to determining the third sets of battery voltage values equal or exceed the threshold battery voltage, and
the executable instructions include instructions executable by the processor to output a notification indicating the battery pack failed a battery test in response to determining at least some battery voltages of the third sets of battery voltage do not equal or exceed the threshold battery voltage.

25. The computing system of claim 1, wherein:
determining the vehicle is being driven in the electric vehicle mode with the first output rate continuously for at least the first threshold amount of time includes determining a first set of parameters received from the vehicle indicate electrical current within a circuit of the vehicle equals or exceeds a first electrical current threshold,
determining the vehicle is being driven in the regenerative braking mode with the second output rate continuously for at least the second threshold amount of time includes determining a second set of parameters received from the vehicle indicate electrical current within the circuit of the vehicle equals or exceeds a second electrical current threshold,
the first set of parameters includes first and second parameters corresponding to a particular parameter identifier,
the second set of parameters includes third and fourth parameters corresponding to the particular parameter identifier,
an amount of time between when the computing system receives the first and second parameters equals or exceeds the first threshold amount of time, and
an amount of time between when the computing system receives the third and fourth parameters equals or exceeds the second threshold amount of time.

26. The computing system of claim 25, wherein:
one or more other parameters of the first set of parameters correspond to the particular parameter identifier and are received by the computing system between receiving the first and second parameters, and the one or more other parameters of the first set of parameters indicate electrical current within the circuit of the vehicle equals or exceeds the first electrical current threshold, and/or
one or more other parameters of the second set of parameters correspond to the particular parameter identifier and are received by the computing system between receiving the third and fourth parameters, and the one or more other parameters of the second set of parameters indicate electrical current within the circuit of the vehicle equals or exceeds the second electrical current threshold.

27. The computing system of claim 25, wherein:
determining the multiple first sets of battery voltage values includes determining battery voltage values from vehicle messages received at the computing system between the computing system receiving a first vehicle message including the first parameter and a second vehicle message including the second parameter, and
determining the multiple second sets of battery voltage values includes determining battery voltage values from vehicle messages received at the computing system between the computing system receiving a third vehicle message including the third parameter and a fourth vehicle message including the fourth parameter.

28. The computing system of claim 1, wherein the functions further comprise:
outputting, in response to determining the vehicle was driven in the electric vehicle mode and in the regenerative braking mode and determining the multiple first and second sets of battery voltage values, an audible or visual notification indicating a test of the battery pack is complete.

29. The computing system of claim 1, wherein:
the vehicle is an autonomous vehicle, and
the functions further comprise transmitting, to an electronic control unit in the autonomous vehicle, instructions for controlling the vehicle to operate in the electric vehicle mode and the regenerative braking mode.

30. The computing system of claim 1, wherein:
the vehicle includes a hybrid vehicle, and
determining the vehicle is being driven in the electric vehicle mode with the first output rate continuously for at least the first threshold amount of time occurs after determining a button in the hybrid vehicle to select electric vehicle mode has been selected.

31. A method comprising:
determining a vehicle is being driven in an electric vehicle mode with a first output rate continuously for at least a first threshold amount of time;
determining multiple first sets of battery voltage values for multiple battery pack components in the vehicle as the vehicle is driven in the electric vehicle mode with the first output rate continuously for at least the first threshold amount of time, each first set of battery voltage values includes or is representative of a pair of battery voltage values;
determining the vehicle is being driven in a regenerative braking mode with a second output rate continuously for at least a second threshold amount of time;
determining multiple second sets of battery voltage values for the multiple battery pack components in the vehicle as the vehicle is driven in the regenerative braking mode, each second set of battery voltage values includes or is representative of a pair of battery voltage values; and
outputting a test indicator regarding a state of a battery pack including the multiple battery pack components based on differences in pairs of battery voltage values among the first set of battery voltage values and differences in pairs of battery voltage values among the second set of battery voltage values, wherein:
each pair of battery voltage values among the first set of battery voltage values includes or is representative of minimum and maximum battery voltage values from each first set of battery voltage values, and
each pair of battery voltage values among the second set of battery voltage values includes or is representative of minimum and maximum battery voltage values from each second set of battery voltage values.

32. A non-transitory computer-readable memory having stored therein instructions executable by a processor to cause a computing system to perform functions, the functions comprising:
determining a vehicle is being driven in an electric vehicle mode with a first output rate continuously for at least a first threshold amount of time;
determining multiple first sets of battery voltage values for multiple battery pack components in the vehicle as the vehicle is driven in the electric vehicle mode with the first output rate continuously for at least the first threshold amount of time, each first set of battery voltage values includes or is representative of a pair of battery voltage values;
determining the vehicle is being driven in a regenerative braking mode with a second output rate continuously for at least a second threshold amount of time;
determining multiple second sets of battery voltage values for the multiple battery pack components in the vehicle as the vehicle is driven in the regenerative braking mode, each second set of battery voltage values includes or is representative of a pair of battery voltage values; and
outputting a test indicator regarding a state of a battery pack including the multiple battery pack components based on differences in pairs of battery voltage values among the first set of battery voltage values and differences in pairs of battery voltage values among the second set of battery voltage values, wherein:
each pair of battery voltage values among the first set of battery voltage values includes or is representative of minimum and maximum battery voltage values from each first set of battery voltage values, and
each pair of battery voltage values among the second set of battery voltage values includes or is representative of minimum and maximum battery voltage values from each second set of battery voltage values.
